(19) United States
(12) Patent Application Publication
(10) Pub. No.: US 2024/0258771 A1
(43) Pub. Date: Aug. 1, 2024

(54) III-NITRIDE-BASED DEVICES GROWN ON A THIN TEMPLATE ON THERMALLY-DECOMPOSED MATERIAL

(71) Applicant: The Regents of the University of California, Oakland, CA (US)

(72) Inventors: Philip Chan, Goleta, CA (US); Steven P. DenBaars, Goleta, CA (US); Shuji Nakamura, Santa Barbara, CA (US)

(73) Assignee: The Regents of the University of California, Oakland, CA (US)

(21) Appl. No.: 18/559,654

(22) PCT Filed: May 9, 2022
(86) PCT No.: PCT/US22/28264

§ 371 Date: Nov. 8, 2023

Related U.S. Application Data
(60) Provisional application No. 63/230,205, filed on Aug. 6, 2021.
(60) Provisional application No. 63/186,749, filed on May 10, 2021.

(51) Int. Cl. H01S 5/343; H01S 5/20

(52) U.S. Cl. CPC H01S 5/34333; H01S 5/2068; H01S 2301/173

(57) ABSTRACT

A III-nitride based device is fabricated having an in-plane lattice constant or strain that is more than 30% biaxially relaxed, by creating a III-nitride based decomposition stop layer on or above a III-nitride based decomposition layer, wherein a temperature is increased to decompose the III-nitride based decomposition layer; and growing a III-nitride based device structure on or above the III-nitride based decomposition stop layer. The III-nitride based device structure includes at least one of an n-type layer, active layer, and p-type layer, and at least one of the n-type layer, active layer and p-type layer has an in-plane lattice constant or strain that is preferably more than 30% biaxially relaxed, more preferably 50% or more biaxially relaxed, and most preferably at least 70% biaxially relaxed.

### CROSS REFERENCE TO RELATED APPLICATIONS

This application claims the benefit under 35 U.S.C. Section 119(e) of the following co-pending and commonly-assigned applications:

U.S. Provisional Application Ser. No. 63/186,749, filed on May 10, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP1 (UC 2021-888-1); and

U.S. Provisional Application Ser. No. 63/230,205, filed on Aug. 6, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP2 (UC 2021-888-2):
both of which applications are incorporated by reference herein.

This application is related to the following co-pending and commonly-assigned applications:

U.S. Provisional Application Ser. No. 63/197,740, filed on Jun. 5, 2021, by Shuji Nakamura and Steven P. DenBaars, entitled “III-V, II-VI IN-SITU COMPLIANT SUBSTRATE FORMATION,” attorneys' docket number G&C 30794.0803USP1 (UC 2021-889-1):

U.S. Provisional Application Ser. No. 63/230,205, filed on Aug. 6, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP2 (UC 2021-888-2);

U.S. Provisional Application Ser. No. 63/240,517, filed on Sep. 3, 2021, by Norleakvisoth Lim, Philip Chan, Steven P. DenBaars, Michael J. Gordon and Shuji Nakamura, entitled “III-NITRIDE-BASED DEVICES GROWN WITH A RELAXED ACTIVE REGION,” attorneys' docket number G&C 30794.0806USP1 (UC 2022-760-1);

U.S. Provisional Application Ser. No. 63/245,105, filed on Sep. 16, 2021, by Philip Chan, Steven P. DenBaars and Shuji Nakamura, entitled “SURFACE MORPHOLOGY OF III-NITRIDE-BASED DEVICES GROWN ON OR ABOVE A STRAIN COMPLIANT TEMPLATE,” attorneys' docket number G&C 30794.0808USP1 (UC 2022-763-1); and

U.S. Provisional Application Ser. No. 63/305,441, filed on Feb. 1, 2022, by Philip Chan, Hsun-Ming Chan, Vincent Rienzi and Shuji Nakamura, entitled “III-NITRIDE-BASED HIGH EFFICIENCY AND HIGH-POWER DEVICES GROWN ON OR ABOVE A STRAlN RELAXED TEMPLATE,” attorneys' docket number G&C 30794.0813USP1 (UC 2022-775-1);
all of which applications are incorporated by reference herein.

### STATEMENT REGARDING FEDERALLY SPONSORED RESEARCH AND DEVELOPMENT

This invention was made with Government support under Grant No. HR001120C0135 awarded by the Defense Advanced Research Projects Agency (DARPA). The Government has certain rights in this invention.

### BACKGROUND OF THE INVENTION

### 1. Field of the Invention

This invention relates to III-nitride based devices grown on or above a thin template on thermally decomposed material.

### 2. Description of the Related Art

(Note: This application references a number of different publications and patents as indicated throughout the specification by one or more reference numbers in brackets, e.g., [x]. A list of these different publications and patents ordered according to these reference numbers can be found below in the section entitled “References.” Each of these publications and patents is incorporated by reference herein.)

Next-generation micron-sized light-emitting diode (micro-LED or μLED) displays with a chip size of less than 100 μm have been studied intensively due to their advantages of high wall plug efficiency (HPE) and wide color gamut [1, 2] as compared to conventional liquid crystal displays (LCDs) and organic LED (OLED) displays. Despite the promising outlook, μLEDs are still faced with a number of technical bottlenecks. Currently, mini-sized LED (mini-LED or mLED) displays with a chip size of more than 100 μm are commercially available, despite the huge costs caused by the large chip size [1].

Indium Gallium Nitride (InGaN) based LEDs are currently used for blue and green LEDs while Aluminum Indium Gallium Phosphide (AlInGaP) based LEDs are currently used for red LEDs. With regard to temperature stability, wide bandgap InGaN-based LEDs are superior. AlInGaP-based red LEDs have problems with temperature stability due to a small band offset between the active layer and p-type cladding layer [2]. The external quantum efficiency (EQE) of InGaN-based green and red LEDs is much smaller than that of InGaN-based blue LEDs.

In order to make highly efficient green and red LEDs using an InGaN active layer, the Indium (In) composition must be increased while maintaining good crystal quality. High temperature growth is necessary for high crystal quality but reduces In incorporation. Additionally, increasing the In composition of an InGaN layer grown on GaN increases the compressive strain of InGaN due to the increased lattice mismatch between the InGaN and GaN. The increased strain further reduces the In incorporation. This effect from the large compressive strain of InGaN, known as the composition pulling effect, makes it difficult to increase the In composition past blue emission at a high growth temperature necessary to make a highly efficient green and red LEDs and laser diodes (LDs) [3-8].

Recently, porous GaN was developed using electro-chemical etching of GaN [3,4]. A highly Silicon (Si) doped region is selectively etched to form the porous GaN. After InGaN is grown on GaN, the GaN layer can be porosified to allow the InGaN layer to partially relax as shown by Pasayat et al. [3,4]. Also, when they grow InGaN layer on a partially relaxed InGaN layer grown on a porous GaN template with size of 10 μm×10 μm mesa, the InGaN layer has much higher In composition in comparison with that grown on a GaN template [3,4]. Finally, they demonstrated red LED emission with a peak EQE of 0.2% and an emission peak wavelength of 625 nm at a current density of 10Acm⁻² [4]. Their InGaN quantum well (QW) was grown at a low temperature of 765° C. They used porous GaN with a size of 10 μm×10 μm and having a rectangular shape to obtain a mechanically flexible or compliant GaN template for next relaxed InGaN growth.

An example of the use of porous GaN is illustrated in the LED structure 100 of FIG. 1, which includes a sapphire substrate 101, a GaN template 102, a porous GaN layer 103, an unintentionally doped (uid) GaN layer 104, an In_{0.04}Ga_{0.96}N layer 105, an InGaN multi-quantum well (MQW) 106, a p-InGaN layer 107, and an Indium-Tin-Oxide (ITO) layer 108. The tile size is 10 μm and a mesa is etched having a size of 6 μm. A Silicon Dioxide (SiO₂) layer 109 is deposited on the sidewalls by plasma-enhanced chemical vapor deposition (PECVD). A Titanium Gold (Ti/Au) n-contact 110 and a Ti/Au p-contact 111 are subsequently deposited. A battery 112 or other electrical source is connected to the contacts 110, 111 in order to apply an electrical bias to the LED 100. The resulting light emission 113 is extracted from both top and bottom sides of the LED 100.

The red emission 113 from the LED 100 is scattered by the porous GaN 103, which loses the directionality of the LED emission 113 and reduces the EQE of the LED 100. Also, the peak EQE of 0.2% is too small for a display application and other applications [4]. The problem with this structure is that the LED emission 113 is extracted from the sapphire substrate 101, wherein the LED emission 113 is absorbed and scattered by the porous GaN 103.

Another problem with porous GaN is that it is a complicated process. In order to make the porous GaN, mesa etching with a size of 10 μm is performed, and then electrical chemical etching is performed to form the holes from sidewall of the mesa after putting protecting mask on the top of the mesa. Next, the LED structure is grown on top of each mesa after removing the protecting mask. After the growth, a conventional LED process is performed. The reproducibility of the whole process is very poor. Also, porous GaN technology is only effective for a mesa size less than 10 μm×10 μm in order to obtain the highly relaxed InGaN layers to minimize composition pulling effects [5]. Due to the small size of the device, the application is limited. Also, the process is complicated.

Thus, there is a need in the art for improved methods of making highly efficient blue, green and red LEDs and LDs using an InGaN active layer, where the In composition is increased while maintaining good crystal quality. The present invention satisfies this need.

### SUMMARY OF THE INVENTION

To overcome the limitations of the prior art described above, the present invention discloses a method of fabricating a device, and the resulting device, comprising: a III-nitride based device structure, such as an LED and LD, grown on or above a GaN decomposition stop layer on a thermally decomposed InGaN decomposition layer, wherein the decomposition layer is decomposed at a high temperature to obtain a mechanically flexible or compliant decomposition stop layer. This disclosure refers to a “decomposition stop layer on a decomposed decomposition layer” as a “Thin Template On Thermally Decomposed Material (TTOTDM).”

Any III-nitride based device structure may be grown on or above the decomposition stop layer with a high crystal quality and with a high In incorporation at a high growth temperature. In the case of an LED or LD, at least n-type, active or emitting, and p-type layers are grown on or above the decomposition stop layer. A top layer of the III-nitride based device structure may be flip-chip bonded onto a sub-mount, and the device structure may be removed from the decomposed decomposition layer by etching or mechanical means.

Using the present invention, experimental results have obtained more than 130% biaxially relaxed InGaN across a surface of a 2-inch substrate. In this context, relaxed means that the in-plane lattice constant or strain is biaxially relaxed. The limitation of a 2-inch size is determined by the size of the substrate, not by the method of the present invention. The present invention is also capable of obtaining almost freely relaxed InGaN across a whole surface area of larger substrates.

Conventionally, the growth temperature of InGaN QW has been around 750° C. to obtain a red emission with a peak emission wavelength of 610˜630 nm at a current density of 10 A cm⁻² [3-6]. Using the current invention, the growth temperature of InGaN QW could be increased up to 870° C. to obtain a peak emission wavelength of 650 nm at a current density of 10-200 A cm⁻². The higher the growth temperature of InGaN QWs the better to improve the crystal quality of InGaN QWs [3-6]. This would be a big breakthrough!

The present invention may also be used to grow a III-nitride AlInGaN based device structure using an AlGaN, InGaN or AlInGaN decomposition stop layer on a thermally decomposed AlGaN, InGaN or AlInGaN decomposition layer, wherein the decomposition layer is decomposed at a high temperature to obtain a mechanically-flexible or compliant decomposition stop layer.

This means that the method could make any number of different devices using almost freely relaxed InGaN, AlGaN or AlInGaN to increase the In or Al composition by minimizing the composition pulling effect. In this disclosure, InGaN refers to InₓGa₍₁₋ₓ₎N(0≤x≤1), AlGaN refers to AlₓGa₍₁₋ₓ₎N(0≤x≤1) and AlInGaN refers AlₓIn_{y}Ga_{z}N ((0≤x≤1, (0≤y≤1), (0≤z≤1), x+y+z=1).

During the growth of the decomposition stop layer, the decomposition layer should be decomposed until the decomposition stop layer becomes mechanically flexible or compliant. The materials and thickness of the decomposition stop layer should be determined by this definition. Thus, the materials of the decomposition stop layer are more thermally stable than decomposition layer. The thickness of the decomposition stop layer depends on how long it takes for the decomposition layer to decompose until the decomposition stop layer becomes mechanically flexible or compliant. If the decomposition layer decomposes slowly at the growth temperature of the decomposition stop layer, the thickness of the decomposition stop layer becomes large assuming the growth rate of the decomposition stop layer is constant.

Or after growing the decomposition stop layer with a certain thickness, the temperature is increased more than the growth temperature of the decomposition stop layer to decompose the decomposition layer. In this case, the decomposition layer is not decomposed during the growth of the decomposition stop layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1 is a schematic of an LED found in the prior art.

FIG. 2 is a schematic of an epitaxial structure illustrating first and second growths by metal organic chemical vapor deposition (MOCVD), according to the present invention.

FIGS. 3(a) and 3(b) present experimental results for the present invention.

FIG. 4 is a high resolution x-ray diffraction reciprocal space map (RSM) of an as-grown epitaxial wafer described in FIG. 2, which is taken aligned to an off-axis (-1-124) peak, wherein the points plotted indicate an 85% relaxed In_{0.04}Ga_{0.96}N layer.

FIGS. 5(a), 5(b), and 5(c) present results of a quick test (QT) measurement of red LEDs grown using the present invention, wherein FIG. 5(a) shows the light output power and the forward voltage as a function of the current, FIG. 5(b) shows an emission spectra at a forward current of 20 mA, and FIG. 5(c) is a list that shows the light output power, forward voltage, peak emission wavelength and the full width at half maximum (FWHM) of the emission spectra at the forward current of 20 mA.

FIG. 6 presents a QT measurement setup and a structure of a red LED epi-wafer grown using the present invention.

FIGS. 7(a), 7(b) and 7(c) present results of a QT measurement of red LEDs grown using the present invention, wherein FIG. 7(a) shows the light output power and the forward voltage as a function of the current, FIG. 7(b) shows an emission spectra at a forward current of 20 mA, and FIG. 7(c) is a list that shows the light output power, forward voltage, peak emission wavelength and the FWHM of the emission spectra at the forward current of 20 mA.

FIGS. 8(a), 8(b) and 8(c) present results of a QT measurement of red LEDs grown using the present invention, wherein FIG. 8(a) shows the light output power and the forward voltage as a function of the current, the FIG. 8(b) shows an emission spectra at a forward current of 20 mA, and FIG. 8(c) is a list that shows the light output power, forward voltage, peak emission wavelength and the FWHM of the emission spectra at the forward current of 20 mA.

FIG. 9 is a high resolution x-ray diffraction RSM of an as-grown epitaxial wafer described in FIG. 8, which is taken aligned to an off-axis (-1-124) peak, wherein the points plotted indicate a 159% relaxed In_{0.04}Ga_{0.96}N layer.

FIGS. 10(a), 10(b) and 10(c) present results of a QT measurement of red LEDs grown using the present invention, wherein FIG. 10(a) shows the light output power and the forward voltage as a function of the current, FIG. 10(b) shows an emission spectra at a forward current of 20 mA, and FIG. 10(c) is a list that shows the light output power, forward voltage, peak emission wavelength and the FWHM of the emission spectra at the forward current of 20 mA.

FIGS. 11(a), 11(b), and 11(c) present results of a QT measurement of red LEDs grown using the present invention, wherein FIG. 11(a) shows the light output power and the forward voltage as a function of the current, FIG. 11(b) shows an emission spectra at a forward current of 20 mA, and FIG. 11(c) is a list that shows the light output power, forward voltage, peak emission wavelength and the FWHM of the emission spectra at the forward current of 20 mA.

FIG. 12 presents the structure of a fabricated red LED on a wafer after ITO deposition, mesa etching and metal bonding pad deposition.

FIGS. 13(a), 13(b), 13(c) and 13(d) show the emission spectra, peak emission wavelength, light output power (L) and forward voltage (V), and external quantum efficiency (EQE), respectively, as a function of the current density (J), of the fabricated red LED on the wafer without packaging.

FIGS. 14(a), 14(b) and 14(c) present results of a QT measurement of red LEDs described in FIGS. 13(a)-13(d) grown using the present invention, wherein FIG. 14(a) shows the light output power and the forward voltage as a function of the current, FIG. 14(b) shows an emission spectra at a forward current of 20 mA, and FIG. 14(c) is a list that shows the light output power, forward voltage, peak emission wavelength and the FWHM of the emission spectra at the forward current of 20 mA.

FIGS. 15(a), 15(b), 15(c) and 15(d) show the emission spectra, peak emission wavelength, light output power (L) and forward voltage (V), and external quantum efficiency (EQE), respectively, as a function of the current density (J), of the fabricated LED on the wafer without packaging.

FIGS. 16(a), 16(b) and 16(c) present results of a QT measurement of red LEDs described in FIGS. 15(a)-15(d) grown using the present invention, wherein FIG. 16(a) shows the light output power and the forward voltage as a function of the current, FIG. 16(b) shows an emission spectra at a forward current of 20 mA, and FIG. 16(c) is a list that shows the light output power, forward voltage, peak emission wavelength and the FWHM of the emission spectra at the forward current of 20 mA.

FIGS. 17(a), 17(b) and 17(c) are schematics that show the experimental results of fabricating monolithic three primary color LEDs for display application using the present invention, including the structure of the monolithic three primary color LEDs and a growth sequence.

FIG. 18 shows the emission spectra of monolithic three color LEDs with each chip size of 20×20 μm at a forward current of 1.5 mA as shown in FIGS. 17(a), 17(b) and 17(c), wherein the peak wavelengths are 427 nm (blue), 565 nm (green) and 603 nm (red).

FIGS. 19(a), 19b) and 19(c) show photo images of the monolithic three color LEDs of FIGS. 17(a), 17(b) and 17(c), respectively, with each chip size being 20×20 μm at a forward current of 1 mA.

FIG. 20 is a schematic of an LED following growth by MOCVD and flip-chip bonding of an LED epi-wafer to a sub-mount, according to a first embodiment of the present invention.

FIG. 21 is a schematic of the LED of the first embodiment after removing the LED epi-wafer from the decomposed decomposition layer by etching or mechanical pressure.

FIG. 22 is a schematic of the LED chip of the first embodiment sub-mounted on an Si sub-mount after the LED chip is separated from the epi-wafer.

FIG. 23 is a schematic of an LED following growth by MOCVD and flip-chip bonding of the LED epi-wafer to a sub-mount, according to a second embodiment of the present invention.

FIG. 24 is a schematic of the LED of the second embodiment after removing the LED epi-wafer from the decomposed decomposition layer by etching or mechanical pressure.

FIG. 25 is a schematic of the LED of the second embodiment with the LED chip sub-mounted on a glass substrate after the LED chip is separated from the epi-wafer.

FIGS. 26(a) and 26(b) are schematics depicting the fabrication of an LED chip with an aperture and mesa for removal of LED epi-layers from the decomposed decomposition layer using photoelectrochemical (PEC) etching, according to a third embodiment of the present invention.

FIG. 27 is a schematic of the completed LED structure of the third embodiment after decomposition layer removal by PEC etching.

FIG. 28 is a schematic of an LD following growth by MOCVD and flip-chip bonding of the LD to a sub-mount, according to a fourth embodiment of the present invention.

FIG. 29 is a schematic of the LD of the fourth embodiment after removing the device structure from the decomposed decomposition layer by etching or mechanical pressure.

FIG. 30 is a schematic of the LD of the fourth embodiment with the LD chip sub-mounted on a Silicon Carbide (SiC) substrate after the LD chip is separated from the epi-wafer.

FIG. 31 is a schematic of an LD epi-wafer following growth by MOCVD and flip-chip bonding of the LD epi-wafer to a sub-mount, according to a fifth embodiment of the present invention.

FIG. 32 is a schematic of the LD epi-wafer of the fifth embodiment after removing the LD epi-wafer from the decomposed decomposition layer by etching or mechanical pressure.

FIG. 33 is a schematic of the LD chip of the fifth embodiment sub-mounted on the SiC substrate after the LD chip is separated.

FIG. 34 is a schematic of an LED, LD or photodiode (PD) fabricated without removing the decomposition layer, according to a sixth embodiment of the present invention.

FIGS. 35(a) and 35(b) are schematics of LEDs grown by MOCVD with variable emission wavelengths, according to a seventh embodiment of the present invention.

FIGS. 36(a) and 36(b) are schematics where ion implantation of In is performed, according to an eighth embodiment of the present invention.

FIGS. 37(a) and 37(b) are schematics for making three color LEDs for a display application, according to a ninth embodiment of the present invention.

FIGS. 38(a) and 38(b) are schematics for making three color LEDs for a display application, according to a tenth embodiment of the present invention.

FIG. 39 is a flowchart illustrating a process for fabricating III-nitride device structures according to the present invention.

### DETAILED DESCRIPTION OF THE INVENTION

In the following description of the preferred embodiment, reference is made to the accompanying drawing which forms a part hereof, and in which is shown by way of illustration a specific embodiment in which the invention may be practiced. It is to be understood that other embodiments may be utilized, and structural changes may be made without departing from the scope of the present invention.

### Overview

The present invention discloses III-nitride based LED and LD device structures with InGaN, AlGaN or AlInGaN layers having emission wavelengths from 200 nm to 1500 nm. For III-nitride based LED and LD structures having blue, green and red emission wavelengths, InGaN layers are used: for III-nitride based LED and LD structures having from ultraviolet (UV-A) to band C (UV-C) emission wavelengths, the InGaN layers are replaced with AlGaN layers. In both instances, the InGaN or AlGaN growth is of high crystal quality, with a high In or Al composition using relaxed InGaN or AlGaN layers, respectively, grown on or above a flexible or compliant decomposition stop layer grown on or above a decomposition layer that is decomposed at a high temperature or a high growth temperature.

The present invention can be applied to many types of III-nitride based devices, in addition to LEDs and LDs, such as electronic devices, radio frequency (RF) devices, high frequency devices, transistors, high electron mobility transistors (HEMTs), field effect transistors (FETs), photodetectors, solar cells, etc., because these devices require a high crystal quality of InGaN, AlGaN and AlInGaN.

### Technical Description

Conventionally, porous GaN has been used to grow relaxed InGaN multiple quantum well (MQW) structures or other InGaN layers with increased In incorporation [3,4]. In addition, nanowire, nanorod and quantum dot have been used to grow relaxed InGaN to obtain a longer wavelength, such as red emission [7,8]. However, the processes of these conventional methods are so complicated and the relaxed usable area is nanometer size [7,8]. The present invention demonstrates a different method to grow relaxed InGaN, AlGaN or AlInGaN layers, including InGaN or AlGaN MQW layers and other InGaN, AlGaN or AlInGaN layers, with increased In or Al incorporation and increased growth temperature, respectively. In this disclosure, only MOCVD growth is mentioned, although other growth methods, including MBE, CVD and other growth methods, are applicable for this invention.

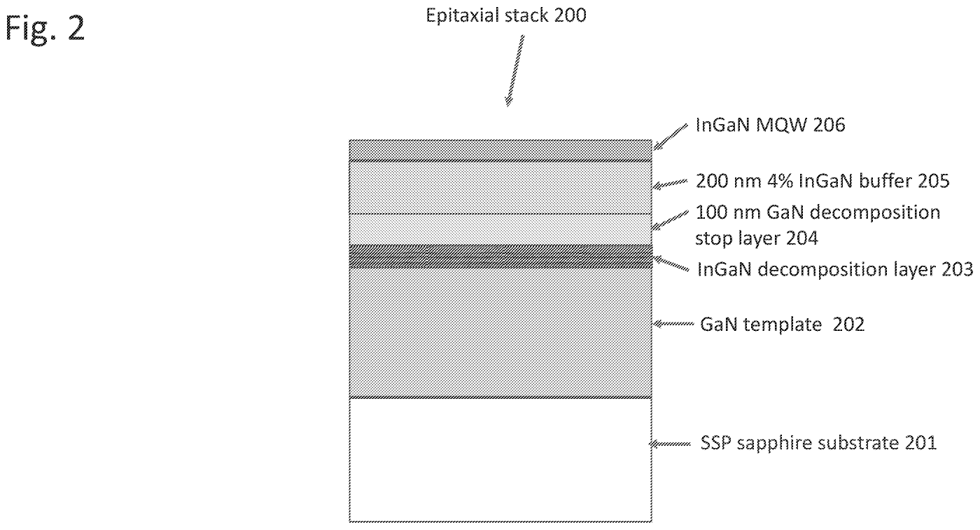

FIG. 2 is a schematic of an epitaxial structure 200 grown by MOCVD, according to the present invention. The epitaxial structure 200 is fabricated in two growths.

A first growth involves the following steps: a single-side polished (SSP) sapphire substrate 201 is provided and a GaN template 202 is grown on the SSP sapphire substrate 201 by MOCVD. Next, a decomposition layer 203, comprising a 2.5 nm thick In_{0.3}Ga_{0.7}N layer, is grown by MOCVD at a temperature of 750° C. The decomposition layer 203 should be thin, preferably under 10 nm and more preferably under 5 nm, because a thick decomposition layer 203 allows the device structure to peel off from the decomposed decomposition layer 203 after device growth or during device processing. Then, a decomposition stop layer 204, comprising 100 nm thick GaN, is grown, with 30 nm of the growth at 750° C. and the remaining 70 nm while the temperature is ramped to 1000° C. During the high temperature growth of the decomposition stop layer 204 at 1000° C., the 2.5 nm thick InGaN of the decomposition layer 203 decomposes into Indium (In) or Gallium (Ga) metal or InGa metal alloy and Nitrogen gas and, as a result, TTOTDM is complete. The temperature is then cooled down to 920° C. to grow a 200 nm In_{0.04}Ga_{0.096}N buffer 205 with 4% In composition on or above the decomposition stop layer 204.

During experiments, the resulting wafer was cooled to room temperature and removed from the MOCVD chamber to check the surface morphology for the first growth. However, during production, when making a device such as an LED or LD, the structure would be continuously grown without removing the wafer from the MOCVD chamber to check the surface morphology.

A second growth involves the following steps: an InGaN MQW 206 is grown on or above the InGaN buffer 205 at a temperature greater than 800° C. Specifically, the InGaN MQW 206 consists of four periods of 2.5 nm InGaN QWs grown at 865° C., a 2.5 nm GaN cap grown at 865° C., and 8.3 nm InGaN barriers grown at a temperature 35° C. hotter than the QWs or 900° C.

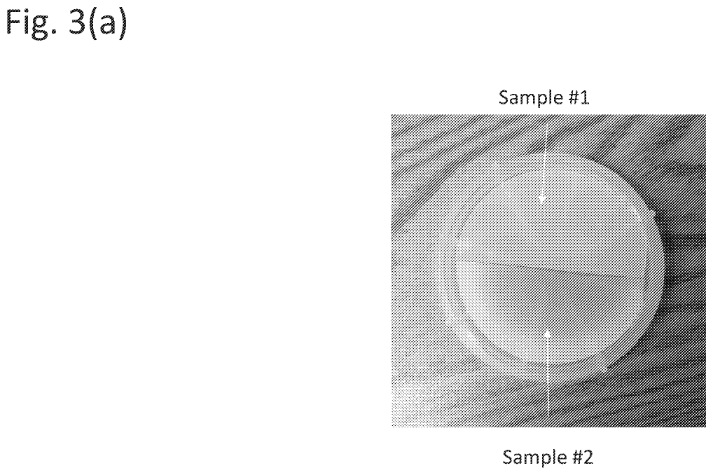

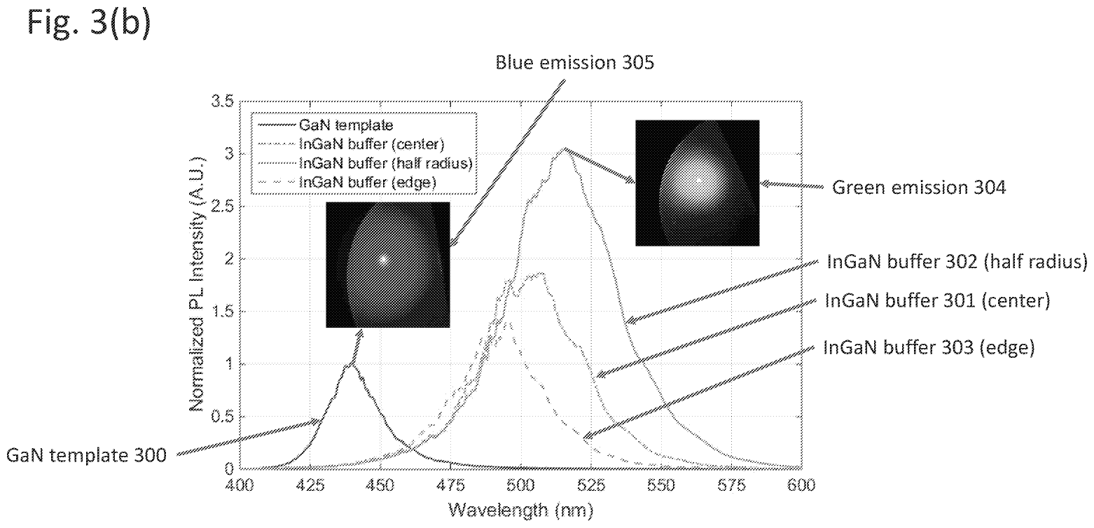

FIGS. 3(a) and 3(b) show results from the experiments, wherein FIG. 3(a) is a photograph of a 2-inch wafer with two samples thereon, and FIG. 3(b) is a graph of normalized photoluminescence (PL) intensity (a.u.) vs. wavelength (nm) for the two samples.

In FIG. 3(a), the upper half of the 2-inch wafer with a transparent color, labelled as sample #1, is a GaN template 202 on a sapphire substrate 201 as a reference, while the bottom half of the 2-inch wafer with a dark color, labelled as sample #2, is the first growth (an InGaN buffer 205 on a GaN decomposition stop layer 204 on a decomposed InGaN decomposition layer 203 on the GaN template 202 on the sapphire substrate 201) as described in FIG. 2. X-ray diffraction was used to measure layer composition and relaxation.

As noted above, the InGaN decomposition layer 203 is decomposed into In or Ga metal or InGa metal alloy and Nitrogen gas during the high temperature growth of the GaN decomposition stop layer 204. Due to In and Ga metal formation, the color of the bottom half of the 2-inch wafer becomes black in color. The GaN decomposition stop layer 204 is almost floating from the lower GaN template 202, and the GaN decomposition stop layer 204 is mechanically flexible and compliant.

As noted above, both samples were co-loaded into an MOCVD chamber, and then the second growth of the InGaN MQW 206 was performed at 865° C. (2.5 nm thick QWs, 2.5 nm thick GaN cap, and 8.3 nm thick InGaN barriers with a temperature 35° C. hotter than the QWs, for 4 periods of the QWs). Then, the samples were removed from the MOCVD chamber to measure the photoluminescence (PL) at room temperature (RT) with a Helium Cadmium (He—Cd) 325 nm laser, as shown in FIG. 3(b).

In FIG. 3(b), the normalized PL intensity vs. wavelength is plotted for the GaN template 202 (sample #1) and labeled as 300, while the normalized PL intensity vs. wavelength is plotted for the InGaN buffer 205 (sample #2) is labeled as 301 (center of sample #2), 302 (half radius of sample #2), and 303 (edge of sample #2).

The InGaN MQW 206 on the InGaN buffer 205 described in FIG. 2 shows a strong green emission 304 around 515 nm in FIG. 3(b). On the other hand, the reference InGaN MQW on the GaN template 202, which has a high compressive strain, shows a weak blue emission 305 around 440 nm. As measured at the same location of the resulting wafer, the peak PL wavelength increased by at least 50 nm, and as much as 75 nm, and the peak PL intensity of the green emission 304 is three times stronger than that of the blue emission 305.

The reference InGaN MQW grown on the GaN template 202 shows a peak wavelength of 440 nm, violet color, as indicated by the plot 300 and the photograph 305, because the InGaN has a huge compressive strain when it is grown on the GaN template 202 due to a large lattice mismatch. Less In is incorporated into the InGaN, called composition pulling effects, due to the large compressive strain [5].

On the other hand, the InGaN MQW 206 grown on the InGaN buffer 205 and the GaN decomposition stop layer 204 shows a peak wavelength of 515 nm at the same location of the wafer, as indicated by the plot 301 and photograph 304. The peak PL wavelength is 75 nm longer and the peak PL intensity is three times stronger than that of the reference InGaN MQW on the GaN template 202, because all of the InGaN layers 205, 206 grown on the flexible or compliant GaN decomposition stop layer 204 are fully or partially relaxed.

From the experimental results, the III-nitride based device structure 206 grown on or above the III-nitride based decomposition stop layer 204 can be characterized as having one or more properties comprising: a peak photoluminescence wavelength increased by at least 50 nm; and an in-plane lattice constant or strain of at least one InGaN layer 205, 206 has a relaxation of more than 50%: as compared to a III-nitride based device structure grown on or above the III-nitride based decomposition stop layer 204 without the decomposed III-nitride based decomposition layer 203.

Further, at least one of a temperature, a thickness of the III-nitride based decomposition layer 203, a thickness of the III-nitride based decomposition stop layer 204, or an Indium content of the III-nitride based decomposition layer 203, are tailored so that atoms of the III-nitride based decomposition layer 203 are distributed such that the III-nitride based decomposition stop layer 204 forms on the III-nitride based decomposition layer 203 with reduced strain and reduced defect density.

Pasayat et al. reported a 45 nm longer emission of InGaN MQW on a relaxed (56% relaxed) InGaN buffer on porous GaN in comparison to an InGaN MQW on a GaN template by PL [3]. The PL of the relaxed InGaN MQW 206 grown on the InGaN buffer 205 of the present invention is 75 nm longer than the PL of the reference InGaN MQW grown on the GaN template 202. This means that the relaxed InGaN buffer 205 of the present invention is more relaxed than 56% [3], and is almost 100% relaxed. When the InGaN layers 205, 206 are highly relaxed, the In incorporation into InGaN becomes much higher [3,4,5], which is a reason why the peak PL wavelength is 75 nm longer.

Considering the difference in PL intensity, the present invention's method of growing the InGaN MQWs 206 on the InGaN buffer 205 on the TTOTDM improves the crystal quality of the InGaN MQW 206 and lengthens the PL peak wavelength by 75 nm as compared to the reference InGaN MQW grown on the GaN template 202 on, by minimizing composition pulling effects by fully or partially relaxing the InGaN layers 205, 206 on the flexible or compliant GaN decomposition stop layer 204.

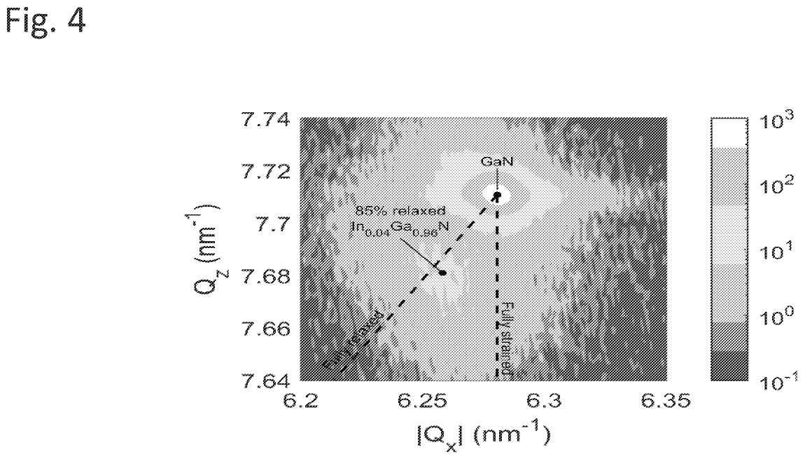

A high resolution x-ray diffraction RSM of the InGaN buffer 205 on the GaN decomposition stop layer 204 of the first growth mentioned in FIG. 2, is shown in FIG. 4, which was taken aligned to an off-axis (-1-124) peak, where the points plotted indicate an 85% relaxed In_{0.04}Ga_{0.96}N layer. The In composition of the InGaN buffer 205 was 4% and it was confirmed that the in-plane lattice constant of the InGaN buffer 205 was 85% biaxially relaxed. Here, relaxed means that the in-plane lattice constant or strain are relaxed.

When InGaN layers are more relaxed, the In incorporation rate into InGaN becomes much higher due to the minimization of composition pulling effects. That is a reason why the peak wavelength is 75 nm longer. Also, the peak intensity of PL is three times stronger than that of the reference InGaN MQW grown on the GaN template 202, as shown in FIG. 3(b). This is caused by the improved crystal quality of the InGaN MQW 206, because the InGaN MQW 206 is grown on the relaxed InGaN buffer 205 to minimize the lattice mismatch. Using the present invention, the crystal quality of InGaN, AlGaN or AlInGaN is improved by almost three times.

The inventors have never heard of a green PL intensity for InGaN layers that is three times stronger than a blue PL intensity for InGaN layers, because crystal quality becomes worse by increasing the In composition of the InGaN layers to change the PL emission peak wavelength from blue to green due to a large strain caused by a large lattice mismatch between GaN and InGaN. It is believed that this is the first report of green PL intensity that is stronger than blue PL intensity under the same growth conditions.

Pasayat et al. [3] reported the green PL intensity of relaxed InGaN on porous GaN is weaker than that of an InGaN MQW on a GaN template. Their crystal quality of relaxed InGaN is worse than that of InGaN on a conventional GaN template with a large strain. In this invention, the strong green emission of PL is observed in the whole area on half of the 2-inch substrate, as shown in sample #2. This is a big difference in comparison with the conventional porous GaN method, wherein the relaxed region is less than 10 μm×10 μm [3,4].

Considering these results, the present invention is much better than the conventional porous GaN method in view of: (1) much better crystal quality (as evidenced by the PL intensity being three times greater): (2) 85% biaxial relaxation is a much higher relaxation: (3) relaxed over the whole growth area on the 2-inch substrate; and (4) low cost using a simple process.

Moreover, it is anticipated that, when the In composition of the InGaN MQW 206 is increased further, for example, the wavelength would shift from green to the red region. This would enable fabrication of high efficiency, red light emitting, III-nitride based LEDs or LDs using present invention on the whole area of a substrate.

After growing the LED or LD structure on or above the decomposition stop layer 204, the total thickness of the n-type layers is preferably less than 1000 nm or more preferably less than 500 nm, due to a limitation on the total thickness of the InGaN layers. However, this is not thick enough to make a highly efficient LED and LD. The thickness of each III-nitride based layer in the LED and LD structure should be less than 1000 nm to be fully or partially relaxed. When the thickness of the InGaN layer is greater than 1000 nm, the crystal quality becomes poor. The present invention therefore supplements thin n-type and p-type III-nitride based layers by depositing a transparent conductive oxide (TCO) on these thin n-type or p-type III-nitride based layers.

Also, the TCO is deposited on the p-type layers to reduce the operating voltage of the LD [6] and LED, and to increase the light extraction efficiency of the LED. In addition, TCO is also used as n-cladding and p-cladding layers for the LED and LD in the present invention [6]. For heat dissipation, mounting the device p-side down is much better, because the main heat generation region is near the device p-side due to the high series resistance and high contact resistance of p-type layer.

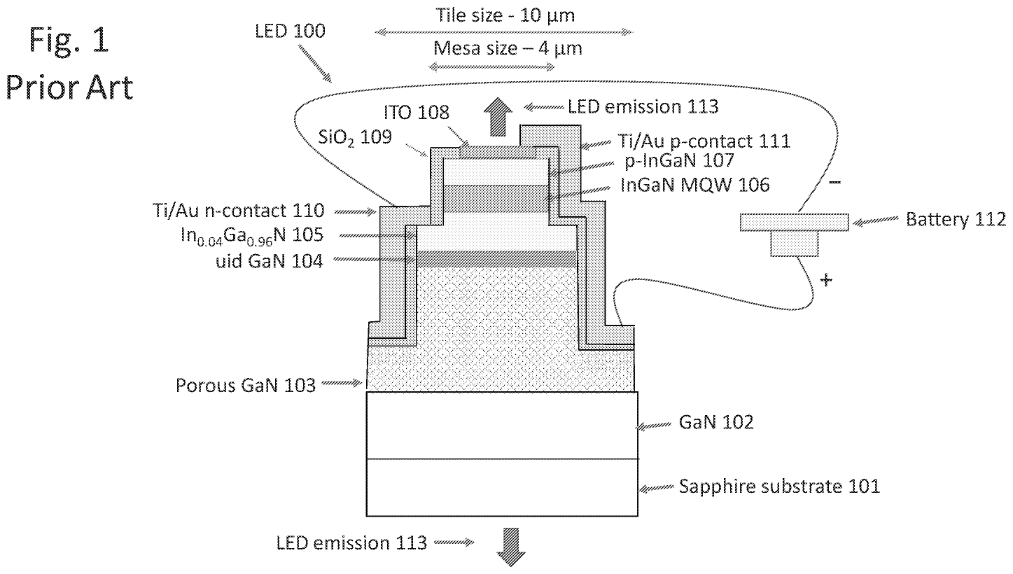

Further, in the present invention, an n-electrode is placed on a top side of the device and a p-electrode is placed on a back side of the device. This results in the chip size of the LED and LD becoming much smaller, because each electrode is on an opposite side of the chip. The prior art typically has both of the electrodes placed on the top side of the device, which results in a larger chip size, as shown in FIG. 1. For micro-LED displays, a smaller chip size helps to reduce cost [1].

The present invention demonstrates the planar growth of III-nitride based LEDs, LDs or any device, comprised of layers 205, 206 on or above the decomposition stop layer 204 on the decomposed decomposition layer 203 on a GaN template 202 on a 2 inch sapphire substrate 201. Any substrate with any sizes 201 may be used, such as sapphire, SiC, GaN, AlN, Si and others.

Pasayat et al. [3,4] found that the relaxation of InGaN layers grown on porous GaN is larger when the tile size is smaller. Their conclusion is that the tile size should be smaller than 10 μm×10 μm to obtain the highest relaxation (40˜50% relaxation) [3]. This invention, on the other hand, uses an almost free-standing and compliant layer of a decomposition stop layer 204 on a decomposed decomposition layer 203. It is expected that the relaxation of the present invention will be much higher than that of InGaN layers grown on porous GaN. As mentioned above with regard to FIGS. 2, 3(a) and 3(b), it has already been confirmed that the InGaN layers grown 205, 206 on the decomposition stop layer 204 on the decomposed decomposition layer 203 of the present invention is 85% biaxially relaxed using X-ray measurements. Also, as mentioned above, the PL measurement results of FIG. 3(b) show that the relaxed InGaN 205, 206 on or above the decomposition stop layer 204 has a much higher relaxation (80˜85%) across the whole area of the InGaN layer 205, 206 grown on 2-inch substrate. Using the present invention, the whole area of any sizes of substrates and any kinds of substrates could be used to make any devices using conventional device processing and growth methods by inserting the decomposition and decomposition stop layers, because the device structure is not separated from the decomposition layer after the growth and during the device processing.

Next, this disclosure describes the experimental results of red LEDs grown on the decomposition stop layer grown on the decomposed decomposition layer.

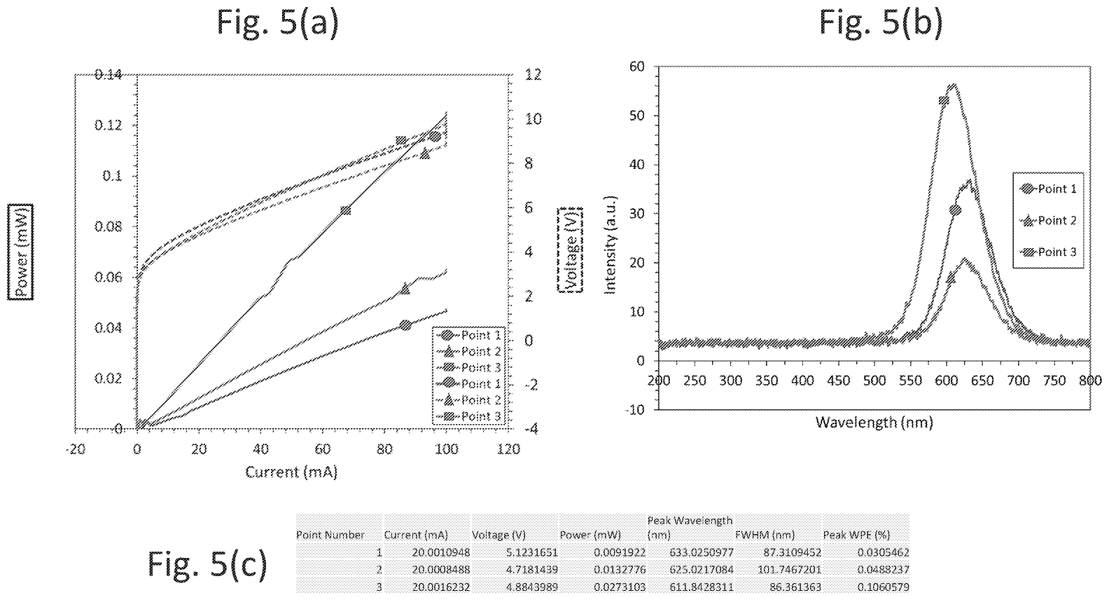

FIGS. 5(a), 5(b) and 5(c) show the QT measurement results of the longest wavelength LED with a peak emission wavelength of 633 nm at a current density of about 20 A cm⁻² using a 100 nm thick GaN decomposition stop layer.

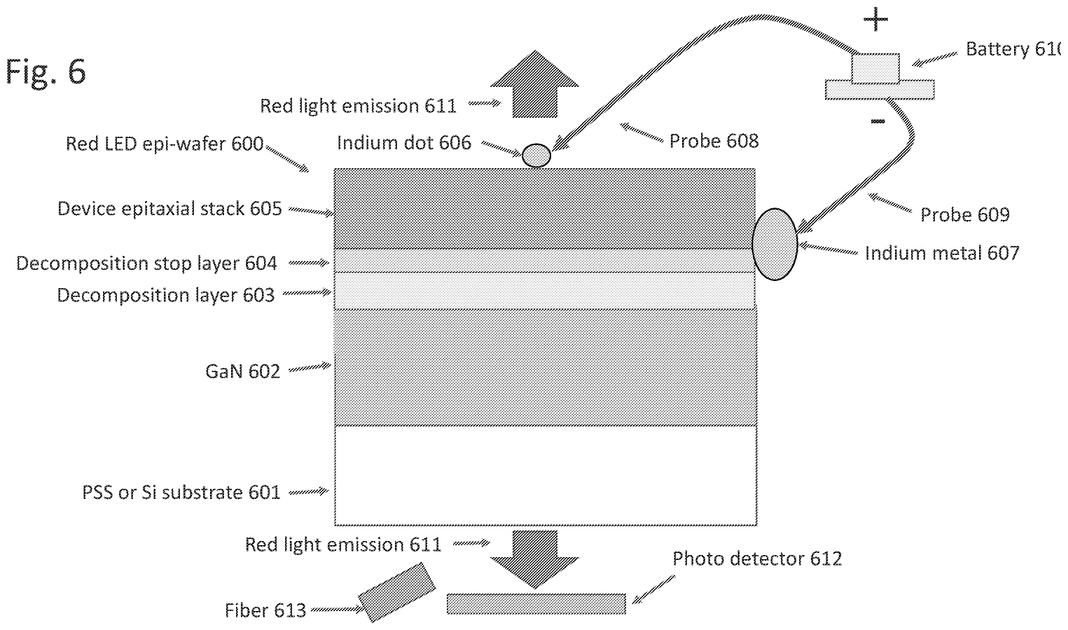

FIG. 6 is a schematic that illustrates the QT measurement arrangement for an LED structure 600 on an epitaxial wafer, which was used for the results in FIGS. 5(a), 5(b) and 5(c).

The LED structure 600 and growth conditions are as follows. First, a PSS or Si substrate 601 was provided, and a 4 μm thick GaN template 602 was grown on or above the substrate 601. A 3 nm In_{0.3}Ga_{0.7}N decomposition layer 603 was grown at a temperature of 750° C. on the GaN template 602. A 100 nm thick Si-doped n-GaN decomposition stop layer 604 was grown on or above the decomposition layer 603, wherein 30 nm was grown at 750° C. and 70 nm was grown while ramping the temperature from 750° C. to 1000° C.

A device epitaxial stack 605 was grown on or above the decomposition stop layer 604. The epitaxial device stack 605 is comprised of a 300 nm thick Si-doped n-InGaN buffer (comprised of 8 periods of a superlattice (SL) of 8×35 nm thick In_{0.04}Ga_{0.96}N/2 nm thick GaN) grown at a temperature of 920° C., followed by an active layer comprising an InGaN multi quantum well (MQW) (4×2.5 nm QWs/5 nm GaN barriers) grown at a temperature of 800° C., wherein, considering the LED emission wavelength, the Indium (In) composition of the MQW is about 30˜50%. Then, a 100 nm Mg-doped p-type InGaN/GaN SL and a 12 nm p++In_{0.05}Ga_{0.95}N layer were grown on or above the active layer at a temperature of 920° C. In FIG. 6, the device epitaxial stack 605 includes all of the layers from the 300 nm n-InGaN buffer to the p++ layer.

In the red LED 600 growth, the total device growth was done continuously from the GaN template 602 to the device epitaxial stack 605 without taking the sample from the MOCVD system, which is different from a conventional porous GaN method, as well as nanowire and nanorod methods [3,4,7,8]. As several companies are selling GaN templates grown on various substrates, such as sapphire, PSS, Si, SiC and others, with various sizes of the substrates ranging from 2 inches to 12 inches, the device epitaxial stack 605 could be grown on GaN templates purchased from these companies. Here, continuous growth means including the device epitaxial stack 605 on GaN templates purchased from those companies. The growth for the experimental results described herein also used a purchased GaN template 602 grown on a PSS substrate 601 to grow the device epitaxial stack 605 on the GaN template 602 in order to save time.

In the conventional porous GaN method, as well as the nanowire and nanorod methods, the epitaxial wafer has to be taken out from the MOCVD system to form the porous GaN, nanowire or nanorod, in a clean room, and then the device structure is regrown by MOCVD. In the view of the cost of the growth process, the present invention is much cheaper than the conventional porous GaN method, as well as the nanowire and nanorod methods.

After the epitaxial growth, the as-grown epi-wafer was annealed at a temperature of 650° C. for 30 minutes under an air ambient to activate the p-type layers. An indium dot 606 was placed on a surface of the epitaxial wafer, using tweezers to place the indium dot 606 on top of the p++ layer of the epitaxial stack 605 as a p-contact. The contact area of the indium dot 606 on the p++ layer is about 1 mm in diameter, which is determined by the pressure of the tweezers, and thus the contact area is not constant. A large amount of indium metal 607 was also placed on a sidewall of the n-type layers as an n-contact, wherein the indium metal 607 could contact many layers of the sidewall of the epitaxial wafer. The indium metal 607 can make an Ohmic contact only with a high carrier concentration layer of n-type layers of the n-type InGaN buffer of the epitaxial stack 605 or the n-type decomposition stop layer 604. Thus, the current flow is only through the n-type layers of the n-type InGaN buffer of the device epitaxial stack 605 or the n-type decomposition stop layer 604.

A probe 608 was attached to the indium dot 606 to flow a current of 20 mA, and another probe 609 was attached to the large indium metal 607 to flow the current of 20 mA between the probe 608 and the probe 609. A battery 610 or other electrical source provided the 20 mA current flow between the indium dot 606 as the p-contact and the indium metal 607 as the n-contact and, and red light emission 611 was output from both the front and back sides of the LED structure 600. The output power of the red light emission 611 was measured from the backside of the LED structure 600 using an Si photo-diode as a photo detector 612 and the spectrum of the red emission 611 was measured through a fiber 613 that was connected to a spectrum analyzer (not shown).

The current density of the QT measurement was determined by the current of 20 mA divided by the contact area of the indium dot 606, and thus the current density of the QT was not constant. The 20 mA forward current of the QT measurement is almost equal to the current density of about 20-50 A cm⁻² as discussed below in a comparison with the peak emission wavelength of a fabricated LED. The forward voltage of the QT measurement was also not accurate due to the current density fluctuation of 20-50 A cm⁻².

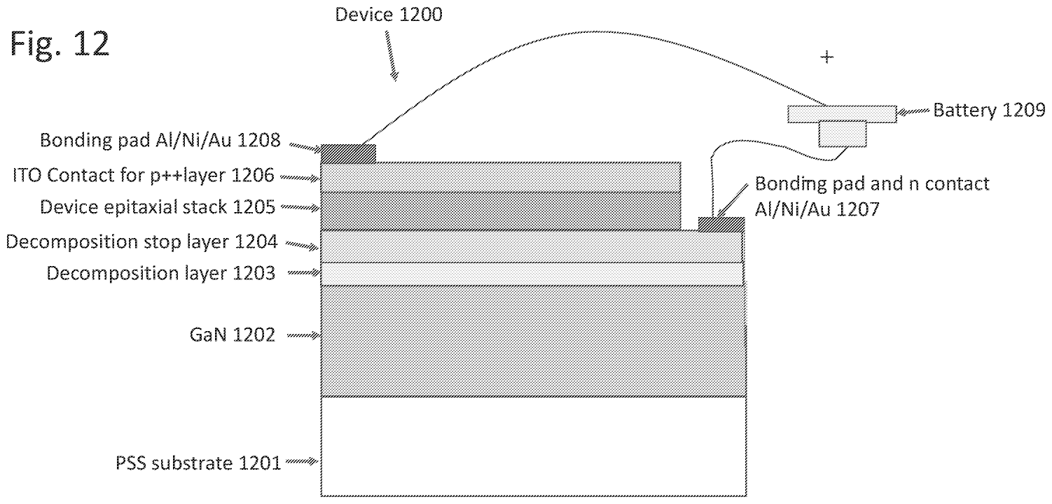

To measure the uniformity of the 2-inch epitaxial wafer, three points were measured by placing the indium dot 606 at each point, with the three points comprising the following: point 1: center; point 2: ½ radius: point 3: edge. The QT was used to evaluate the red LED structure 600 immediately after the MOCVD growth. About one hour after the MOCVD growth, the QT results with some fluctuations of the current density were obtained, and those results of the output power, forward voltage and emission spectra were used for the next MOCVD growth, with fast feedback of the results. The fabrication of the LED device (for example, as shown in FIG. 12 below) usually takes 4˜7 days to obtain accurate data, and thus such accurate data could not be used as fast feedback for the next MOCVD. Moreover, the QT was performed using the as-grown epitaxial wafer and LED structure 600 without any additional device processing, although, after the QT, device processing can be performed in a clean room after removing the indium dot 606 and indium metal 607 using an acid solution.

By using the GaN decomposition stop layer 604, the longest peak emission wavelength of the red LED 600 was 633 nm. When the inventors attempt a longer wavelength more than about 630 nm, the strain becomes more than the critical strain between the GaN decomposition stop layer 604 and the InGaN buffer, and the lattice seems to be broken. In order to obtain the longer wavelength, the decomposition stop layer 604 was changed from 100 nm thick GaN to a 100 nm thick In_{0.04}Ga_{0.96}N/GaN SL.

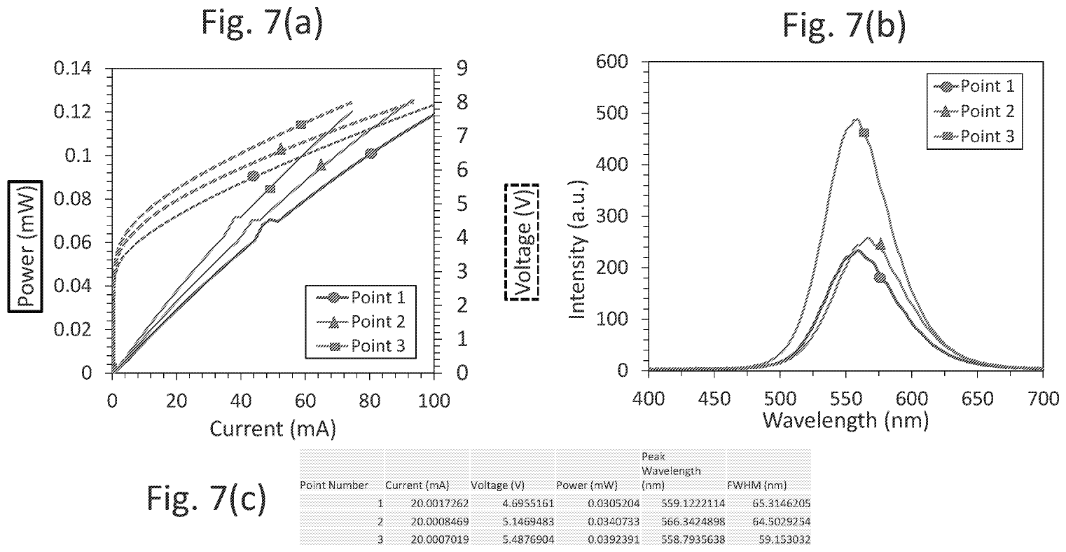

FIGS. 7(a), 7(b) and 7(c) show the QT results of the reference red LED with the GaN decomposition stop layer. The LED structure and growth condition is the same as described in FIG. 6, except for a 66 nm n-type InGaN buffer comprised of 3 periods of an SL of 3×20 nm thick In_{0.04}Ga_{0.96}N/2 nm thick GaN grown at a temperature of 920° C., an InGaN MQW grown at a temperature of 825° C., a p-type 88 nm SL comprised of 4×20 nm In_{0.04}Ga_{0.96}N/2 nm thick GaN, and a 12 nm p++InGaN grown at a temperature of 920° C. The peak emission wavelength shown in FIG. 7(b) is from 558 nm to 566 nm at 20 mA, which wavelengths are shorter than those of LED mentioned in FIG. 6. The main reason is that the growth temperature of the InGaN MQW was increased from 800° C. to 825° C. When the growth temperature is higher, there is less indium corporation into InGaN.

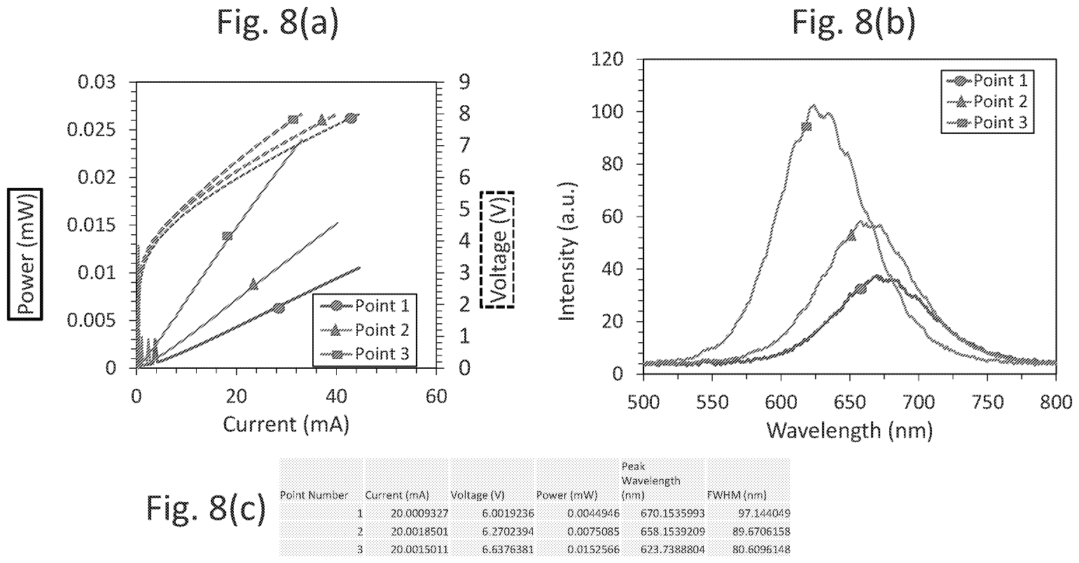

FIGS. 8(a), 8(b) and 8(c) show the QT results of a red LED with a 100 nm thick 10×7 nm In_{0.04}Ga_{0.96}N/3 nm GaN SL decomposition stop layer grown at a temperature of 920° C. The LED structure and growth condition are same as the reference LED mentioned in FIGS. 7(a), 7(b) and 7(c), except for a 3 nm InGaN decomposition layer grown at a temperature of 700° C. (with an additional 2 nm GaN cap grown at a temperature of 700° C. and a 2 nm GaN cap grown at a temperature of 810° C.), an n-type 100 nm thick decomposition stop layer comprised of 10×7 nm In_{0.04}Ga_{0.96}N/3 nm GaN SL grown at a temperature of 920° C., and a 110 nm n-type InGaN buffer comprised of 5×20 nm thick In_{0.04}Ga_{0.96}N/2 nm thick GaN at a temperature of 920° C. The growth temperature of the decomposition stop layer was reduced from 1000° C. to 920° C. because the growth temperature of InGaN is lower than that of GaN. The growth temperature of the decomposition layer also had to be reduced from 750° C. to 700° C., because the decomposition layer has to be decomposed at the growth temperature of the decomposition stop layer of 920° C.

FIG. 8(b) shows the peak emission wavelength is from 623 nm to 670 nm at 20 mA, which is much longer than those (558˜566 nm) of the LEDs of FIG. 7(b). The main reason why the emission wavelength is much longer is due to the InGaN/GaN SL decomposition stop layer grown at a low temperature of 920° C., because the growth temperature of the InGaN MQW is same for both LEDs of FIGS. 7 and 8. Conventionally, the peak emission wavelength of III-nitride LED is mainly determined by the growth temperature of the InGaN QW.

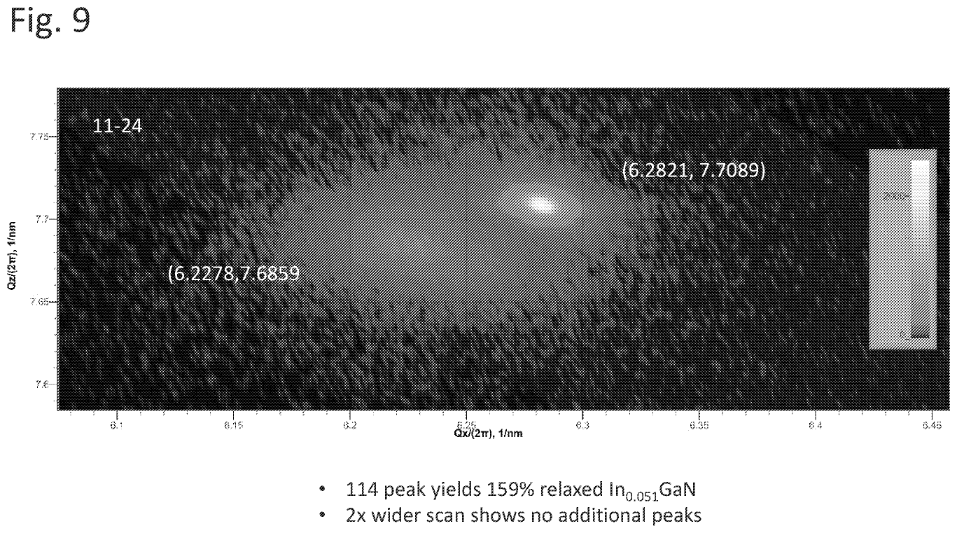

A high resolution x-ray diffraction RSM of the InGaN buffer on the InGaN/GaN decomposition stop layer mentioned in FIG. 8 is shown in FIG. 9, which was taken aligned to the off-axis (-1-124) peak, wherein the points plotted indicate an 159% relaxed In_{0.05}Ga_{0.95}N layer assuming that InGaN buffer layer is grown on a GaN template, although the InGaN buffer layer is grown on an InGaN/GaN SL decomposition stop layer. In FIG. 9, the inventors could observe only the signals of the GaN and relaxed In_{0.05}Ga_{0.95}N peaks. That is a reason why the inventors assume a 159% relaxed In_{0.05}Ga_{0.95}N buffer layer by assuming that the InGaN buffer layer or the decomposition stop layer is grown on a GaN template. The In composition of the InGaN buffer including the decomposition stop layer has a similar In composition of 5%. Based on those assumptions, the in-plane lattice constant of the InGaN buffer including the InGaN/GaN SL decomposition stop layer is considered to be 159% biaxially relaxed, which value is much higher than the 85% relaxation of FIG. 4 for the LED with the GaN decomposition stop layer. The value of 159% relaxation of planarly grown InGaN is the highest ever reported. Here, relaxed means that the in-plane lattice constant or strain are relaxed. That is a reason why the emission wavelength of red LEDs of FIG. 8 is much longer than that of FIG. 7. When the InGaN buffer is more relaxed, the composition pulling effects are minimized and the indium corporation into the InGaN MQW becomes much higher [5].

A 100 nm InGaN/GaN SL decomposition stop layer was mentioned to increase the emission wavelength. An InₓGa₍₁₋ₓ₎N(0≤x≤1) decomposition stop layer with a thickness of 10˜100 nm instead of an SL was also considered to work for increasing the peak emission wavelength by relaxing the InGaN buffer further. When the InGaN buffer uses the same InGaN/GaN SL used for the decomposition stop layer, there is no interface between the InGaN buffer and the decomposition stop layer. In this case, it is difficult to find the real thickness of the decomposition stop layer and the InGaN buffer.

The inventors like to define the decomposition stop layer thickness as the decomposition layer is decomposed enough to relax the upper InGaN buffer while the decomposition stop layer is grown. It means that the decomposition stop layer thickness is dependent on how easily the decomposition layer could decompose. If the decomposition layer easily decomposes, the decomposition stop layer thickness is small, assuming that the growth rate of the decomposition stop layer is constant. Thus, it is difficult to determine the thickness of the decomposition stop layer. Also, after growing the decomposition stop layer, the temperature is increased to higher than the temperature used for the decomposition stop layer to decompose the decomposition layer. In this case, the decomposition layer dose not decompose while the decomposition stop layer is growing.

Instead of above-mentioned InGaN/GaN SL decomposition stop layer, an InGaN decomposition stop layer with a thickness of 2˜300 nm could be used. The important thing is that the decomposition stop layer has to include at least indium to obtain the longer peak emission wavelength of more than 630 nm at a growth temperature of 800˜950° C.

Also, with regard to AlGaN growth, an AlₓGa₍₁₋ₓ₎N/AlyGa_{(1-y)}N (x≠y, 0≤x≤1, 0≤y≤1) SL, AlₓGa₍₁₋ₓ₎N(0≤x≤1)/GaN SL or AlₓGa₍₁₋ₓ₎N (0≤x≤1) layer, with a thickness of 2˜300 nm would be best as the decomposition stop layer to relax the AlGaN layer grown on or above the decomposition stop layer.

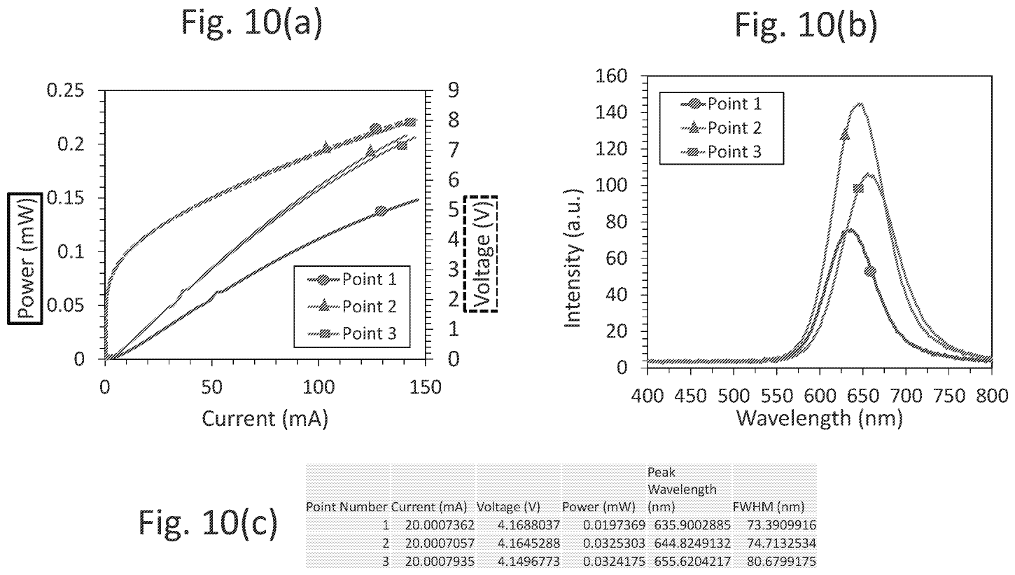

FIGS. 10(a), 10(b) and 10(c) show the QT test results of the highest temperature growth of an InGaN MQW of a red LED at a temperature of 870° C., with a peak emission wavelength from 635 nm to 655 nm, which is the highest temperature growth of an InGaN MQW of a red LED ever reported. Conventionally, an InGaN MQW of a red LED with an emission wavelength from 610 nm to 630 nm grown on a GaN template with a large compressive strain has been grown at a temperature around 750° C. [3,4, 6-9]. The crystal quality of the InGaN layer becomes better with the increasing growth temperature. That is a reason why the FWHM is as narrow as 73˜80 nm with a peak emission wavelength of 635˜655 nm using present invention. Also, a peak emission wavelength longer than those (610˜630 nm) of conventional red LEDs is obtained despite the about 120° C. higher growth temperature of the InGaN MQW.

The LED structure and growth conditions of the red LEDs of FIGS. 10(a), 10(b) and 10(c) are as follows. The LED structure and growth condition are same as the LED mentioned in FIG. 8 except for a 100 nm thick n-type decomposition stop layer comprised of a 5×18 nm In_{0.04}Ga_{0.96}N/2 nm GaN SL grown at a temperature of 930° C., a 110 nm n-type InGaN buffer comprised of 5×20 nm thick In_{0.04}Ga_{0.96}N/2 nm thick GaN SL grown at a temperature of 900° C., an InGaN MQW with 2.5 nm thick QWs, 6 nm GaN barriers and 8 QWs grown at a temperature of 870° C., a 10 nm thick p-Al_{0.3}Ga_{0.7}N electron blocking layer (EBL) grown at a temperature of 920° C., and a 80 nm p-GaN/12 nm p++GaN layer grown at a temperature of 920° C. The operating voltage of 4.1 V at 20 mA of the QT in FIG. 10(a) is relatively low in comparison with other samples. This would be due to the low series resistance of the 80 nm p-GaN/12 nm p++GaN layer grown at a temperature of 920° C. and also due to the high temperature growth of the InGaN MQW. The EBL was also inserted into the p-type layers.

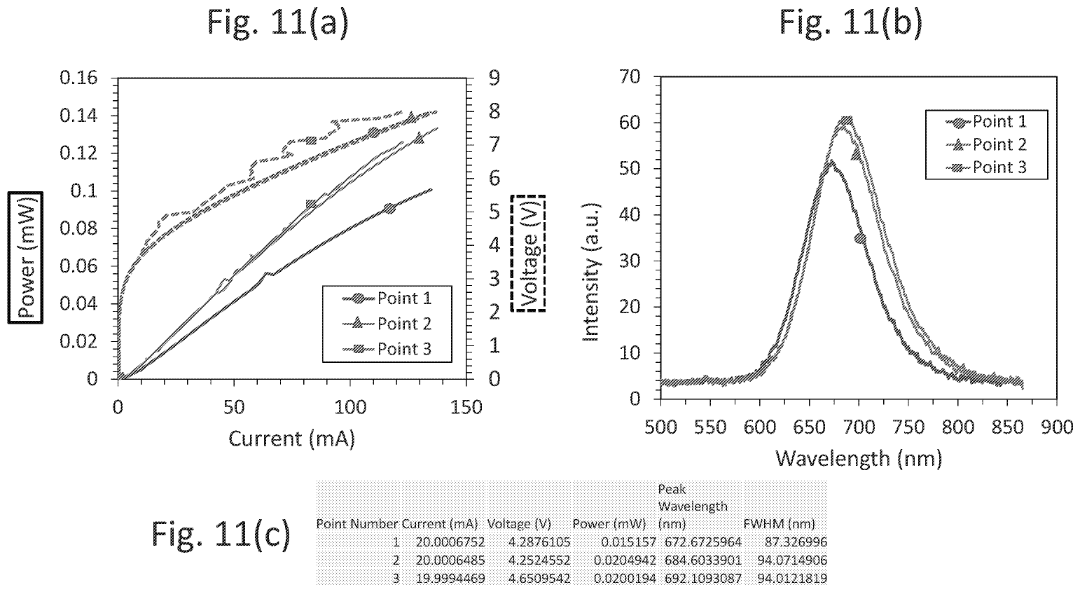

FIGS. 11(a), 11(b) and 11(c) show the QT results of the longest peak emission wavelength of 672˜692 nm of a near-infrared LED, which is the longest wavelength ever reported for a III-nitride based LED. The LED structure and growth conditions of the LEDs in FIG. 11 are same as the LED mentioned in FIGS. 10, except for an InGaN MQW grown at a temperature of 850° C., a GaN barrier with a small amount of Indium, and 30 nm p-GaN/20 nm p++GaN layers grown at a temperature of 920° C.

By reducing the growth temperature from 870° C. to 850° C., reducing the total thickness of the p-GaN layers from 92 nm to 50 nm, and using an InGaN barrier instead of a GaN barrier, the emission wavelength becomes longer. When the inventors insert a GaN or AlGaN layer, the peak emission wavelength becomes shorter, because GaN or AlGaN causes compressive strain. When InGaN layers are used, the peak emission wavelength becomes longer, because InGaN layers cause tensile strain. The inventors wanted to minimize the usage of GaN or AlGaN to make a long wavelength LED and LD. The total thickness of the p-layers should be less than 60˜50 nm to reduce the forward voltage and to increase the emission wavelength.

FIG. 12 shows the fabricated red LED device structure 1200, which includes a patterned sapphire substrate (PSS) 1201, GaN layer 1202, decomposition layer 1203, decomposition stop layer 1204, and device epitaxial stack 1205. After red LED epitaxial wafer growth by MOCVD, p-type layers are activated by thermal annealing at 650° C. for 30 minutes under an air ambient. Then, an ITO for the p++ layer 1206 is deposited on the structure 1200. Next, mesa etching using a photo mask is performed in a depth between an n-InGaN buffer and the n-decomposition stop layer 1204 to form an n-contact 1207. Then, after removing the mask, Al/Ni/Au is deposited on the ITO layer 1206 as a bonding pad 1208 for wire bonding and is also deposited on the InGaN buffer or decomposition stop layer 1204 depending on the mesa etching depth as the n-contact and bonding pad 1207. A bias was applied from a battery 1209 or other electrical source, and the emission spectra, outpower and I-V curve were measured on the wafer. The emitting area of the red LED 1200 is 0.1 mm². A 20 mA forward current results in a 20 A cm⁻² current density.

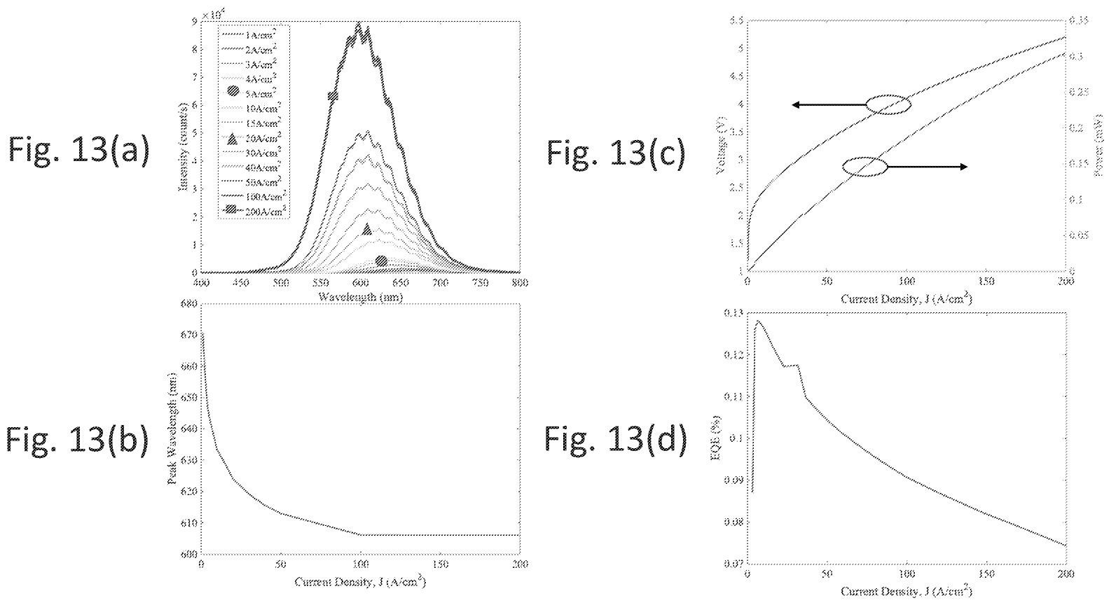

FIGS. 13(a), 13(b), 13(c) and 13(d) show the emission spectra, peak emission wavelength, light output power (L) and forward voltage (V), and the external quantum efficiency (EQE), respectively, as a function of the current density (J), for the fabricated LED shown in FIG. 12 without packaging. As mentioned above, the QT results are not reliable on current density due to the unstable indium dot contact area. The fabricated LED shows the exact current density in order to compare with other groups' results. The output power measurement was performed from only the top side. The output power and the EQE could be doubled by including the bottom side emission of the LED. The fabricated LED has no package (no epoxy molding). When the fabricated LED on the wafer is packaged with epoxy molding, the light output power and the EQE almost doubled by increasing the light extraction efficiency. The peak EQE of the red LED of FIG. 13(d) is about 0.13%. After packaging, the EQE of the red LED of FIG. 13 would become about 0.5%. Additional efforts are needed to optimize the red LED growth conditions and device fabrication process to improve the EQE and light output power further.

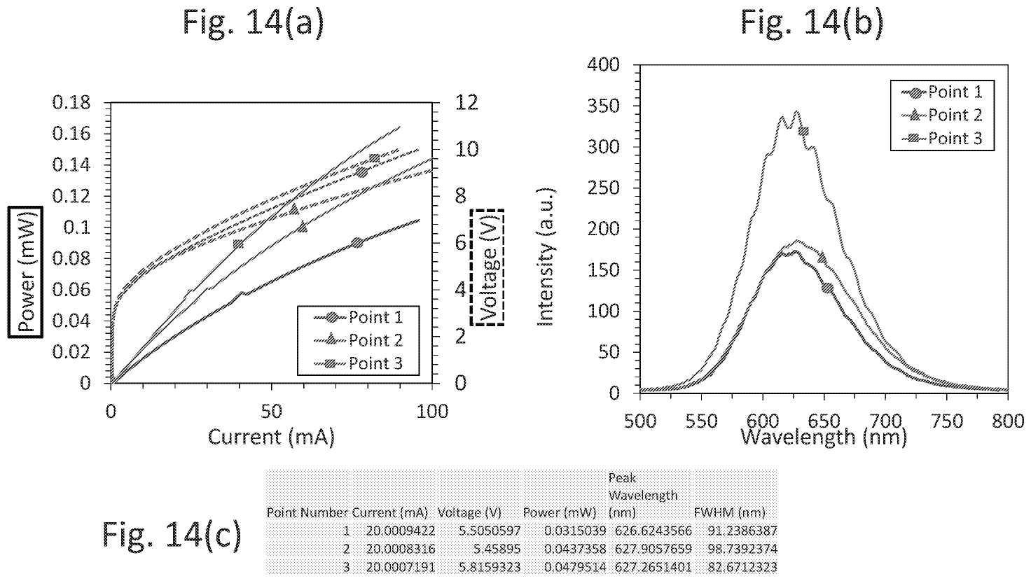

FIGS. 14(a), 14(b) and 14(c) show the QT measurement results of the same epi-wafer as FIG. 13. The peak emission wavelength of the QT is 626˜627 nm at 20 mA. In FIG. 13(a), at 20 A cm⁻², the peak emission wavelength is around 626 nm. Thus, 20 mA of the QT corresponds to the current density of about 20 A cm⁻² in FIG. 13. In order to compare the QT results of the emission wavelength of red LED grown by this invention with other groups' results, the inventors have to compare it at the current density around 20 A cm⁻².

A Toshiba group reported the best packaged red LED with a peak emission wavelength of 620 nm at a current density of 20 A cm⁻² and a peak EQE of 2.8% by inserting an AlGaN layer between the InGaN QW and GaN barrier. [6]. Pasayat et al., [3] reported a red LED with a peak emission wavelength of 620 nm at the current density of 20 A cm⁻² and the peak EQE of 0.17%. In this invention, the peak EQE of the packaged LED would be about 0.5%, which value is smaller than Toshiba's results due to a lack of optimization and the longer emission wavelength around 626 nm at the current density of 20 A cm⁻². All conventional red LEDs have used an interlayer of AlGaN between the InGaN QWs and the GaN or InGaN barriers, since the Toshiba group announced the highest EQE of 2.7% in 2014 [6]. The present invention does not use any interlayers between the InGaN QWs and the GaN or InGaN barriers at all, because the InGaN QWs of this invention are grown under relaxed conditions and no interlayer is required to mitigate the strain between the InGaN QWs and the GaN or InGaN barriers.

For display applications, a III-nitride based red LED should have the peak wavelength longer than 650 nm due to the broad spectrum width (FWHM) of more than 60 nm in order to make a beautiful display [7-8]. Only the present invention could make the III-nitride based red LED with an emission wavelength longer than 650 nm at a current density of more than 10˜20 A cm⁻² as mentioned in FIGS. 8-11. The red LEDs of FIGS. 13 and 14, where the structure and growth condition are the same as the LED mentioned in FIGS. 8, except for the 100 nm thick decomposition stop layer comprised of the 10×7 nm In_{0.04}Ga_{0.96}N/3 nm GaN SL grown at a temperature of 950° C., the 110 nm n-type InGaN buffer comprised of 5×20 nm thick In_{0.04}Ga_{0.96}N/2 nm thick GaN grown at a temperature of 920° C., and the InGaN MQW with 2.5 nm QWs, 7 nm GaN barriers and 8 QWs grown at a temperature of 820° C.

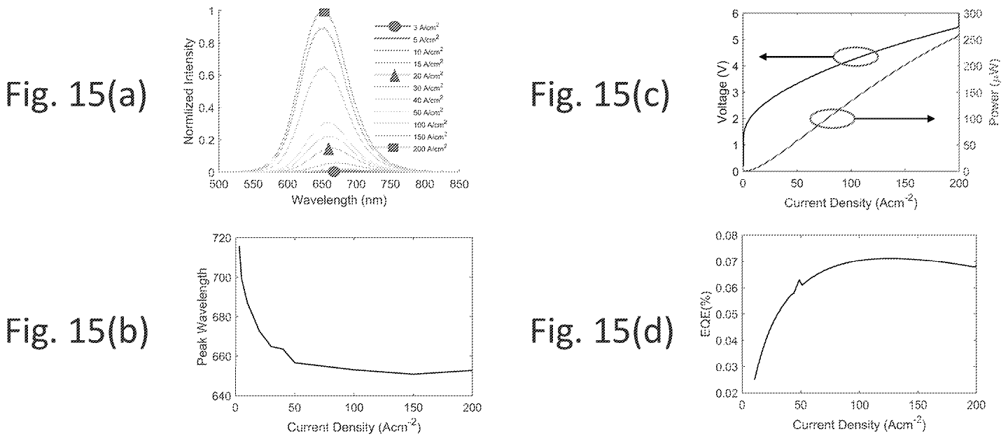

Another experimental result of the long wavelength fabricated red LED on a wafer is shown in FIGS. 15(a), 15(b), 15(c) and 15(d). The peak emission wavelength of the red LED is about 650 nm up to a current density of about 200 A cm⁻². This is the first report of a III-nitride based LED showing a peak emission wavelength of 650 nm at a current density of 200 A cm⁻².

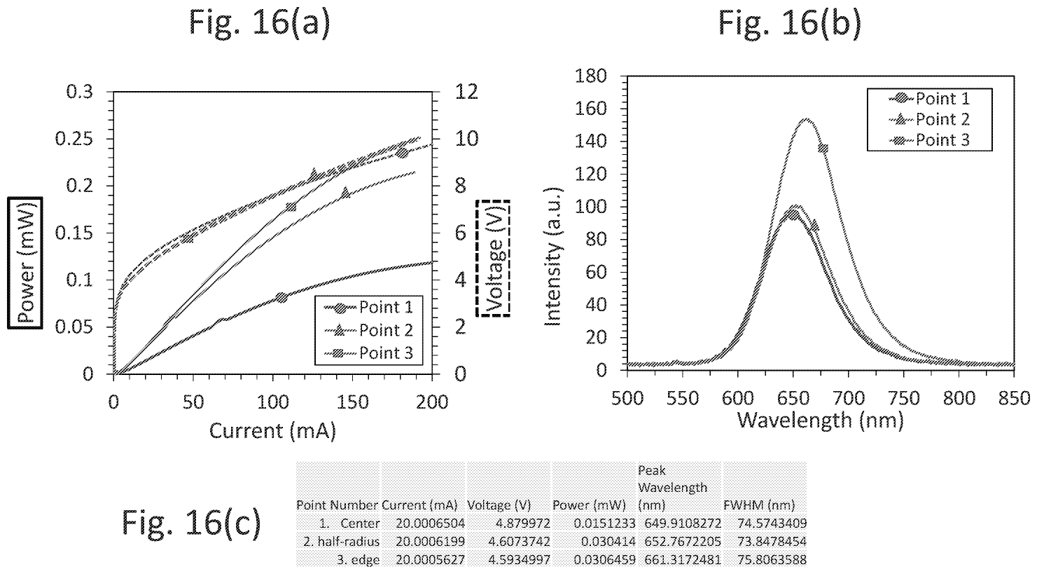

FIGS. 16(a), 16(b) and 16(c) show the QT results of the red LED epi-wafer shown in FIG. 15. The peak emission wavelength of the QT at 20 mA in FIG. 16(b) is around 650˜661 nm, which corresponds to the peak emission wavelength at the current density around 50 A cm⁻² in FIG. 15(a). The current of 20 mA of the QT means a current density of 20˜50 A cm⁻² considering about the results of the red LEDs of FIGS. 13-14 and FIGS. 15-16. The emission spectra of the QT results in FIGS. 5, 7-8, and 10-11 would be a current density around 20˜50 A cm⁻². The red LED in FIG. 11(b) shows a peak emission wavelength around 692 nm at a current density around 20˜50 A cm⁻², which is the longest wavelength ever reported among III-nitride based LEDs. The III-nitride based red LED shows a blue shift of the peak emission wavelength with the increasing current density due to the screening effect of polarization and the band filling effects of the localized states.

The red LEDs of FIGS. 15 and 16, wherein the structure and growth conditions are the same as the LED mentioned in FIGS. 8, except for the 100 nm thick n-type decomposition stop layer comprised of the 10×18 nm In_{0.04}Ga_{0.96}N/2 nm GaN SL grown at a temperature of 930° C., the 110 nm n-type InGaN buffer comprised of 5×20 nm thick In_{0.04}Ga_{0.96}N/2 nm thick GaN grown at a temperature of 920° C., the InGaN MQW with 2.5 nm QWs, 6 nm GaN barriers and 8 QWs grown at a temperature of 850° C., the 10 nm p-Al_{0.3}Ga_{0.7}N EBL, the 88 nm p-SL with 4×20 nm p-InGaN/2 nm p-GaN, and the 12 nm p++InGaN grown at a temperature of 920° C. At the growth temperature of the InGaN QWs at 850° C., it is possible to grow the red LED with an emission wavelength longer than 650 nm.

The above mentioned results are amazing. Conventionally, InGaN QWs of a red LED with an emission wavelength around 610˜620 nm at a current density around 20 A cm⁻² has been grown at the temperature around 750° C. to increase the indium composition to make the red emission. Using present invention, the inventors could increase the growth temperature of the InGaN MQW of the red LED with an emission wavelength around 650 nm at a current density around 20-50 A cm⁻² up to a temperature of 870° C. Using the high temperature growth more than 800° C. for the InGaN MQW, the crystal quality of the InGaN MQW and the reproducibility of the red or far-infrared LED growth becomes much better than those grown at low temperatures around 750° C.

Also, the forward voltage is much lower than that of Toshiba group's red LED [6]. Their forward voltage is 5.8V at a current density of 25 A cm⁻² [6]. In this invention, the forward voltage of the fabricated LEDs in FIGS. 13 and 15 is 2.8 V and 2.5 V, respectively, at the same current density of 25 A cm⁻². The low forward voltage is due to the high temperature growth of the p-type layers owing to the high temperature growth of the InGaN MQW using the present invention. Conventionally, when the InGaN QW is grown at a temperature around 750° C., the growth temperature of the p-type layers should be lower, because the InGaN MQW decomposes during the high temperature growth of p-type layers. Using the present invention, the growth temperature of the InGaN MQW increases up to a temperature of 870° C., which means that a growth temperature of more than 920° C. could be used for the p-type layers to obtain a higher hole concentration by minimizing the decomposition of the InGaN MQW to reduce the forward voltage.

Using different samples, the mesa-etched fabricated LEDs on the wafer were diced by a dicer to make small bare chips for packaging. The bare chip was not separated from the decomposed decomposition layer. Thus, the final packaged LED could be fabricated using the diced bare chip without worrying about the separation from the decomposed decomposition layer. This is very important because the packaged LED could be fabricated using a conventional simple method. Also, many types of devices could be fabricated, such as LEDs, LDs, power electronics, RF devices, detectors, solar cells, and other devices, using conventional growth methods and conventional device processing, because the device is not separated from the decomposed decomposition layer when the device fabricated on wafer is diced. Thus, by inserting the decomposition and decomposition stop layers, and decomposing the decomposition layer, before device growth, conventional device structures and processing can be used. This is a big deal. Also, the present invention of relaxation works for a whole area of the substrate with any size such as 12-inch Si or sapphire substrates.

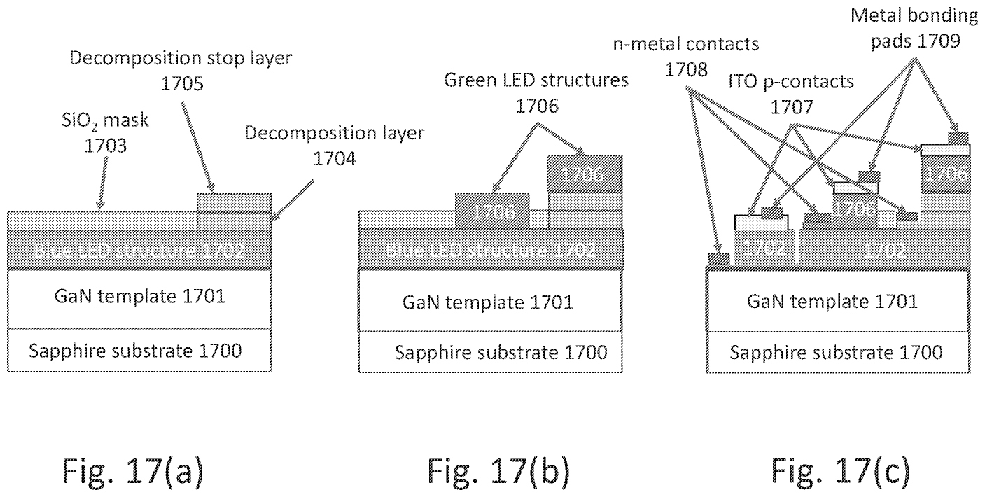

FIGS. 17(a), 17(b), 17(c), 18, 19(a), 19(b) and 19(c) show additional experimental results comprised of monolithic three primary color LEDs for display applications using the present invention. In the past, nobody has demonstrated a real monolithic three-color LED. FIGS. 17(a), 17(b), 17(c) show the structure of the monolithic three primary color LEDs and the growth sequence, starting with a sapphire substrate 1700 and a 4 μm GaN template 1701.

As shown in FIG. 17(a), a blue LED structure 1702 is grown on or above the GaN template. Next, except for a red LED growth region, the blue LED structure 1702 is covered by an SiO₂ mask 1703 using a photo mask. Each LED size of the blue, green and red LEDs was designed with a size of 5×5 μm, 10×10 μm, 20×20 μm, 100×100 μm, respectively, using the photo mask, and each LED is separated by 375 μm. Next, on the window region of the red LED, a 3 nm InGaN decomposition layer 1704 is grown at a temperature of 720° C. (with an additional 2 nm GaN cap grown at a temperature of 720° C. and a 2 nm GaN cap grown at a temperature of 835° C.), and then an n-type 100 nm thick decomposition stop layer 1705 comprised of 10×7 nm In_{0.04}Ga_{0.96}N/3 nm GaN SL is grown at a temperature of 950° C. This is referred to as a first selective area growth (SAG) of the decomposition and decomposition stop layers.

As shown in FIG. 17(b), the SiO₂ mask 1703 is removed from a green LED region and a green LED structure 1706 is grown on a window region of green LED, which is a second SAG, and on the decomposition stop layer 1705 of the red LED, at the second SAG, at the same time. The green LED structure 1706 is comprised of: a 154 nm n-type InGaN buffer comprised of 7×20 nm thick In_{0.04}Ga_{0.96}N/2 nm thick GaN grown at a temperature of 910° C., an InGaN MQW with 2.5 nm QWs, 7 nm GaN barriers and 6 QWs grown at a temperature of 820° C., a 10 nm p-Al_{0.3}Ga_{0.7}N EBL, an 88 nm p-SL with 4×20 nm p-InGaN/2 nm p-GaN, and a 12 nm p++InGaN grown at a temperature of 920° C. After activation of the p-type layers by thermal annealing under an ambient of air, ITO p-contacts 1707 are deposited on whole epi-wafer, and mesa etching is performed according to the size of each LED chip to expose the n-type layers of each LED chip to make n-contacts 1708. Then, Al/Ni/Au is deposited on the exposed n-type layer of each LED chip as n-contacts 1708 and on the ITO contacts 1707 as bonding pads 1709.

The green LED structure 1706 grown directly on top of blue LED structure 1702 has a green emission because the green LED structure 1706 is grown on the p-GaN of the blue LED with a large compressive strain. On the other hand, the emission wavelength of the green LED structure 1706 grown on the decomposition stop layer 1705 on the decomposed decomposition layer 1704 should emit around 620 nm in the red LED growth region because the green LED structure 1706 is grown on a highly relaxed InGaN buffer.

To make the red LED, mesa etching should be performed into the n-InGaN buffer of the green LED structure 1706 or the n-decomposition stop layer 1705, but not into the blue LED structure 1702 or GaN template 1701, because the n-contact metal 1708 should be deposited on the n-InGaN buffer 1706 or the n-decomposition stop layer 1705. If the mesa etching is performed through the decomposed decomposition layer 1704 into the blue LED structure 1702 or GaN template 1701, the n-contact 1708 must be deposited on blue LED structure 1702 or GaN template 1701. In that case, the series resistance becomes very high because the forward current must flow through the decomposed decomposition layer 1704 which has a lot of airgaps.

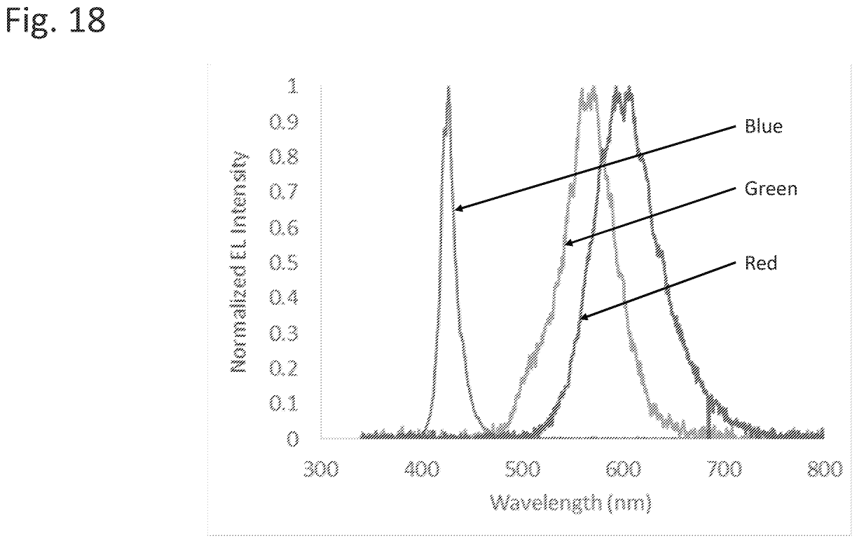

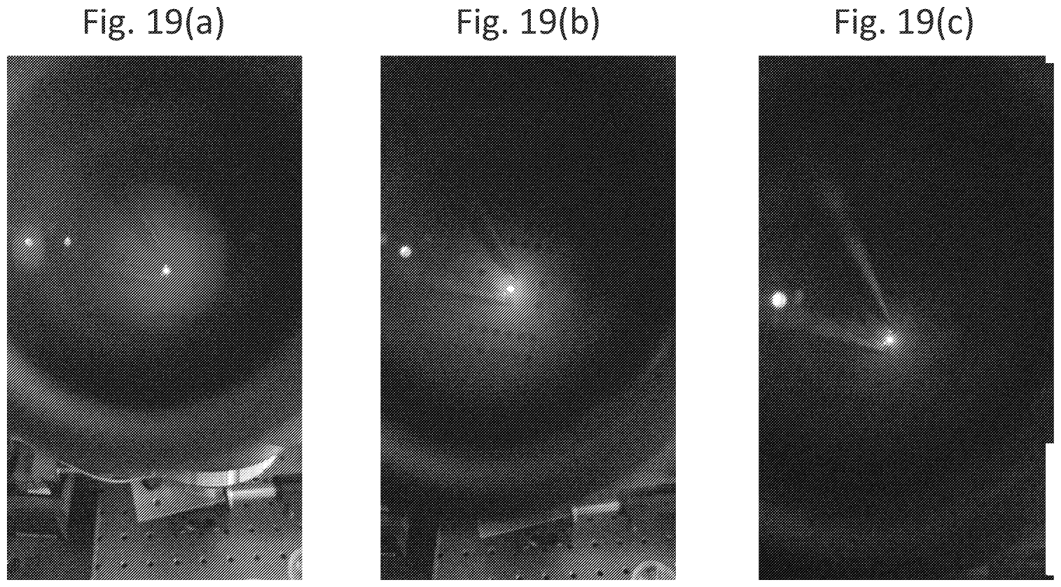

FIG. 18 shows the emission spectra of monolithic three-color LEDs as shown in FIGS. 17, each with a chip size of 20×20 μm and operating at a forward current of 1.5 mA. The peak wavelengths are 427 nm (blue), 565 nm (green) and 603 nm (red). FIGS. 19(a), 19(b) and 19(c) are photo images of the monolithic three-color LEDs as shown in FIGS. 17, each with a chip size of 20×20 μm, and operating at a forward current of 1 mA. The images show blue light emission for FIG. 19(a), green light emission for FIG. 19(b) and red light emission for FIG. 19(c).

The red emission wavelength is a little bit shorter at 603 nm as shown in FIG. 18 and the color looks orange as shown in FIG. 19(c), as compared to the blue emission in FIG. 19(a) and the green emission in FIG. 19(b). This is the first trial of monolithic three-color LED growth, and additional efforts are needed time for optimization. Regardless, this is the first demonstration of monolithic three primary color LEDs or display using III nitride-based materials, because it has been difficult to make red LEDs using the conventional method.

The present invention could open the way to make a simple monolithic micro-LED display in the near future with a cheaper cost by using a large substrate such as 12 inch Si or 6 inch sapphire substrates. This present invention requires only two selective area growths (SAGs) to make a three primary color LED. Conventionally, it required at least three SAGs to make a monolithic three-color LED. Thus, the conventional process has been complicated and costly. That is a reason why nobody could demonstrate the monolithic three primary color LED or display.

Another problem is that the growth of red LEDs has been difficult due to the low temperature growth of InGaN QWs at a temperature around 750° C. Using the present invention, one could easily grow red LEDs with a high reproducibility and high yield on a full substrate because the InGaN QWs are grown at high temperatures of more than 800° C. That is a reason why this invention demonstrates the first monolithic three primary color LEDs for displays.

The present invention also works for AlGaN and AlInGaN when fabricating UV LEDs and other electronic devices, such as HEMTs, power devices and RF devices. In that embodiment, the decomposition layer is InGaN, AlGaN or AlInGaN with a thickness preferably less than 10 nm or more preferably less than 5 nm. First, AlN is grown on a sapphire or AlN substrate. Then, a decomposition layer of GaN or AlGaN is grown with a thickness of 1˜5 nm at temperatures of 1000˜1200° C. Next, a decomposition stop layer of AlN or AlGaN is grown with a thickness of 100 nm at temperatures of 1000˜1600° C. is grown. After the growth, the decomposition layer is thermally decomposed for 1˜10 minutes at a temperature of 1200˜1600° C. Also, on the GaN template grown on sapphire or Si, InGaN decomposition layer is grown around 750° C. and then, AlGaN or AlInGaN decomposition stop layer is grown around 900˜1200° C. During the high temperature growth of the decomposition stop layer, the InGaN decomposition layer is decomposed. Next, AlGaN or AlInGaN based device structure is grown including AlGaN or AlInGaN buffer on or above the decomposition stop layer.

As with the InGaN case, thin decomposition layers are better. When the decomposition layers are thick, the decomposition stop layer can peel off from the substrate after the decomposition process at a high temperature during the MOCVD growth. The decomposition stop layer is AlInGaN or AlGaN with a thickness of 20˜200 nm, because the decomposition stop layer should be flexible or compliant after the decomposition process to obtain the relaxed AlInGaN or AlGaN layers grown on or above the decomposition stop layer. A UV-LED or other structure is then grown on or above the decomposition stop layer. An active layer comprising an AlGaN or AlInGaN MQW could obtain a higher Al or In incorporation ratio due to the relaxed AlGaN or AlInGaN layers, including the relaxed AlGaN or AlInGaN MQW grown on above the decomposition stop layer.

Here, any n-type layer or any p-type layer is a part of the device structure. For example, an n-type InGaN buffer or n-type AlGaN buffer on or above the decomposition stop layer is a part of the device structure of the LED, LD and any kind of device, because the n-type InGaN or n-type AlGaN buffer layer is doped by donors such as Silicon (Si) to become n-type to work as a part of the semiconductor device. For the examples of LEDs and LDs, the n-type InGaN or n-type AlGaN buffer layer work as an n-type cladding layer and or n-contact layer. When the decomposition stop layer is an n-type decomposition stop layer, the n-type decomposition stop layer is a part of the device structure of the LED, LD and any kind of device, because the n-type decomposition stop layer is doped by donors such as Silicon (Si) to become n-type to work as a part of the semiconductor device. For the examples of an LED and LD, the n-type decomposition stop layer works as a n-type cladding layer and or n-contact layer.

On InGaN based device structures, all of the InGaN layers should be InGaN/GaN or InₓGa₍₁₋ₓ₎N/In_{y}Ga_{(1-y)}N(1≥x≥0, 1≥y≥0, x≠y) SL to improve the crystal quality of InGaN layers. On AlGaN based device structure, all of the AlGaN layers should be AlGaN/GaN or AlₓGa₍₁₋ₓ₎N/Al_{y}Ga_{(1-y)}N(1≥x≥0, 1≥y≥0, x≠y) SL to improve the crystal quality.

### Light-Emitting Diode Structure

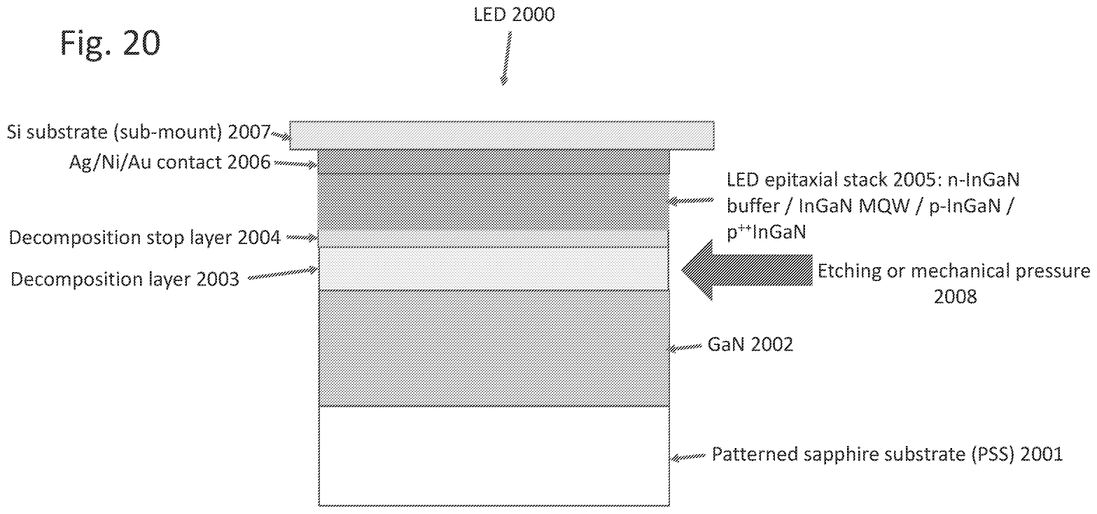

FIG. 20 illustrates a light-emitting diode (LED) 2000 according to a first embodiment of the present invention. In fabricating the LED 2000, a patterned sapphire substrate (PSS) 2001 is provided and a 3 μm thick undoped GaN template 2002 is grown on the sapphire substrate 2001. A decomposition layer 2003, comprising a 2.5 nm thick InGaN layer, is grown on or above the GaN layer 2002 at a growth temperature of 750° C., followed by growth of decomposition stop layer 2004, comprising a 100 nm thick n-type AlₓGa₍₁₋ₓ₎N layer (0≤x≤1), at a growth temperature of 1000° C. During the growth of the decomposition stop layer 2004 at the high temperature of 1000° C., the decomposition layer 2003 is decomposed into In or Ga metal or an alloy of In and Ga metal and Nitrogen gas. As a result, the decomposition stop layer 2004 becomes almost free-standing, as a flexible compliant and freely relaxed layer. An LED epitaxial stack 2005 is grown on or above the decomposition stop layer 2004, wherein the LED epitaxial stack 2005 is comprised of at least an n-InGaN buffer, which works as a cladding layer or n-contact layer of the LED, InGaN MQW, p-InGaN, p++InGaN. (In the case of a UV LED, the InGaN is replaced with AlGaN.)

The n-InGaN buffer of the LED epitaxial stack 2005 is an n-type InₓGa₍₁₋ₓ₎N layer (0.01≤x≤0.5) grown with a thickness preferably less than 1000 nm and more preferably less than 500 nm. It is difficult to grow a thick n-type InₓGa₍₁₋ₓ₎N layer (0.01≤x≤0.5) and keep the crystal quality high, which is a reason why the thickness of the n-InGaN buffer is less than 1000 nm. Also, this n-InGaN buffer should be fully relaxed or partially relaxed [3,4].

The InGaN MQW of the LED epitaxial stack 2005 is an active region. The In composition of the InGaN MQW and its growth temperature are determined by a desired emission wavelength of the LED. The InGaN MQW is grown on the relaxed InGaN buffer of the LED epitaxial stack 2005. Thus, the In incorporation is much higher than an InGaN MQW grown on non-relaxed InGaN at the same growth temperature. Also, the InGaN MQW will be relaxed.

An Mg-doped p-type AlₓGa₍₁₋ₓ₎N layer (0≤x≤1) (not shown) that is an electron blocking layer (EBL) with a thickness of about 5˜40 nm may be grown on or above the InGaN MQW.

The p-InGaN of the LED epitaxial stack 2005 comprises an Mg-doped p-type InGaN layer with a thickness of 50˜400 nm. The p++-InGaN of the LED epitaxial stack 2005 comprises an Mg doped p++-InGaN layer with a thickness of 10˜100 nm that is a contact layer.

Following growth of the LED epitaxial stack 2005, the top layer is usually a p-type layer. If a tunnel junction (not shown) is grown on or above the p-type layer, then the top layer is an n-type layer. Then, thermal annealing can be performed to activate the p-type layers at a temperature of 600˜700° C. with an ambient gas of air or Nitrogen (N₂)/Oxygen (O₂) mixed gas.

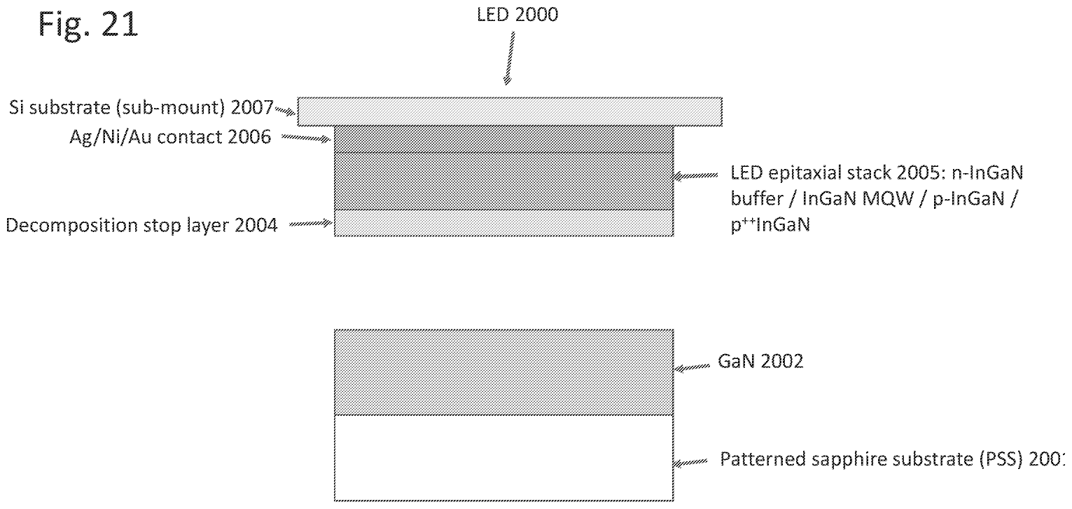

A high reflection mirror and good ohmic contact 2006, such as a Silver (Ag)/Nickel (Ni)/Gold (Au) material, is deposited on a top layer of the LED epitaxial stack 2005, along with an electrode (not shown), and the entire epitaxial structure is flip-chip bonded to an Si sub-mount 2007. Etching or mechanical pressure 2008 is applied to the decomposition layer 2003, to separate the LED epitaxial stack 2005 and the decomposition stop layer 2004 from remnants of the decomposition layer 2003, the GaN layer 2002 and the substrate 2001, as shown in FIG. 21.

FIG. 21 illustrates the LED 2000 after removing the decomposed decomposition layer 2003 (not shown) by etching or mechanical pressure, thereby separating the LED epitaxial stack 2005 and the decomposition stop layer 2004 from the GaN template 2002 and substrate 2001. As noted above, the decomposition layer 2003 is decomposed into In or Ga metal or an alloy of In and Ga metal, and Nitrogen gas during the high temperature growth of the decomposition stop layer 2004, and thus it is easy to remove the decomposed decomposition layer 2003 by wet etching, for example, photoelectrochemical (PEC) etching. This technique also removes any residual InGaN from the decomposed decomposition layer 2003 that may remain on the decomposition stop layer 2004. Additional etching or mechanical force may be applied to completely remove the substrate 2001 and GaN template 2002.

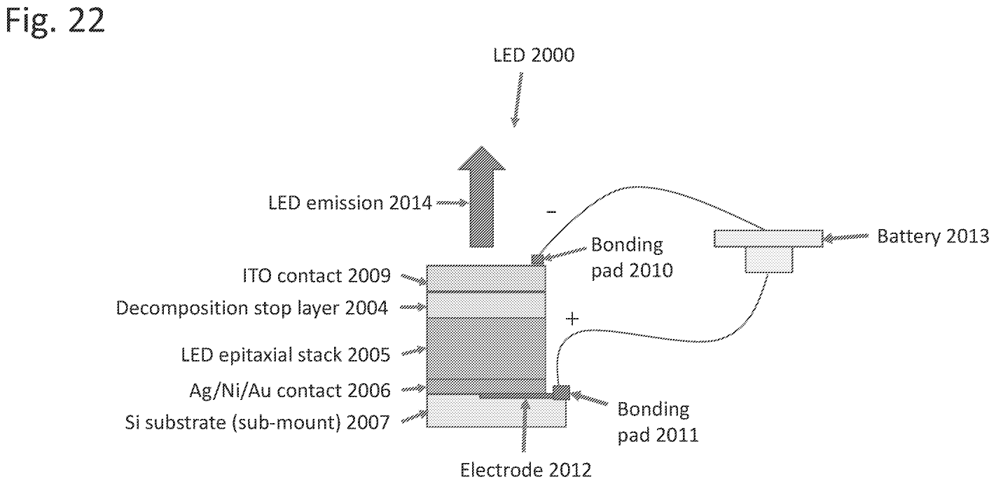

FIG. 22 illustrates the LED 2000 after chip separation. After removing the LED epitaxial stack 2005 including the decomposition stop layer 2004 from the GaN template 2002 and substrate 2001 by wet etching of the decomposed decomposition layer 2003, the top surface of the decomposition stop layer 2004, comprising 100 nm thick n-type AlₓGa₍₁₋ₓ₎N layer (0≤x≤1), is cleaned. Then, an ITO n-contact 2009 is deposited on the top surface of the decomposition stop layer 2004. Bonding pads 2010 are deposited on the ITO n-contact 2009. Then, each LED chip 2000 is separated by dicer or mesa etching. The size of LED chip 2000 may range from 1 μm to 1 mm. After LED chip 2000 separation, the sidewalls of the LED chip 2000 are wet etched by Potassium Hydroxide (KOH), Phosphoric Acid (H₃PO₄), or other etchants, to remove damage from the dry etching or dicer [2]. The sidewalls of the LED chip 2000 are deposited with Aluminum Oxide (Al₂O₃) to passivate a dangling bond at the surface of the sidewalls [2]. A bonding pad 2011 is deposited on an n-electrode 2012 (which was deposited on the Ag/Ni/Au contact 2006 before the epitaxial structure was sub-mounted on the Si substrate 2007). A battery 2013 or other electrical source is connected to the bonding pads 2010, 2011 in order to apply an electrical bias to the LED chip 2000, which results in light emission 2014 from the top of the LED chip 2000.

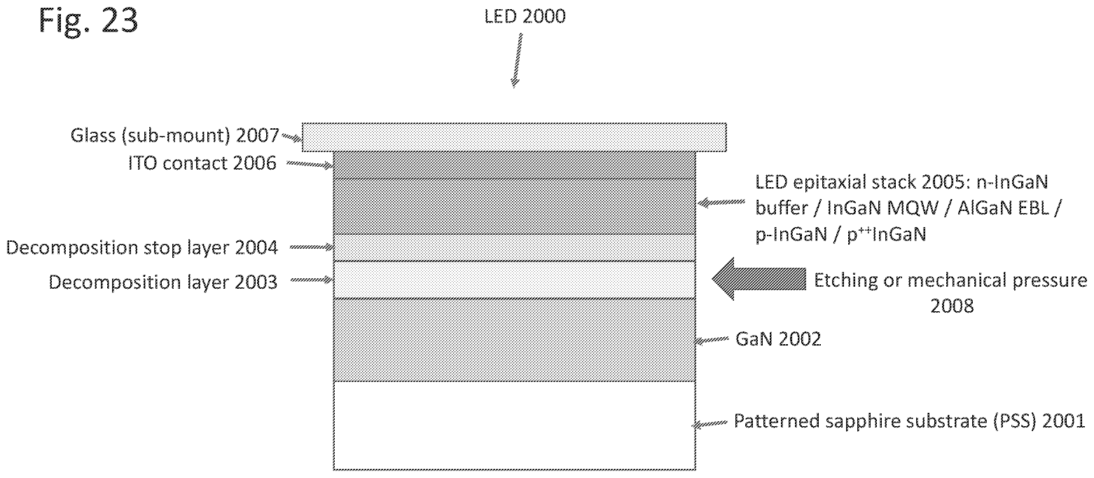

FIG. 23 illustrates a second embodiment, which is similar to the first embodiment of FIG. 20, except that the contact 2006 is comprised of a TCO, such as ITO, on or above the p⁺⁺InGaN of the LED epitaxial stack 2005, and the LED 2000 with the ITO contact 2006 is flip-chip bonded to a glass sub-mount 2007, which is a good heat sink. Also, in this embodiment, the LED epitaxial stack 2005 includes an Mg-doped p-type AlₓGa₍₁₋ₓ₎N layer (0≤x≤1) with a thickness of about 5˜40 nm that is an EBL, which is positioned after the growth of the InGaN MQW and before the p-InGaN.

In the case of a transparent LED 2000, where light is extracted from both the p-side and n-side of the LED 2000, the sub-mount 2007 should be a transparent material as well, such as glass, sapphire, plastic, or other transparent materials. In this invention, transparent means transmission of the emission wavelength is more than 10%. Also, the bonding materials should be transparent, such as epoxy, plastic, glue, or other transparent materials.

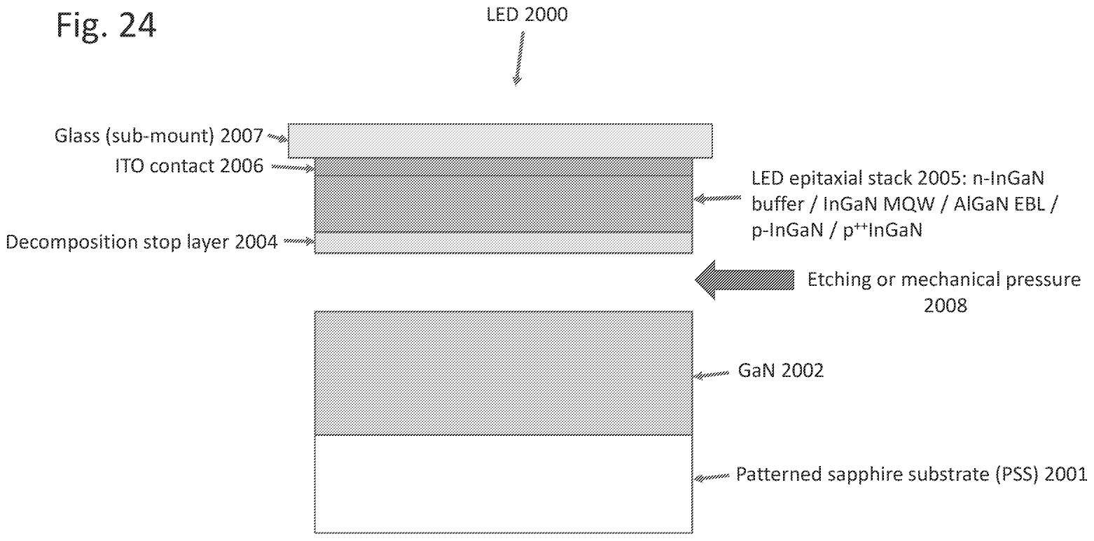

The decomposition layer 2003 of InGaN is grown on the GaN template 2002 on the substrate 2001 at a temperature of 700˜800° C. and then the decomposition stop layer 2004, comprised of AlₓGa₍₁₋ₓ₎N layer (0≤x≤1), is grown at temperature of 1000° C. The temperature is increased to 1050° C. and kept at that temperature for 1 minute to decompose the decomposition layer 2003 of InGaN. Then, the LED epitaxial stack 2005 is grown continuously. After growth of the LED epitaxial stack 2005, the ITO contact 2006 is deposited, and the LED 2000 is flip-chip bonded to the glass sub-mount 2007. The LED 2000 is separated from the decomposition layer 2003 by wet etching or mechanical pressure 2008, wherein PEC etching as the wet etching 2008 is preferred. As shown in FIG. 24, this technique removes any residual InGaN from the decomposed decomposition layer 2003. Additional etching or mechanical force 2008 may be applied to completely remove the substrate 2001 and GaN template 2002.

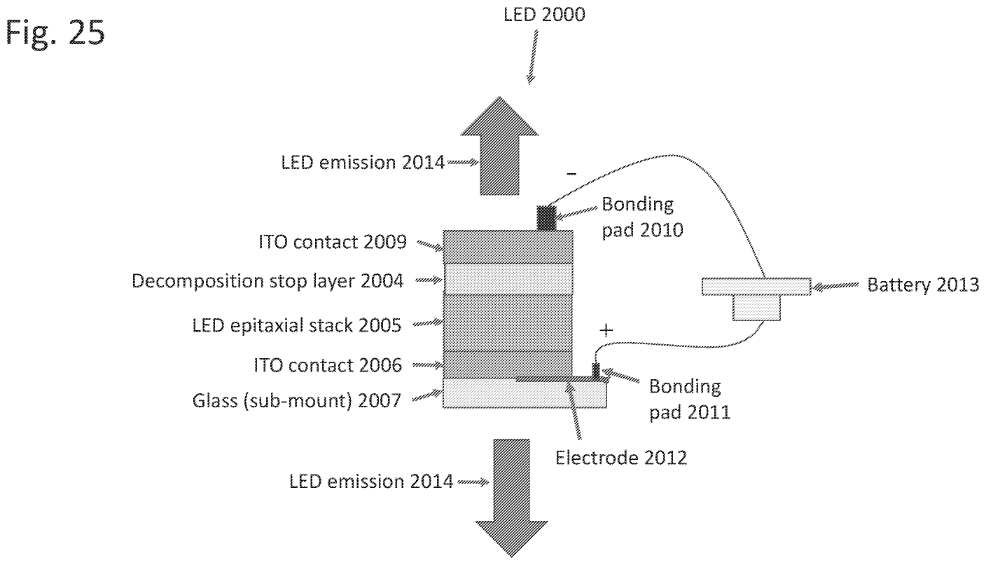

After cleaning the top surface of the decomposition stop layer 2004, a TCO layer such as ITO is deposited as a contact 2009 on the decomposition stop layer 2004 to extract light from an n-type side of the LED 2000, as shown in FIG. 25. A wire bonding pad 2010 for an n-electrode, comprised of Ni and 3-μm thick Au, are deposited on the TCO layer 2009. Then, each LED chip 2000 is separated from the epi-wafer using a dicer or mesa etching. The separated LED chip 2000 size is from 1 μm×1 μm to 1 mm×1 mm. The TCO layer 2009 also works as a cladding layer due to the thinness of the n-type InGaN layer 2004, which preferably is less than 1000 nm or more preferably is less than 500 nm, and the TCO contact 2009. The TCO contact 2009 may comprise ITO, Zinc Oxide (ZnO), sapphire, Gallium Oxide (Ga₂O₃), or other transparent materials.

When TCO is used for both the n-side contact 2009 and p-side contact 2006, a transparent LED 2000 is made, as shown in FIG. 25. A transparent LED 2000 has the highest light extraction efficiency by extracting the light emission from both the n-side and p-side of the LED 2000 effectively [11,12,13,14]. It is expected that a highly efficient III-nitride based LED 2000 with an emission wavelength from 200 nm to 1500 nm can be fabricated using this invention.

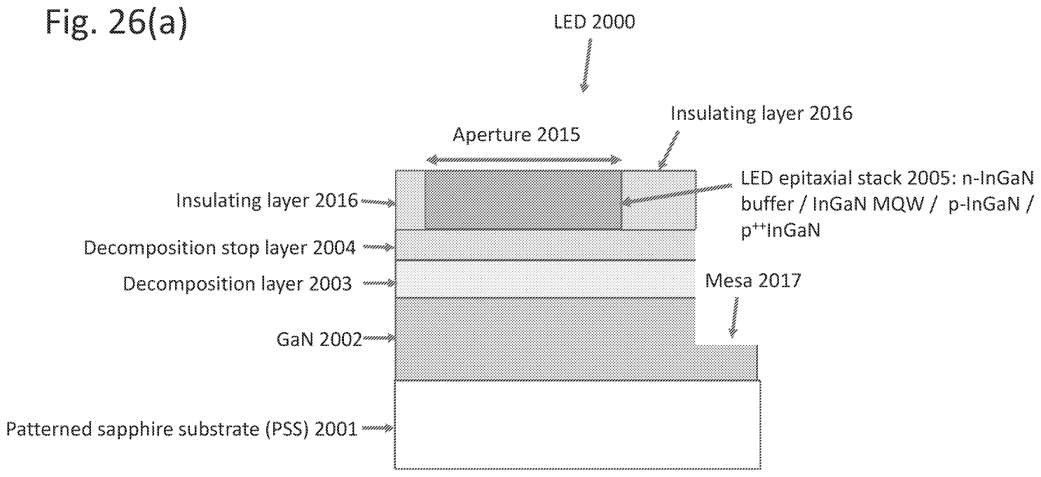

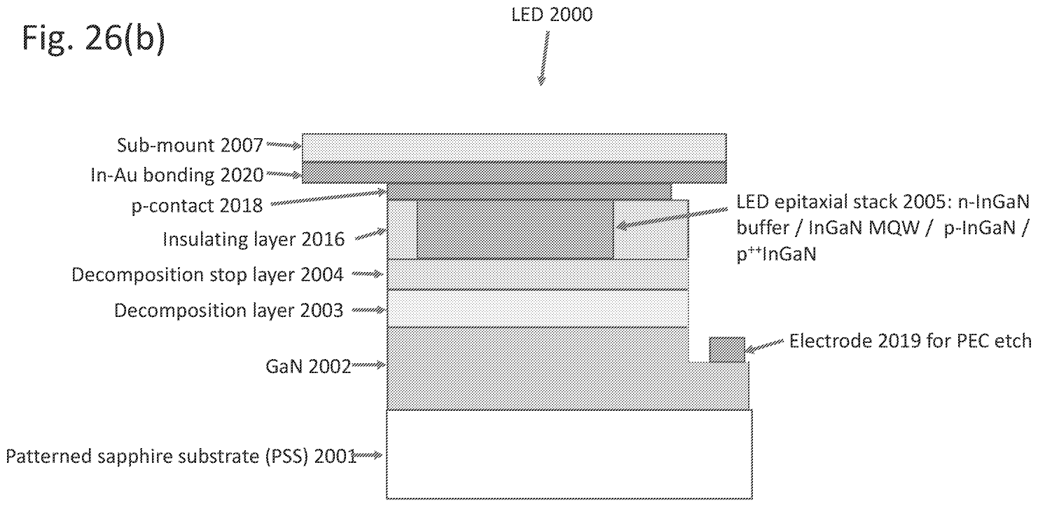

A third embodiment is depicted in FIGS. 26(a) and 26(b), which is similar to the first embodiment of FIG. 20, but uses a PEC etch for removal of the substrate 2001. All epitaxial layers in the LED epitaxial stack 2005 remain the same.

In this embodiment, an aperture 2015 is first etched, with the etch ending in the n-type InGaN layer of the LED epitaxial stack 2005 or the decomposition stop layer 2004, as shown in FIG. 26(a). This aperture 2015 determines the emitting area and can be from 1 μm×1 μm to 1 mm×1 mm. The sidewalls are then protected and passivated using an insulating layer 2016 of Silicon Dioxide (SiO₂) or Silicon Nitride (SiN). This protects the InGaN MQW of the LED epitaxial stack 2005 from etching during a subsequent PEC etch. Next, a mesa 2017 is etched outside the aperture 2015 region, through the decomposed decomposition layer 2003 into the GaN template 2002. The mesa 2017 determines the total LED chip 2000 size and should be larger than the aperture 2015.

As shown in FIG. 26(b), a p-contact 2018 is next deposited, comprised of Ti/Ag/Ni/Au, or an TCO such as ITO. An additional metal electrode 2019 comprised of Ti/Ag/Ni/Au is deposited on the GaN template 2002, which serves as a contact to provide a bias for the PEC etch. The epi-wafer is then flip-chip bonded to a sub-mount 2007 using In—Au bonding 2020, although other types of bonding may be used as well. In the case of a TCO p-contact 2018, a transparent sub-mount 2007 such as glass may be chosen for a completely transparent LED, as in the third embodiment.

The decomposition layer 2003 is then etched using a PEC etch in KOH with a light source having a shorter wavelength than the original absorption edge of the decomposition layer 2003. For this etch, the decomposition stop layer 2004, comprised of n-type AlₓGa₍₁₋ₓ₎N(0≤x≤1), acts as an etch stop. This technique removes any residual InGaN from the decomposed decomposition layer 2003. Additional etching or mechanical force may be applied to completely remove the substrate 2001 and GaN template 2002.

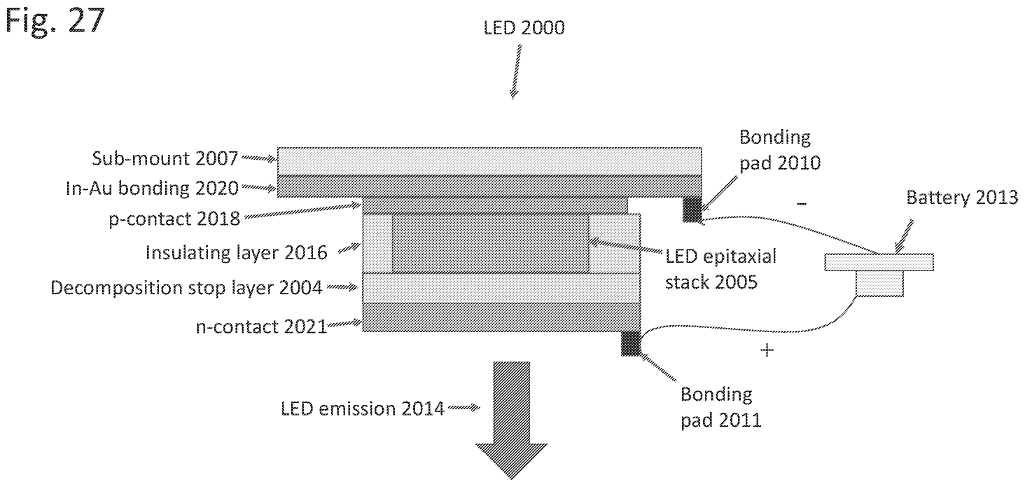

As shown in FIG. 27, an n-contact 2021 is deposited on the n-type decomposition stop layer 2004, wherein the TCO n-contact 2021 may comprise ITO, ZnO, sapphire, Ga₂O₃, or other materials. The complete structure with a reflective metal p-contact 2018 is shown in FIG. 27.

### Laser Diode Structure

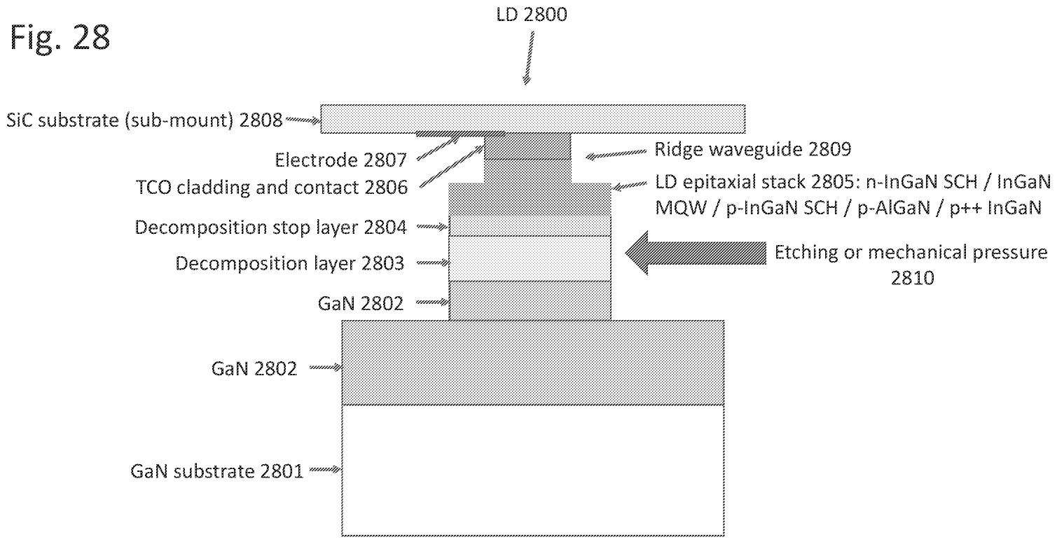

FIG. 28 illustrates a laser diode (LD) 2800 according to a fourth embodiment of the present invention. In fabricating the LD 2800, a GaN substrate 2801 is provided, which may have any crystal orientation for the LD growth, such as a semipolar, nonpolar or polar c-plane GaN substrate. Alternatively, an AlN substrate could be used. As mentioned in FIG. 3(b), the crystal quality of III-nitride based InGaN and AlGaN of the present invention is much better than that of conventional III-nitride based InGaN and AlGaN with a large strain due to a large lattice mismatch. Thus, other substrates could be used, such as Si, SiC, sapphire, and others, in order to grow an LD or other devices using the present invention.

A 3 μm thick undoped GaN template 2802 is grown on the GaN substrate 2801. A decomposition layer 2803, comprised of 2 nm thick InGaN, is grown at a temperature of 700˜850° C. Then, the temperature is increased to 1000° C. to grow a decomposition stop layer 2804, comprised of 100 nm thick n-type AlₓGa₍₁₋ₓ₎N layer (0≤x≤1).

The thickness of the decomposition stop layer 2804 ranges from 10 nm to 500 nm, which is best for LDs, LEDs, and other types of devices. If the decomposition stop layer 2804 is too thick, the decomposition stop layer 2804 is not flexible and does not relax for the device structure growth. If the decomposition stop layer 2804 is too thin, the decomposition stop layer 2804 has no effect as a decomposition stop layer 2804. The decomposition stop layer 2804 also works as an n-type cladding layer for the LD 2800.

After the decomposition stop layer 2804 is grown, the temperature is increased to 1050° C. and kept at that temperature for 1 minute, in order to decompose the decomposition layer 2803 of 2 nm thick InGaN. The decomposition layer 2803 is decomposed into In and Ga metal, or alloy of In and Ga metal, and Nitrogen gas. As a result, the decomposition stop layer 2804 becomes almost free-standing, as a flexible, compliant and freely relaxed layer.

Then, the rest of LD epitaxial stack 2805 is grown, which is comprised of at least an n-InGaN separate confinement hetero-structure (SCH), InGaN MQW, p-InGaN SCH, p-AlGaN, p++InGaN. (For a UV-LD, InGaN should be replaced with

### AlGaN.)

The n-InGaN SCH is an n-type InₓGa₍₁₋ₓ₎N layer (0.01≤x≤0.5), which is grown to a thickness of 200 nm. It is difficult to grow thick n-type InGaN layers more than 500 nm while keeping the crystal quality high. That is a reason why the total thickness of InGaN layers is preferably less than 1000 nm or more preferably less than 500 nm. Also, this n-InGaN layer should be fully relaxed or partially relaxed.

Next, an active or emitting layer comprising an InGaN MQW is grown. The In composition and growth temperature are determined by the emission wavelength of the LD. In one embodiment, the target emission wavelength of the LD is from 200 nm to 1500 nm.

The InGaN MQW is grown on or above a flexible decomposition stop layer 2804. Thus, the InGaN MQW is fully or partially relaxed. As a result, the In incorporation rate is much higher than an InGaN MQW grown on a GaN template with a large compressive strain.

After the InGaN MQW, the p-InGaN SCH is grown, which comprises a 200 nm thick p-type InₓGa₍₁₋ₓ₎N layer. An optional Mg-doped p-type AlₓGa₍₁₋ₓ₎N electron blocking layer (EBL) (0≤x≤0.4) (not shown), can be grown to a thickness of about 5˜30 nm. The p-AlGaN comprises an Mg-doped p-type AlₓGa₍₁₋ₓ₎N cladding layer (0≤x≤1) that is grown to a thickness of 100 nm. The p++InGaN comprises a final p⁺⁺InₓGa₍₁₋ₓ₎N(0≤x≤1) contact layer that is grown to a thickness of 10˜100 nm.

Following completion of the LD epitaxial stack 2805, a thermal annealing is performed to activate the p-type layers at a temperature of 600˜700° C. with an ambient gas of air or N₂/O₂ mixed gas. The total thickness of the p-type AlₓGa₍₁₋ₓ₎N cladding layer (0≤x≤1) and p-type GaN layer should be less than the total thickness (about 500 nm) of the InGaN layers because the InGaN layers should be fully or partially relaxed. When the total thickness of 300 nm of AlₓGa₍₁₋ₓ₎N cladding layer (0≤x≤1) and p-type GaN layers is not enough to confine the laser light, TCO is deposited on the p++GaN contact layer as part of a cladding layer.

After growing a 100 nm Mg-doped p-type AlₓGa₍₁₋ₓ₎N cladding layer (0≤x≤1) and 10 nm p++GaN contact layer, a TCO layer 2806 is deposited as a cladding and contact layer [6]. The TCO layer 2806, which may be ITO, has a higher conductivity than that of the Mg-doped p-type AlₓGa₍₁₋ₓ₎N layer (0≤x≤1). Also, TCO has a small refractive index of about 1.5, which is good to confine the light in the active layer. Using the TCO layer 2806, the operating voltage can be reduced dramatically [6].

After growth of the LD epitaxial stack 2805, the top layer is usually a p-type layer. If a tunnel junction (not shown) is grown on top of the p-type layer, then the top layer is an n-type layer. The TCO layer 2806 is deposited on the top layer as a part of cladding layer and contact layer.

A metal Ohmic material, such as Ni/Au, may be deposited for an Ohmic contact 2807 to the p⁺⁺-GaN layer of the LD epitaxial stack 2805. If the top layer is an n⁺⁺-GaN layer of a tunnel junction, then Ti/Al/Ni/Au may be deposited for an Ohmic contact 2807.

If the top layer is TCO, such as ITO, a metal bonding pad of Au alloy is deposited for flip-chip bonding to a sub-mount 2808.

The contact 2806 shown is a TCO layer, such as ITO, which is a p-type contact 2806. The TCO layer 2806 may also be used as a cladding layer along with a thin 100 nm p-type AlₓGa₍₁₋ₓ₎N cladding layer (0≤x≤1) (not shown). A metal bonding pad 2807 is deposited on the TCO layer.

Then, mesa etching is performed, with a ridge width of 2˜15 μm, that reaches near the bottom of the Mg-doped p-type AlₓGa₍₁₋ₓ₎N layer (0≤x≤1) or the p-type InGaN SCH, to form a ridge waveguide 2809 of the LD 2800. A 50 μm×1700 μm stripe mesa etching is then performed that reaches into the GaN template 2802 to separate the LD chip 2800.

The LD wafer is then flip-chip bonded to an SiC substrate 2808 as a sub-mount. The sub-mount 2808 is usually a good heat sink, and thus AlN, Cu, etc., may be used as well.

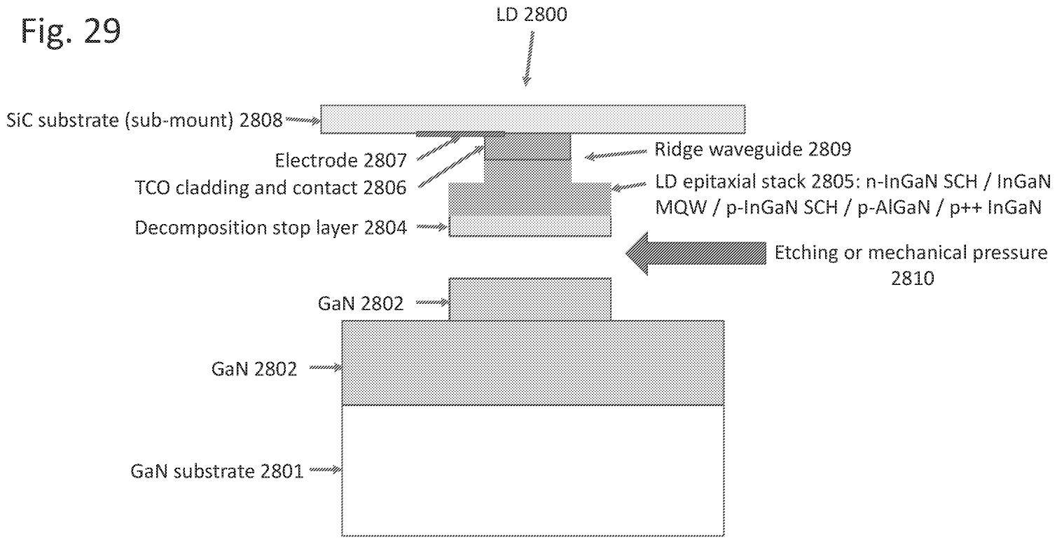

The LD epitaxial stack 2805 is separated from the decomposition layer 2804 by wet etching or mechanical force 2810 from the sidewall of the 50 μm×1700 μm stripe mesa, as shown in FIG. 29, wherein PEC etching can be used as the wet etching.

This technique removes any residual InGaN from the decomposed decomposition layer 2803. Additional etching or mechanical force 2810 may be applied to completely remove the substrate 2801 and GaN template 2802.

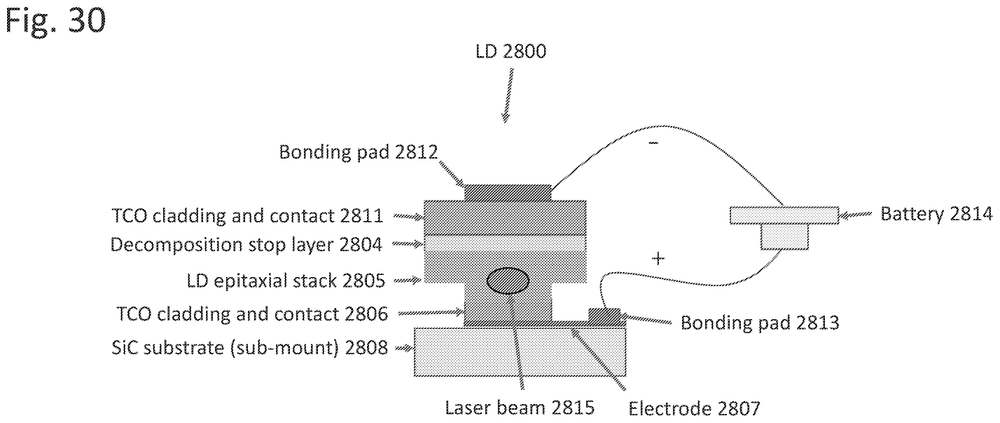

After cleaning a top surface of the decomposition stop layer 2804, which is a 100 nm n-type AlₓGa₍₁₋ₓ₎N layer (0≤x≤1), a TCO layer 2811 is deposited on the decomposition stop layer 2804, as shown in FIG. 30. The TCO layer 2811 works as a cladding and contact layer because the decomposition stop layer 2804, comprising a 100 nm thick n-type AlₓGa₍₁₋ₓ₎N layer (0≤x≤1), is not enough to confine the light in the active layer and SCH of the LD epitaxial stack 2805 [6]. The TCO layer 2811 may be comprised of ITO, ZnO, sapphire, Ga₂O₃, and other materials. Metal, such as a bonding pad 2812 comprised of Ni and thick Au, is deposited on the TCO layer 2811 for wire bonding. A bonding pad 2813 may also be deposited on the electrode 2807.

A battery 2814 or other electrical source is connected to the bonding pads 2812, 2813 in order to apply an electrical bias to the LD 2800, which results in light emission comprising a laser beam 2815 being emitted from an edge of the LD 2800.

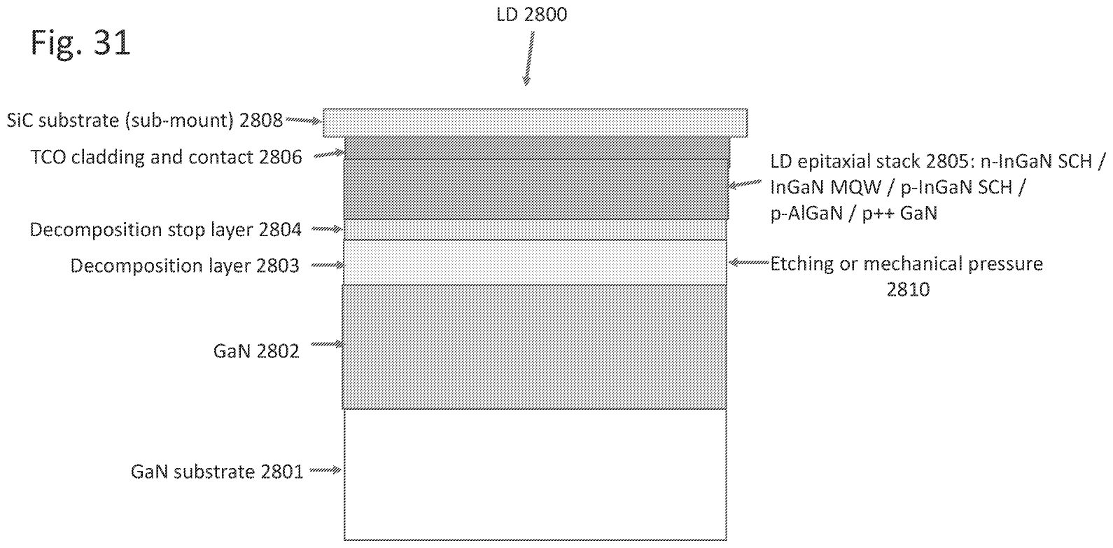

FIG. 31 illustrates an LD 2800 according to a fifth embodiment of the present invention. In the LD 2800, a GaN substrate 2801 is provided, which may have any crystal orientation for the LD growth, such as a semipolar, nonpolar and c-plane GaN. Alternatively, an AlN substrate may be used.

A 3 μm thick undoped GaN template 2801 is grown on the GaN substrate 2801. A decomposition layer 2803, comprised of 2 nm thick InGaN, is grown at a temperature of 700˜850° C. Then, the temperature is increased to 1000° C. to grow the decomposition stop layer 2804, comprised of 100 nm thick n-type AlₓGa₍₁₋ₓ₎N layer (0≤x≤1). The decomposition stop layer 2804 also works as an n-type cladding layer for the LD 2800. After the decomposition stop layer 2804 is grown, the temperature is increased to 1050° C. and kept at that temperature for 1 minute in order to decompose the decomposition layer 2803 of 2 nm thick InGaN.

Then, an LD epitaxial stack 2805 is grown, which is comprised of at least an n-InGaN SCH, InGaN MQW, p-InGaN SCH, p-AlGaN, p++InGaN. (For a UV-LD, InGaN should be replaced with AlGaN.)

The n-InGaN SCH is an n-type InₓGa₍₁₋ₓ₎N layer (0.01≤x≤0.5) grown to a thickness of 200 nm. It is difficult to grow an n-type InGaN layer with a thickness more than 500 nm while keeping the high crystal quality. That is a reason why the total thickness of the InGaN layers is preferably less than 1000 nm and more preferably less than 500 nm. Also, this n-InGaN SCH should be fully relaxed or partially relaxed [3,4].

The InGaN MQW is an active or emitting layer. The In composition and growth temperature is determined by the emission wavelength of the LD 2800. In one embodiment, the target emission wavelength of the LD 2800 is from 200 nm to 1500 nm.

The InGaN MQW is grown on or above the flexible decomposition stop layer 2804. Thus, the InGaN MQW is fully or partially relaxed. As a result, the In incorporation rate is much higher than an InGaN MQW grown on a GaN template with a large compressive strain.

The p-InGaN SCH is a 200 nm thick p-type InₓGa₍₁₋ₓ₎N layer. An optional Mg-doped p-type AlₓGa₍₁₋ₓ₎N electron blocking layer (EBL) (0≤x≤0.4) (not shown) may be grown on or above the p-InGaN SCH to thickness of about 5˜30 nm. The p-AlGaN is an Mg-doped p-type AlₓGa₍₁₋ₓ₎N cladding layer (0≤x≤1) grown to a thickness of 100 nm. The p++GaN is a final p++InₓGa₍₁₋ₓ₎N(0≤x≤1) contact layer grown to a thickness of 10˜100 nm. Thereafter, a thermal annealing is performed to activate the p-type layers of the LD epitaxial stack 2805 at a temperature of 600˜700° C. with an ambient gas of air or N₂/O₂ mixed gas.

The total thickness of the p-type AlₓGa₍₁₋ₓ₎N cladding layer (0≤x≤1) and p-type GaN layer should be less than that of the total thickness (about 500 nm) of the InGaN layers, because the InGaN layers should be fully or partially relaxed. When the total thickness of 300 nm of the AlₓGa₍₁₋ₓ₎N cladding layer (0≤x≤1) and p-type GaN layers is not enough to confine the laser light, a TCO layer 2806 is deposited on the p++GaN contact layer as a cladding and contact layer.

After growing the 100 nm Mg-doped p-type AlₓGa₍₁₋ₓ₎N cladding layer (0≤x≤1) and 10 nm p⁺⁺GaN contact layer, a TCO layer 2806 is deposited as a cladding and contact layer [6]. The TCO layer 2806, which may comprise ITO, has a higher conductivity than that of the Mg-doped p-type AlₓGa₍₁₋ₓ₎N layer (0≤x≤1). Also, TCO has a small refractive index of about 1.5, which works well to confine the light in the active layers and the SCH layers of the LD epitaxial stack 2805. Using the TCO layer 2806, the operating voltage can be reduced dramatically [6].

After growth of the LD epitaxial stack 2805, the top layer is usually a p-type layer. If a tunnel junction (not shown) is grown on top of the p-type layer, then the top layer becomes an n-type layer. The TCO layer 2805 is deposited on the top layer as a part of a cladding layer and contact layer.

A metal Ohmic contact material, such as Ni/Au, may be deposited for an Ohmic contact (not shown) to the p⁺⁺GaN layer of the LD epitaxial stack 2805. If the top layer is an n⁺⁺GaN layer of a tunnel junction, then Ti/Al/Ni/Au may be deposited for an Ohmic contact.

If the top layer is TCO such as ITO, a metal bonding pad of Au alloy may be deposited for flip-chip bonding the LD 2800 on a SiC substrate 2808 as a sub-mount. The contact shown is a TCO layer 2806, such as ITO, which is a p-type contact. The TCO layer may also be used as a cladding layer along with a thin 100 nm p-type AlₓGa₍₁₋ₓ₎N cladding layer (0≤x≤1) (not shown). A metal bonding pad is deposited on the TCO layer 2806. The LD 2800 is then flip-chip bonded to a SiC substrate 2808 as a sub-mount. The sub-mount 2808 is usually a good heat sink, and thus AlN, Cu, etc., may be used as well.

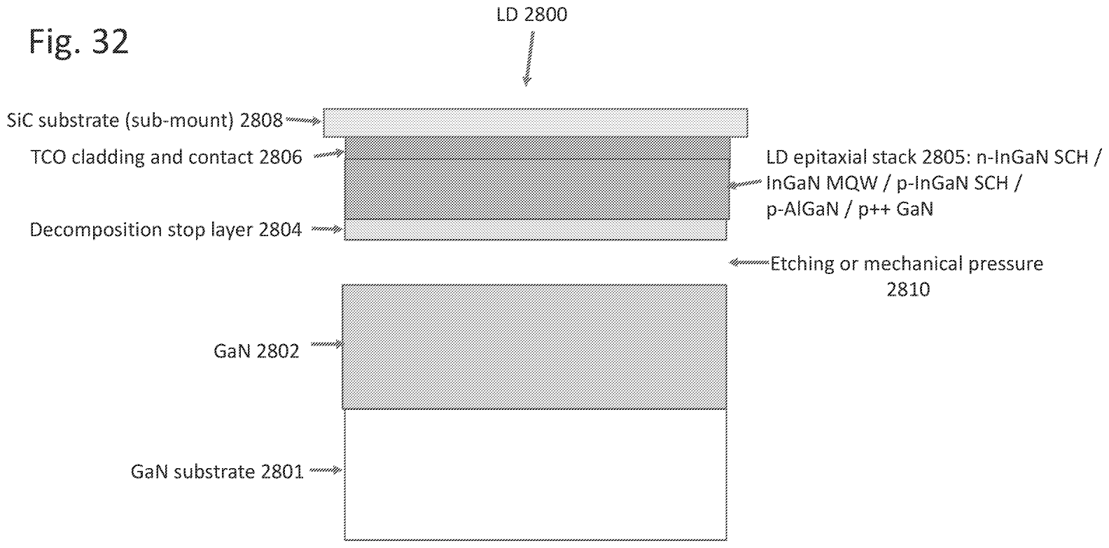

The LD 2800 is separated from the decomposition layer 2803 by wet etching or mechanical force 2810, as shown in FIG. 32, wherein PEC etching can be used as the wet etching. This technique removes any residual InGaN from the decomposed decomposition layer 2803. Additional etching or mechanical force 2810 may be applied to completely remove the substrate 2801 and GaN template 2802.

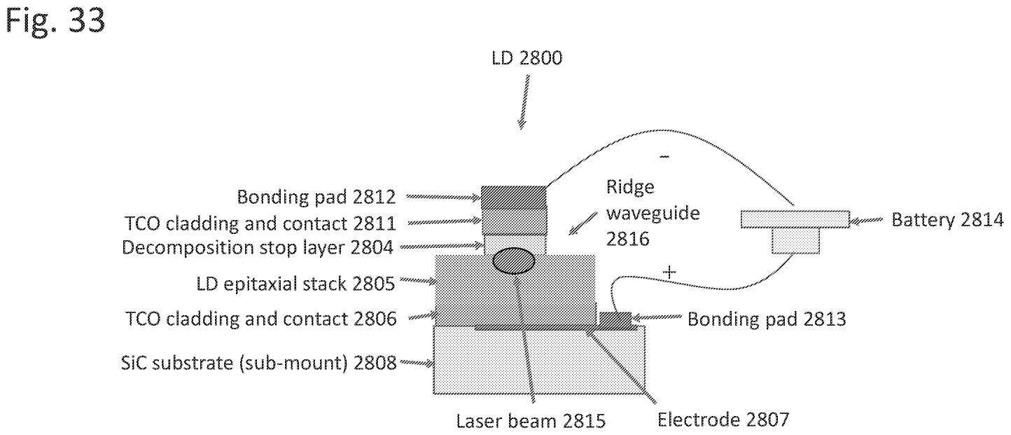

As shown in FIG. 33, after cleaning a top surface of the decomposition stop layer 2804, which is a 100 nm n-type AlₓGa₍₁₋ₓ₎N layer (0≤x≤1), mesa etching with a ridge width of 2˜15 μm is performed, that reaches near the bottom of the decomposition stop layer 2804 or the n-InGaN SCH of the LD epitaxial stack 2805, to form a ridge waveguide of the LD 2800.

A TCO layer 2811 is deposited on the decomposition stop layer 2804 as a cladding layer in order to increase the confinement of light and carriers, because decomposition stop layer 2804 is only 100 nm thick, which is not enough as a cladding layer to confine the light in the active layers and SCH layers [6]. The TCO layer 2811 may comprise ITO, ZnO, sapphire, Ga₂O₃, or other materials.

Metal, such as a bonding pad 2812 comprised of Ni and thick Au, is deposited on the TCO layer 2811 for wire bonding. A bonding pad 2813 may also be deposited on the electrode 2807.

Then, a 50 μm×1700 μm stripe mesa etching is performed to separate the LD chip 2800, wherein the etching reaches into the bonding pad 2813 on the SiC sub-mount 2808. Also, a dicer can be used to separate the LD chip 2800.

A battery 2814 or other electrical source is connected to the bonding pads 2812, 2813 in order to apply an electrical bias to the LD 2800, which results in light emission comprising a laser beam 2815 being emitted from an edge of the LD 2800. In this embodiment, the narrow 2˜15 μm width ridge waveguide 2816 is formed on the top layers of the n-type layers of the LD epitaxial stack 2805. The top layer of the p-side of the LD epitaxial stack 2805 is flip-chip bonded with a wider width of 50 μm to the SiC sub-mount 2808.

In a conventional embodiment, the ridge wave guide 2816 is formed on the p-side of the LD epitaxial stack 2805, and the top layer of the p-side of the LD epitaxial stack 2805 with the narrow 2˜15 μm width ridge waveguide 2816 is bonded to the sub-mount 2808. However, the bonded area would be much smaller than that of the sixth embodiment. Thus, the heat is effectively removed by this embodiment in comparison with that of a conventional embodiment. The sub-mount 2808 is usually a good heat sink, and materials such as AlN, Cu, etc., may be used as well.

A sixth embodiment of the present invention describes a III-nitride based LED, LD, or other device. The device is fabricated without separation from the decomposed decomposition layer. When the decomposition layer is very thin, for example, less than 5 nm after decomposition, an upper portion of the decomposition stop layer and a lower portion of the GaN template are stuck together. In that case, if the device is an LED or LD, the top layer of the device is a p-type layer. If a tunnel junction is formed, then the top layer is an n-type layer. The device fabrication process becomes similar to that of conventional device processing, as shown in references [6, 11-14]. As mentioned above, experimentally the inventors confirmed that the device is not separated from the decomposed decomposition layer. Thus, device processing becomes very simple, because conventional device processing could be used.

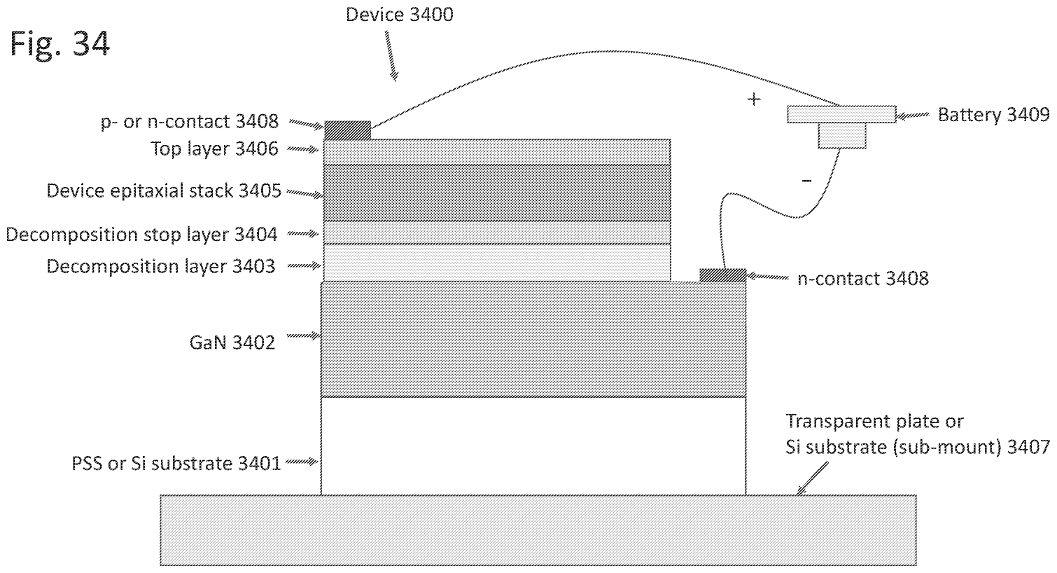

For example, FIG. 34 illustrates a device 3400 according to the sixth embodiment of the present invention, wherein the device may comprise an LED, LD, photodetector, or other device. In fabricating the device 3400, a PSS or Si substrate 3401 is provided and a 3 μm thick undoped GaN template 3402 is grown on the substrate 3401. A decomposition layer 3403 is grown on or above the GaN layer 3402, followed by growth of a decomposition stop layer 3404 at a higher growth temperature. During the growth of the decomposition stop layer 3404 at the higher temperature, the decomposition layer 3403 is decomposed, resulting in the decomposition stop layer 3404 becoming almost free-standing, as a flexible or compliant and freely relaxed layer. A device epitaxial stack 3405 is grown on or above the decomposition stop layer 3404, followed by a top layer 3406. The substrate 3401 is then sub-mounted on a transparent plate or SI substrate 3407.

In the case where the device 3400 is an LED, the device epitaxial stack 3405 is the same as the LED epitaxial stack 2005 described in FIG. 26. In this example, a mesa etch may be performed to a depth within an n-type InGaN buffer of the device epitaxial stack 3405, the decomposition stop layer 3404, or the n-type GaN template 3402. An n-contact 3408 is deposited on the exposed layer, in this example, the decomposition stop layer 3404.

The top layer 3406 is deposited on or above the device epitaxial stack 3405, and a contact 3408 is deposited on the top layer 3406. If the top layer 3406 is an n-type layer of a tunnel junction, then the contact 3408 is an n-contact; otherwise, the contact 3408 is a p-contact. A battery 3409 or other electrical source is connected to the contacts 3408 in order to apply an electrical bias to the device 3400, which results in light emission from the device 3400.

Light may be extracted from the top layer 3406, or from both the top layer 3406 and a back side of the substrate 3401. If the top layer 3406 is a high reflection metal mirror, light is extracted from the back side of the substrate 3401. Thus, if the device epitaxial stack 3405 is not removed from the decomposed decomposition layer 3403, the fabrication process of the device epitaxial stack 3405 becomes very simple, because there is no need for the process to remove the device epitaxial stack 3405 from the decomposed decomposition layer 3403. This process would be used for an LED and, in view of the cost of the LED process, this would be the best process. The substrate may be GaN, AlN, sapphire, Si, SiC, etc. For the LED display, the three primary color LED could be grown on a large (8˜12 inch) Si substrate using this method.

In the case where the device 3400 is an LD, the device epitaxial stack 3405 is the same as the LD epitaxial stack 2805 described in FIG. 28. The top layer 3406 is a p-type layer or an n-type layer of a tunnel junction. Mesa etching of a ridge wave guide with a shape 3 μm×1500 μm is performed, with a depth that reaches within the p-AlGaN cladding or p-InGaN SCH of the device epitaxial stack 3405, or n-InGaN buffer grown decomposition stop layer 3404. In this example, an n-contact 3408 is deposited on the n-type InGaN buffer grown on decomposition stop layer 3404. We cannot make n-contact on GaN template because decomposed decomposition layer includes an airgap which increase the series resistance when we make n-contact on GaN template. A p-contact 3408 comprised of a TCO such as ITO or comprised of metal is deposited on the top layer 3406, which may be the p-type GaN or p-type InGaN of the LD epitaxial stack 2805 described in FIG. 28. Laser light is observed from etched or cleaved facets under operation. This LD process is very simple because there is no need for the process to remove the device epitaxial stack 3405 from the decomposed decomposition layer 3403. In the view of the cost of the LD process, this would be the best one process.

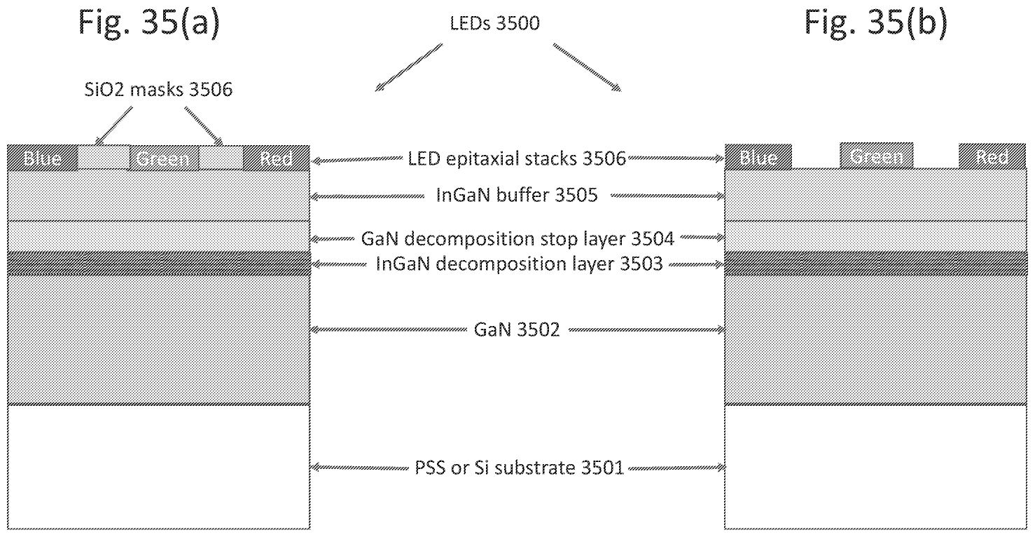

In a seventh embodiment, a first growth for the devices 3500 as shown in FIGS. 35(a) and 35(b) is performed on a PSS or Si substrate 3501, wherein the first growth comprises a GaN template 3502, InGaN decomposition layer 3503, 100 nm GaN decomposition stop layer 3504 and n-type InGaN buffer 3505 (which also works as an n-type cladding and or n-contact layer) comprising 200 nm InₓGa₍₁₋ₓ₎N(0.01<x<0.05). Then, a second growth is performed of LED structures 3505 on or above the first growth, wherein the second growth is a selective area growth using SiO₂ masks 3506 to grow InGaN layers with different In compositions selectively on or above the decomposition stop layer 3504, resulting in different emission wavelengths for the LED structures 3506. Then, the SiO₂ masks 3506 are removed, as shown in FIG. 35(b).

As described in FIG. 3(b), when the InGaN MQW is grown on or above the decomposition stop layer 3504 on the decomposed decomposition layer 3503, the emission wavelength is 75 nm longer than that of a conventional InGaN MQW grown on a GaN template with a large compressive strain. This means that the emission wavelength would increase, for example, from 375 nm (violet) to 450 nm (blue), 450 nm (blue) to 525 nm (green), and from 545 nm (yellow) to 620 nm (red), when an InGaN MQW is grown on or above the decomposition stop layer 3504 grown on the decomposed decomposition layer 3503. When LED structures 3506 including the InGaN MQW are grown on or above decomposition stop layer 3504 on the decomposed decomposition layer 3503, the LED structures 3506 can emit light that is blue, green and red in color. Thus, using the present invention, highly efficient blue, green and red LEDs are grown planarly.

Using the present invention, a micro-LED display could be made using a large size silicon or sapphire substrate. For example, on a 12-inch Si substrate, an n-GaN template is first grown. Then, the decomposition layer of InGaN and the decomposition stop layer of n-GaN is grown on or above the n-GaN template. During the high temperature growth of the decomposition stop layer, the decomposition layer is decomposed into In and Ga metal, or alloy of In and Ga metal, and Nitrogen gas. After the growth, an SiO₂ mask is deposited on whole area. Using photolithography, many 5 μm×5 μm sized rectangular shaped windows are wet etched in the SiO₂ mask with a pitch of 30 μm. A blue LED structure comprised of an n-InGaN cladding layer, InGaN MQW, EBL, p-InGaN layer and p-InGaN contact layer is grown selectively in the 5 μm×5 μm sized rectangular shaped windows with a pitch of 30 μm. After the blue LED structure growth, the SiO₂ is removed by hydrofluoric (HF) wet etching. Only the blue LED structure with the 5 μm×5 μm sized rectangular shape with a pitch of 30 μm remains. Next, an SiO₂ mask is deposited on whole area. Using photolithography, many 5 μm×5 μm sized rectangular shapes of the SiO₂ mask with a pitch of 30 μm with a space of 5 μm from the blue LED is wet etched. Then, a green LED structure comprised of an n-InGaN cladding layer, InGaN MQW, EBL, p-InGaN layer and p-InGaN contact layer is grown selectively in the 5 μm×5 μm sized rectangular shaped windows with a pitch of 30 μm with a space of 5 μm from the blue LEDs. Next, red LEDs are grown the same as the blue and green LEDs with a space of 5 μm from the green LEDs. Finally, an n-type contact is deposited on the decomposition stop layer of n-GaN. A p-contact such as ITO is deposited on the top layer of each LED. A bonding pad such as Au is deposited on each contact. Each bonding pad is connected to a circuit to control each of the LEDs. The 12-inch size micro LED display is completed. Depending on the application, the 12 inch substrate may be cut for smaller sized displays. For this application, it is better that the LED structure is not separated from the decomposition layer, because of the simplicity of the device processing as described in the sixth embodiment in FIG. 34.

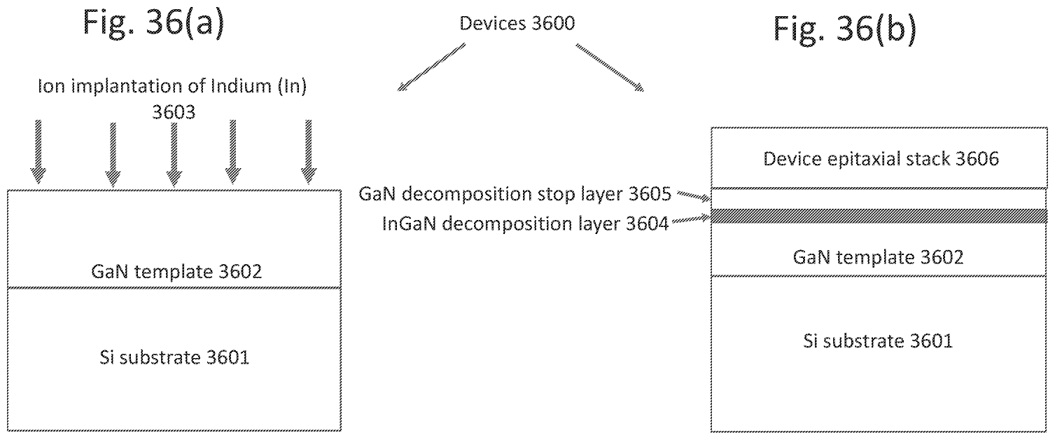

FIGS. 36(a) and 36(b) show an eighth embodiment when fabricating devices 3600. First, an Si substrate 3601 is provided and a GaN template 3602 is grown on the Si substrate 3601 by MOCVD. Then, using ion implantation 3603, In is implanted into the GaN template 3602 to a depth of 20˜500 nm to form an InGaN decomposition layer 3604. Then, a GaN decomposition stop layer 3605 with a thickness of 20˜500 nm is automatically formed. The InGaN decomposition layer 3604 is decomposed by thermal annealing at a temperature of 1000˜1100° C. for 5˜10 minutes, resulting in the GaN decomposition stop layer 3605 becoming an almost free-standing, flexible and compliant, decomposition stop layer 3605. A device structure 3606 is grown on or above the GaN decomposition stop layer 3605, wherein part or all of the layers of the device structure 3606 have a biaxially relaxed lattice constant or strain.

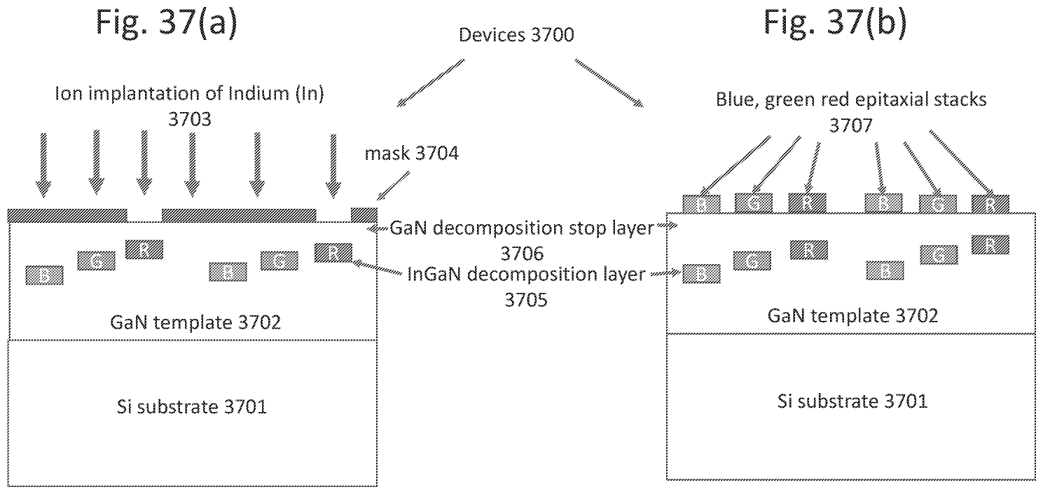

FIGS. 37(a) and 37(b) show a ninth embodiment to make three color LEDs 3700 for a display application. First, an Si substrate 3701 is provided and a GaN template 3702 is grown on the Si substrate 3701 by MOCVD. Then, using ion implantation 3703 and a mask 3704, In is implanted into the GaN template 3702 to a depth of 20˜500 nm to form an InGaN decomposition layer 3705. The InGaN decomposition layer 3705 is decomposed by thermal annealing at a temperature of 1000˜1100° C. for 5˜10 minutes, resulting in the GaN decomposition stop layer 3706 is formed with a thickness of 20˜500 nm and becoming an almost free-standing, flexible, compliant, decomposition stop layer 3706. A device structure 3707 is grown on or above the GaN decomposition stop layer 3706, wherein part or all of the layers of the device structure 3707 have a biaxially relaxed lattice constant or strain.

Depending on the desired color of the device structure 3707, the depth of the implantation 3703 is changed using the mask 3704. For a blue (B) LED 3707, no implantation which means no decomposition layer: for a green (G) LED 3707, the depth of implantation is 100 nm; and for a red (R) LED 3707, the depth of the implantation is 50 nm.

The relaxation will depend on the thickness of the decomposition stop layer 3706. Blue LED growth conditions are used to grow a blue (B) LED 3707 on the GaN template 3702 with a large compressive strain is used to grow LED structure on whole area of Si substrate. Blue LED growth conditions on the decomposition stop layer 3706 without the decomposition layer 3705 becomes a blue (B) LED 3707. Blue LED growth conditions on the decomposition stop layer 3706 with a thickness of 100 nm becomes a green (G) LED 3707 considering the results of FIG. 3(b). Blue LED growth conditions on the decomposition stop layer 3706 with a thickness of 50 nm becomes a red (R) LED 3707 considering the results of FIG. 3(b) and has the highest relaxation with the smallest thickness of the decomposition stop layer 3707. Then, using dry etching, each LED 3707 with a size of 3 μm×3 μm is separated, n- and p-contacts are made, and an electric circuit is formed on a 12 inch Si substrate, which becomes a micro-LED display.

When green LED growth conditions are used, only red (R) LEDs 3707 are grown using a 50˜100 nm thick decomposition stop layer on a decomposed decomposition layer. Blue (B) and green (G) LEDs 3707 are grown on the decomposition stop layer without the decomposition layer. In this case, the blue (B), green (G) and red (R) LEDs 3707 are grown by using selective area growth, as described in FIGS. 35(a) and 35(b).

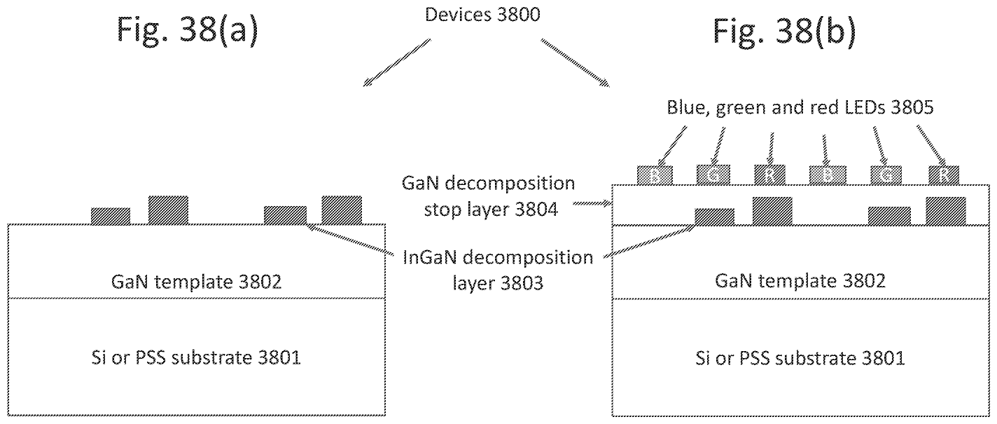

FIGS. 38(a) and 38(b) show a tenth embodiment for making three color LEDs 3800 for a display application. First, an Si or PSS substrate 3801 is provided and a GaN template 3802 is grown on the substrate 3801. An InGaN decomposition layer 3803 with a thickness of 10 nm is grown on the GaN template 3802 at a temperature of 750° C. Then, mesa etching of the InGaN decomposition layer 3803 with a shape of 10 μm×10 μm is performed with different etching depths. For a blue LED, the etching depth is 10 nm to remove all of the decomposition layer 3803: for a green LED, the etching depth is 8 nm and the thickness of the decomposition layer 3803 is 2 nm; and for a red LED, no etching is performed and the decomposition layer 3803 has a thickness of 10 nm. A GaN decomposition stop layer 3804 with a thickness of 100 nm (30 nm grown at 750° C., 70 nm grown at 1000° C.) is grown at a high temperature 1000° C. by MOCVD. During the high temperature growth of the GaN decomposition stop layer 3804, the InGaN decomposition layer 3803 is decomposed. The GaN decomposition stop layer 3804 for red (R) and green (G) LEDs 3805 becomes an almost free-standing, flexible layer with a small thickness of 100 nm. For green (G) LEDs 3805, the thickness of the InGaN decomposition layer 3803 is as small as 2 nm, but the flexibility of the GaN decomposition stop layer 3804 is not perfect. For red (R) LEDs 3805, the thickness of the InGaN decomposition layer 3803 is as small as 10 nm, and the flexibility and compliance of the GaN decomposition stop layer 3804 is almost perfect.

Next, conventional blue LED growth conditions are used to grow a blue (B) LED 3805 on the GaN template 3802 with a high compressive strain. For the blue LED region, the blue (B) LED 3805 is grown on the GaN template 3802 with a large compressive strain, due to no decomposed decomposition layer 3803. For the green LED region, considering the results of FIG. 3(b) and the thickness of the decomposition layer 3803 is 2 nm, the color of the LED 3805 becomes green (G) due to the relaxed lattice constant or strain of the InGaN layers of the LED structure 3805. For the red LED region, considering the results of FIG. 3(b), the thickness of the decomposition layer 3803 is 10 nm, and the flexibility and compliance of the GaN decomposition stop layer 3804, the color of LED 3805 becomes red (R) due to the largest relaxed lattice constant or strain of the InGaN layers of the LED structure 3805. Then, a mesa etch is performed for each LED 3805 with a size of less than 10 μm×10 μm, because the relaxation of lattice constant or strain is not enough to obtain each color of green and red near the edge of the mesa of the decomposition layer 3803. The size of the mesa is 5 μm×5 μm, and is used to separate each LED 3805, as shown in FIG. 38(b). Then, n- and p-contacts are made, and an electric circuit is formed on an 8 inch Si substrate, wherein the 8-inch substrate becomes micro-LED display, which may be used for smartphones, TVs, AR/VR displays, watches and other small displays.

As another embodiment, selective area growth is used to grow the different decomposition layers depending on each color as shown in in FIGS. 38(a) and 38(b). After growth of the GaN template on the Si substrate, SiO₂ is deposited on the whole surface, a 10 μm×10 μm window is opened for the green LEDs. Next, an InGaN decomposition layer with a small In composition is grown with a thickness of 3 nm at a temperature of 770° C. After removing the SiO₂, the InGaN decomposition layer remains only in the green window regions. Next, SiO₂ is deposited on the whole surface, and a 10 μm×10 μm window is opened for the red LEDs with a 20 μm separation from the green LEDs. An InGaN decomposition layer with a high In composition is grown with a thickness of 3 nm at a temperature of 730° C. After removing the SiO₂ from green window region, n-type 100 nm InGaN/GaN SL decomposition stop layer is grown on the green and red decomposition layers at a temperature of 950° C. For blue LEDs, a blue 10 μm×10 μm window is separated by 20 μm from the red LEDs, and no decomposition stop and no InGaN decomposition layers are grown. After removing the SiO₂ from blue window region, conventional blue LED structure including 100 nm n-InGaN buffer at 900° C. is grown on blue, green and red window regions. For the blue LED window region, the blue (B) LEDs are grown on the GaN template with a large compressive strain, due to no decomposition stop and decomposed decomposition layers. For the green LED window region, considering the results of FIG. 9 and the decomposition stop and decomposed decomposition layer with a small In composition, the color of the LED 3805 becomes green (G) due to the relatively small relaxation of lattice constant or strain of the InGaN layers of the LED structure. For the red LED window region, considering the results of FIG. 9, and the decomposition stop layer and decomposed decomposition layer with a high In composition, the color of the LED becomes red (R) due to the relatively high relaxation of lattice constant or strain of the InGaN layers of the LED structure, as shown in FIG. 38(a) an 38(b).

As another embodiment, only a red LED is grown using the decomposition layer. Blue and green LEDs are grown without the decomposition layer with a large compressive strain. In this case, each color LED is grown selectively.

The most important thing for three primary color LED growth for the display mentioned above in FIGS. 37(a) and 37(b) and FIGS. 38(a) and 38(b) is the red LED should be grown with a highest relaxation of InGaN layers. The green LED should be grown with a second highest relaxation of InGaN layers or without relaxation. The blue LED should be grown with a lowest relaxation or without a relaxation.

Mass-transfer technology of separated blue, green and red LED chips with a size of a micron or more has been the biggest issue when making micro-LED displays, because it would take a long time to mass-transfer a large number of such separated blue, green and red LED chips into a single LED display panel [1, 2]. Using present invention, however, each LED chip is not separated. Instead, after the MOCVD growth, the blue, green and red LEDs chips remain in the wafer. After mesa etching to separate each LED chip electrically, making the contacts and forming the electric circuit, then the whole wafer becomes a micro-LED display without any chip separation or mass transfer. Already we could demonstrate the first monolithic three-color LEDs or display as mentioned in FIGS. 17-19 using the present invention. Using the present invention, the mass-transfer technology of a large number of blue, green and red LED chips into a single LED display panel is not required any more.

### Advantages and Benefits

Using the LED and LD structures of this invention, LEDs and LDs with emission wavelengths ranging from far UV-C(200 nm) to far infrared (IR) (1500 nm) are possible, because relaxed InGaN or AlGaN is grown on a flexible, compliant, thin decomposition stop layer of InGaN, InGaN/GaN SL, AlₓGa₍₁₋ₓ₎N or AlGaN/AlGaN SL (0≤x≤1), which is grown on a decomposed decomposition layer of InGaN or AlGaN by MOCVD at a high growth temperature. Using this method, it is possible to grow high crystal quality, high In incorporated InGaN and high Al incorporated AlGaN at a high growth temperature. After the growth, the device structure is not separated from the decomposed decomposition layer. Thus, conventional device processing could be used. This is very important in the view of the costs. The high In incorporated InGaN or high Al incorporated AlGaN is grown on a whole area of a 2-inch substrate as an 50˜160% biaxially relaxed layer. Thereafter, the device processing is similar to conventional device processing.

On the other hand, a method of growing InGaN on porous GaN has a size limitation of less than 10 μm×10 μm [3,4]. In addition, the porous GaN process is a complicated process [3,4].

The present invention has four major advantages in comparison with the porous GaN process:
(1) The crystal quality of the InGaN grown by the present invention is much better than InGaN grown on porous GaN, as described in FIG. 3. The PL intensity of the present invention is three times higher.
(2) Relaxation of InGaN (biaxially 50˜160% relaxed) grown by the present invention is much higher than that of InGaN (biaxially 40˜50%) grown on porous GaN, as described in FIGS. 3(b) and 9.
(3) The present invention can be applied to any size of usable area, while InGaN grown porous GaN is available only for an area less than 10 μm×10 μm.
(4) The present invention is a much simpler process, which means it is a cheaper process, while InGaN grown on porous GaN is a more complicated process, which means that it is an expensive process.

In addition, the high relaxation of the InGaN, as described in FIGS. 3(b) and 9, results in III-nitride based devices of minimized strain due to lattice mismatch with high relaxation, such as LEDs, LDs, detectors, solar cells, electronic devices, transistors, field effect transistors (FETs), high electron mobility transistors (HEMTs), high frequency devices, power devices, and other devices.

Using the present invention, a total thickness of the n-type layers is preferably less than 1000 nm and more preferably less than 500 nm, which is not enough to make a highly efficient LED or LD. The present invention supplements the thin n-type layers by depositing TCO on the thin n-type layers. Also, the total thickness of the p-type AlₓGa₍₁₋ₓ₎N cladding layer (0≤x≤1) and p-type GaN layer should be less than the total thickness of the InGaN layers (about 500 nm), because the InGaN layers should be fully or partially relaxed. When the total thickness of 300 nm of the AlₓGa₍₁₋ₓ₎N cladding layer (0≤x≤1) and the p-type GaN layers is not enough to confine the laser light, TCO has to be deposited on the p++GaN layer or p-AlGaN layer as a part of a cladding layer.

Also, the TCO could be deposited on the p-type layers to reduce the operating voltage of the LD or LED, and to increase the light extraction efficiency of the LED. TCO is also used as n-cladding layers and p-cladding layers of the LED or LD in this invention.

Also, using this invention, the n-electrode is at a top side of the device and the p-electrode is at a back side of the device. For heat dissipation, the device is preferably oriented with the p-side down, because the main heat generation region is near the p-side region.

Also, using this invention, the LED or LD chip size becomes much smaller, because the electrodes are on opposite sides of the chip. For applications such as a micro-LED display, a smaller chip size also is better in reducing cost.

In contrast to this invention, the conventional porous GaN process is complicated and takes a long time. The process of the present invention, on the other hand, is very simple. Using the present invention, the whole of the LED or LD growth is completed as a single MOCVD growth. In the case of porous GaN, a tile shaped mesa first needs to be made using GaN, electro-chemical etching is performed to make porous GaN, and then the LED or LD structure is fabricated on the tile shaped mesa with a size of less than 10 μm. The present invention, in contrast, does not have to make the tile shaped mesa.

The present invention can make use of the whole area of a substrate, such as a 2-inch substrate, to make any devices, because the whole area of the InGaN or AlGaN grown on or above the decomposition stop layer is biaxially 50˜160% relaxed.

In the present invention, after the decomposition stop layer is grown on the decomposition layer, the decomposition layer should be decomposed at a high temperature. When the decomposition layer is decomposed at a high temperature, the decomposition stop layer should not be decomposed and its surface morphology should be mirror-like and need not be changed for the device structure growth.

For examples of relaxed InGaN growth, when the decomposition stop layer is n-GaN or n-InGaN/GaN SL, growth is by MOCVD with a growth temperature of around 1100˜800° C. When the decomposition layer is InGaN, the growth temperature is about 700˜800° C. In this case, during the growth of the decomposition stop layer of n-GaN or n-InGaN/GaN SL, the decomposition layer of InGaN is decomposed and the surface morphology of the decomposition stop layer of n-GaN or n-InGaN/GaN SL does not change. If the decomposition layer of InGaN does not decompose at a temperature of 1000˜800 C, the temperature should be increased up to 1050° C. after the growth of the decomposition stop layer of n-GaN or n-InGaN/GaN SL, and kept at that temperature for 1˜5 minutes to decompose the decomposition layer of InGaN. Then, InGaN-based device structure growth is performed, such as an LED or LD, with an emission wavelength of 200˜1500 nm, on or above the decomposition stop layer of n-GaN or n-InGaN/GaN SL.

In the case of relaxed AlGaN growth, the decomposition layer is n-type AlₓGa₍₁₋ₓ₎N(0)≤x≤1) grown at around 1000˜1200° ° C. and the decomposition stop layer is AlN grown at around 1200˜1600° C. by MOCVD. During the growth of the decomposition stop layer of AlN layer at a high temperature of 1400° C., the decomposition layer of AlₓGa₍₁₋ₓ₎N(0≤x≤1) is decomposed into Ga and Al metal, or alloy of Ga and Al metal, and Nitrogen gas. If the decomposition layer of AlₓGa₍₁₋ₓ₎N(0≤x≤1) is not decomposed enough, the temperature may be increased up to 1500° C. and kept at that temperature for a few minutes after the growth of decomposition stop layer of AlN.

Also, on the GaN template grown on sapphire or Si, InGaN decomposition layer is grown around 750° C. and then, AlGaN or AlInGaN decomposition stop layer is grown around 900˜1200° C. During the high temperature growth of the decomposition stop layer, the InGaN decomposition layer is decomposed. Next, AlGaN or AlInGaN based device structure is grown including AlGaN or AlInGaN buffer on or above the decomposition stop layer.

Then, after the growth, the device fabrication of an AlGaN-based device is performed, such as an UV-LED or UV-LD, with an emission wavelength of 200˜350 nm by using conventional device processing.

### Alternatives and Modifications

A number of alternatives and modifications are available for the present invention, as described in more detail below.

The present invention discloses a III-nitride based decomposition stop layer grown on or above an Aluminum (Al), Indium (In), Gallium (Ga) or Boron (B) containing III-nitride based decomposition layer, wherein the growth temperature is increased to decompose the Al, In, Ga or B containing decomposition layer, but not the III-nitride based decomposition stop layer. (The III-nitride based decomposition layer also may be decomposed by laser or directed energy means.) III-nitride based device structures are grown on or above the III-nitride based decomposition stop layer.

In one embodiment, the III-nitride based decomposition layer is grown on or above a substrate with a GaN template deposited thereon. The substrate may comprise sapphire, GaN, AlN, Si, SiC, glass, plastic, etc.

The III-nitride based decomposition layer may comprise InGaN, InAlGaN, InAlN, AlGaN, GaN or InN. The III-nitride based decomposition layer has a thickness that is preferably less than 10 nm, and more preferably less than 5 nm.

The III-nitride based decomposition stop layer may comprise GaN, InGaN, InGaN/GaN SL, InₓGa₍₁₋ₓ₎N/In_{y}Ga_{(1-y)}N SL or AlGaN, AlₓGa₍₁₋ₓ₎N/Al_{y}Ga_{(1-y)}N SL, AlN, wherein the decomposition stop layer may comprise an n-type layer inserted adjacent to III-nitride based n-type layers of a III-nitride based device. The III-nitride based decomposition stop layer has a thickness that is preferably less than 500 nm, and more preferably less than 200 nm.

The III-nitride based decomposition layer may also be created by ion implantation into a III-nitride based template or substrate, wherein Al, In, Ga or B ions are implanted to a specified depth from a top surface to form a decomposition layer that has a lower sublimation temperature or lower melting point than a decomposition stop layer that is on or above the decomposition layer in the III-nitride based template or substrate. The III-nitride based template or substrate is annealed at a high temperature to decompose or melt the decomposition layer with the lower sublimation temperature or melting point, but not the decomposition stop layer.

The ion implantation may be performed selectively, for example, the ion implantation may be performed through a window of a mask. Moreover, by using one or more masks, different decomposition layers, each with a different thickness, different ion dose density and/or different depth, may be formed to obtain different relaxations of the lattice constant or strain of device layers grown on or above the decomposition stop layer. The result is different III-nitride based device structures, such as LEDs, grown on or above the decomposition stop layer, each using a different one of the decomposition layers, wherein the LED structures emit blue, green and red light.

The III-nitride based device structures on or above the III-nitride based decomposition stop layer include at least an n-type layer, active (emitting) layer, and p-type layer. However, a layer sequence of epitaxial layers for the III-nitride based device structures can be inverted to at least a p-type layer, active (emitting) layer, and n-type layer. In one embodiment, the III-nitride based device structures have a grown area or chip size of more than 100 μm².

In one embodiment, the III-nitride based n-type layer, active (emitting) layer and/or p-type layer has an in-plane lattice constant or strain that is more than 30% biaxially relaxed: in another embodiment, the III-nitride based n-type layer, active (emitting) layer and/or p-type layer has an in-plane lattice constant or strain that is 50% or more biaxially relaxed; and in yet another embodiment, the III-nitride based n-type layer, active (emitting) layer and/or p-type layer has an in-plane lattice constant or strain that is at least 750% biaxially relaxed.

The III-nitride based n-type layer may comprise an Indium (In) containing layer such as InGaN, InGaAlN, InAlN and InN. The III-nitride based n-type layer may also comprise an aluminum (Al) containing layer such as AlGaN, InGaAlN, InAlN and AlN. In one embodiment, a total thickness of the n-type layers is less than 1000 nm; and in another embodiment, a total thickness of the n-type layers is less than 500 nm.

A top layer of the III-nitride based device structure may be flip-chip bonded on a sub-mount, and the device structure separated from the decomposed or melted decomposition layer. The top layer may comprise a TCO layer, such as ITO, ZnO, Ga₂O₃, or other materials. The top layer may be flip-chip bonded with a transparent glue or materials and the sub-mount may be a transparent sub-mount, such as glass, sapphire, plastic, or other transparent materials. The III-nitride based device structure may be separated from the decomposed or melted decomposition layer using a wet etching or mechanical pressure.

After separating the III-nitride based device structure, a TCO layer may be deposited on the flip-chipped top surface of an n-type layer of the III-nitride based device structure. The TCO layer may comprise a cladding or contact layer. Mesa etching may be performed for an LED, and a ridge waveguide for an LD may be formed from the top n-type or p-type layers of the III-nitride based device structure and/or the TCO layer. The III-nitride based device structure may sandwiched by TCO layer, with a first TCO layer on an n-type layer and a second TCO layer on a p-type layer or an n-type layer of a tunnel junction. The TCO layers may comprise contact layers to improve the current spreading and/or cladding layers to confine the light.

An n-electrode may be placed on a top side of the device and a p-electrode may be placed on a back side of the device. Preferably, the n- and p-electrodes are located at opposite sides of the device.

The III-nitride based-based devices may comprise LEDs or LDs with a peak emission wavelength from 200 nm to 1500 nm. The LEDs or LDs may comprise micro-cavity LEDs, micro-LEDs, edge emitting laser diodes, vertical cavity surface emitting laser diodes (VCSELs), etc.

The III-nitride based-based devices also may comprise solar cells, photodetectors (PDs), electronic devices, transistors, field effect transistors (FETs), high electron mobility transistors (HEMTs), power devices, radio frequency (RF) devices, etc.

In addition, the III-nitride based-based devices may be used in display, lighting, power, computation, communication, transportation and disinfection applications.

The III-nitride based decomposition layer may be mesa etched with a different thickness, wherein the thickness of the decomposition layer ranges from 0 to 200 nm and the mesa may have a square, rectangular or stripe shape. Then, the III-nitride based decomposition stop layer is grown to cover the whole area of the III-nitride based decomposition layer with a thickness from 10 nm to 500 nm from a top surface of the III-nitride based decomposition layer with the greatest thickness.

The decomposition layer or decomposition stop layer may have a different thickness depending on a location on a wafer, to change a color emitted from the device. Specifically, the emission color of the LED or LD is blue, green or red, depending on a thickness of the decomposition layer or decomposition stop layer.

Multi-color LEDs or LDs may be grown on or above a decomposition stop layer comprised of AlₓGa₍₁₋ₓ₎N(1≥x≥0), InₓGa₍₁₋ₓ₎N(1≥x≥0) or InₓGa₍₁₋ₓ₎N/In_{y}Ga_{(1-y)}N(1≥x≥0, 1≥y≥0, x≠y) SL, with a different thickness from 10 nm to 500 nm depending on the emission color of the LEDs or LDs. The decomposition stop layer is grown on or above a decomposed decomposition layer comprised of InₓGa₍₁₋ₓ₎N(1≥x≥0) with a different thickness from 0 to 100 nm depending on the emission color of the LED. Thus, the multi-color LEDs or LDs, each with a different relaxation of the InGaN layers depending on emission color of LEDs or LDs, are grown planarly on or above a substrate.

Specifically, at least one InGaN layer of a red LED or LD has the largest relaxation of in-plane lattice constant or strain; at least one InGaN layer of green LED or LD has the second largest or no relaxation of in-plane lattice constants or strain; and at least one InGaN layer of blue LED or LD has the third largest or no relaxation of in-plane lattice constant or strain.

Present invention is applicable for all kind of crystal orientation of III-Nitride based materials such as C-plain, semipolar, nonpolar, nitrogen polar and gallium polar to make all kinds of devices.

### Features and Elements

The present invention comprises a number of features and elements, as described in more detail below.
1) A III-nitride decomposition stop layer is grown on or above an Indium (In) and/or Gallium (Ga) containing III-nitride decomposition layer and then the growth temperature is increased to decompose the In or Ga containing decomposition layer.
2) A III-nitride based template or substrate, wherein ions are implanted with a certain depth from the top surface to form a material called a decomposition layer which has a lower sublimation temperature or lower melting point, and the III-nitride based template or substrate is annealed at a high temperature to decompose or melt the decomposition layer with a lower sublimation temperature or melting point, wherein the upper layer from the decomposed decomposition layer is called as decomposition stop layer.
3) In 2), ion implantation is performed selectively.
4) In 3), ion implantation is performed through a window of a mask.
5) In 3), by using at least one or two kinds of masks, the different decomposition layer with a different thickness, different ion dose density or a different depth is performed to obtain the different relaxation of lattice constant or strain of the layers grown on or above the decomposition stop layer.
6) In 2-5), ions of the implantation include at least In, Ga, Al or B.
7) In 3-5), when LED structure is grown on or above the decomposition stop layer, by using at least one or two kinds of decomposition layer, each decomposition layer is adjusted by changing the ion implantation condition mentioned in 5) to obtain at least a red or green LED.
8) In 1-6), the III-nitride based device structure is grown on or above III-nitride decomposition stop layer.
9) In 8), the III-nitride based device structure includes at least an n-type layer.
10) In 8), the III-nitride based device structure includes at least a p-type layer.
11) In 8), the III-nitride based device structure includes at least an n-type layer and a p-type layer.
12) In 8), the III-nitride based device structure includes at least n-type layers, active layer (or emitting layer), and p-type layers.
13) In 7-12), the top layer of the device structure is flip-chip bonded on a sub-mount, and the device structure is separated from the decomposed or melted decomposition layer.
14) In 7-12), the total thickness of n-type layers is less than 1000 nm.
15) In 7-12), the total thickness of n-type layers is less than 500 nm.
16) In 7-12), the III-nitride based device structure is separated from the decomposed or melted decomposition layer by using a wet etching or mechanical pressure.
17) In 1-16), the thickness of III-nitride decomposition layer is less than 10 nm.
18) In 1-16), the thickness of III-nitride decomposition layer is less than 5 nm.
19) In 1-18), the III-nitride based decomposition layer is grown on an AlₓGa₍₁₋ₓ₎N(0≤x≤1) layer.
20) In 1-19), the III-nitride based decomposition stop layer include at least an AlₓGa₍₁₋ₓ₎N(0≤x≤1) layer, InₓGa₍₁₋ₓ₎N(0≤x≤1) layer, AlₓGa₍₁₋ₓ₎N/Al_{y}Ga_{(1-y)}N superlattice (SL) (0≤x≤1, 0≤ ≤1, x≠y), or InₓGa₍₁₋ₓ₎N/In_{y}Ga_{(1-y)}N superlattice (0≤x≤1, 0≤y≤1, x≠y).
21) In 1-20), the thickness of III-nitride decomposition stop layer is less than 1000 nm.
22) In 1-20), the thickness of III-nitride decomposition stop layer is less than 500 nm.
23) In 13), after separating the III-nitride based device structure, the flip chipped top surface of the n-type layer is deposited by transparent conductive oxide (TCO) layer, such as ITO, ZnO, Ga₂O₃ and others.
24) In 1-23), the decomposition layer is InGaN, InAlGaN, InAlN AlGaN, GaN or InN.
25) In 23), the TCO layer is a part of cladding layer or contact layer of LEDs and LDs.
26) In 13, 23, 25), a ridge waveguide of the LDs is formed from top n-type layers or TCO.
27) In 13), the top layer is flip-chip bonded with a transparent glue or materials on transparent sub-mount, such as glass, sapphire, plastic and other transparent materials.
28) In 8-26), the III-nitride-based devices are LEDs and LDs with a peak emission wavelength from 200 nm to 1500 nm.
29) In 13, 23, 25-26), an n-electrode is at the topside and p-electrode is at the backside of the final device.
30) III-nitride based LEDs and LDs comprised of at least a TCO layer, III-nitride based n-type layers with the total thickness less than 1000 nm or 500 nm, an active layer (or emitting layer) and p-type layers.
31) III-nitride based LEDs and LDs comprised of at least a TCO layer deposited on III-nitride based n-type layers with the total thickness less than 1000 nm or 500 nm adjacent an active layer (or an emitting layer).
32) III-nitride based LEDs and LDs comprised of at least a TCO layer deposited on III-nitride based p-type layers with the total thickness less than 1000 nm or 500 nm adjacent an active layer (or an emitting layer).
33) III-nitride based LEDs and LDs comprised of at least a III-nitride based n-type layer with more than 50% biaxially relaxed in-plane lattice constant or strain, an active layer (or emitting layer) and p-type layers.
34) III-nitride based LEDs and LDs, comprised of at least an III-nitride based n-type layers with at least more than 70% biaxially relaxed strain or lattice constant, an active layer (or emitting layer) and p-type layers.
35) III-nitride based LEDs and LDs, of at least a III-nitride based n-type layer, an active layer (or emitting layer) or a p-type layer with at least more than 70% biaxially relaxed strain or lattice constant.
36) III-nitride based LEDs and LDs, comprised of at least an III-nitride based n-type layer or an active layer (or emitting layer) with at least more than 100% biaxially relaxed strain or lattice constant and p-type layers.
37) In 30-36), the ridge waveguide of the LDs is formed from top n-type layer, top p-type layer or top TCO.
38) In 30-36), the III-nitride based n-type layer is an indium (In) containing layer such as InGaN, InGaAlN, InAlN and InN.
39) In 30-36), the III-nitride based n-type layer is an aluminum (Al) containing layer such as AlGaN, InGaAlN, InAlN and AlN.
40) In 30-36), the III-nitride based LEDs and laser diode structure is sandwiched by TCOs, which means one TCO on n-type layer and another TCO on p-type layer or n-type layer of TJ.
41) In 40), both of TCOs work at least as a contact layer to improve the current spreading.
42) In 40), for the laser diodes, at least one of the TCOs work as a cladding layer to confine the light.
43) In 30-42), the n-electrode is at the topside and p-electrode is at the backside of the final device.
44) In 30-42), each of the n- and p-electrode is located at the opposite side of the chip of LED and laser diode.
45) In 30-42), the n-type AlₓGa₍₁₋ₓ₎N(0≤x≤1), n-type InₓGa₍₁₋ₓ₎N (0≤x≤1) layer, n-type AlₓGa₍₁₋ₓ₎N/Al_{y}Ga_{(1-y)}N superlattice (0≤x≤1, 0≤y≤1, x≠y) or n-type InₓGa₍₁₋ₓ₎N/In_{y}Ga_{(1-y)}N superlattice (0≤x≤1, 0≤y≤1, x≠y) of decomposition stop layer is inserted adjacent to the III-nitride based n-type layers.
46) In 45) the thickness of n-type AlₓGa₍₁₋ₓ₎N(0≤x≤1) layer, n-type InₓGa₍₁₋ₓ₎N(0≤x≤1) layer, n-type AlₓGa₍₁₋ₓ₎N/Al_{y}Ga_{(1-y)}N superlattice (0≤x≤1, 0≤y≤1, x≠y) or n-type InₓGa₍₁₋ₓ₎N/In_{y}Ga_{(1-y)}N superlattice (0≤x≤1, 0≤y≤1, x≠y) is less than 500 nm or less than 200 nm.
47) In 30-46), the transparent conductive oxide (TCO) layer is Indium Tin Oxide, ZnO, Ga₂O₃ and others.
48) In 30-45), the TCO is ITO.
49) In 30-48), the III-nitride based device is an LED or LD with a peak emission wavelength from 200 nm to 1500 nm.
50) In 49), the LED and LD include all kinds of LEDs and LDs, such as micro-cavity LEDs, micro-LEDs, edge emitting LDs, vertical cavity surface emitting laser diodes (VCSEL), etc.
51) In 8-47), the III-nitride based device includes all kinds of devices, such as photo detectors, LEDs, LDs, electronic devices, power devices, RF devices, HEMTs, FETs, transistors, etc.
52) In 49-51), the III-nitride based devices are used in an automobile including an electric vehicle (EV), data center, power grid, computers, robots, smartphones, TVs, base stations of wireless communications, displays, lighting, trains, airplanes, disinfection system and equipment, water and air purification system and equipment, and all kinds of equipment and systems which use the III-V compound based devices described in 49-51)
53) In 8-12), the layer sequence of the epitaxial layers can be inverted to p-type, active region, and n-type on or above the III-nitride decomposition stop layer.
54) In 7-53), the device structure includes one or more tunnel junctions.
55) III-nitride based material with a higher sublimation temperature is grown on or above the III-nitride based material with a lower sublimation temperature and then, the temperature is increased to decompose the III-nitride based material with a lower sublimation temperature
56) In 55), the III-nitride based device structure is grown on or above III-nitride based material with the higher sublimation temperature.
57) In 56), the III-nitride based device structure includes at least an n-type layer.
58) In 56), the III-nitride based device structure includes at least a p-type layer.
59) In 56), the III-nitride based device structure includes at least an n-type layer and p-type layer.
60) In 56), the III-nitride based device structure includes at least n-type layers, active layer (or emitting layer) and p-type layers.
61) In 56-60), the top layer of the device structure is flip-chip bonded on a sub-mount, and the device structure is separated from the decomposed III-nitride based material with a lower sublimation temperature.
62) In 56-61), the III-nitride based device includes all kinds of devices, such as photo detectors, LEDs, LDs, electronic devices, power devices, RF devices, HEMTs, FETs, transistors, etc.
63) In 62), the emission wavelength of the emitting device is from 200 nm to 1500 nm.
64) In 62-63), the III-nitride based devices are used for an automobile including an electrical vehicle (EV), data center, power grid, computers, robots, smartphones, TVs, base stations of wireless communications, displays, lighting, trains, airplanes, disinfection system and equipment, water and air purification system and equipment, and all kinds of equipment and systems which use the III-V compound based devices.
65) III-nitride based layers with the planarly grown on or above the substrate, wherein the in-plane lattice constant or strain of at least one III-nitride layer is biaxially relaxed more than 30%.
66) III-nitride based layers with the planarly grown on or above the substrate, wherein the in-plane lattice constant or strain of at least one III-nitride layer is biaxially relaxed more than 50%.
67) III-nitride based layers with the planarly grown on or above the substrate, wherein the in-plane lattice constant or strain of at least one III-nitride layer is biaxially relaxed more than 70%.
68) III-nitride based layers with the planarly grown on or above the substrate, wherein the in-plane lattice constant or strain of at least one III-nitride layer is biaxially relaxed more than 100%.
69) III-nitride based layers, wherein in-plane lattice constant or strain of at least one III-nitride layer is biaxially relaxed more than 50%.
70) III-nitride based device, wherein in-plane lattice constant or strain of at least one III-nitride layer is biaxially relaxed more than 70%.
71) In 65-70), the III-nitride layer is at least an Indium containing layer such as InGaN or at least an Aluminum containing layer such as AlGaN.
72) In 65-70), the III-nitride based device include all kinds of devices, such as photo detectors, LEDs, LDs, electronic devices, power devices, RF devices, HEMTs, FETs, transistors, etc.
73) In 65-72), wherein the emission wavelength of the emitting device is from 200 nm to 1500 nm.
74) In 72-73), the III-nitride based device is used for an automobile including electrical vehicle (EV), data center, power grid, computers, robots, smartphones, TVs, base stations of wireless communications, displays, lighting, trains, airplanes, disinfection system and equipment, water and air purification system and equipment, and all kinds of equipment and systems which use III-V compound-based devices.
75) In 1-7), the III-nitride decomposition layer is decomposed by laser, heat or directed energy means.
76) In 1-7), the III-nitride based device structure of LED structure is grown on or above the decomposition stop layer, wherein at least the LED structure or InGaN buffer layer is grown selectively.
77) In 76), each selectively grown LED is a blue, green or red LED.
78) In 76-77), the in-plane lattice constant or strain of at least one InGaN layer of at least one LED structure is biaxially relaxed more than 50%.
79) In 76-77), the in-plane lattice constant or strain of at least one InGaN layer of at least one LED structure is biaxially relaxed more than 70%. 80) In 76-79), an LED display is comprised of at least one of blue, green and red LEDs.
81) In 76-80), an LED display is comprised of blue, green and red LEDs.
82) In 80-81), the LED display is a micro- or mini-LED display.
83) In 82), the micro- or mini-LED display is used for smart phones, AR/VR displays, TV/computer displays, and other displays.
84) A first III-nitride decomposition layer is grown on second III-nitride layer or GaN template on a substrate.
85) In 84), the first III-nitride decomposition layer is mesa etched with a different thickness, and the decomposition stop layer is grown to cover the whole area of decomposition layer with a thickness from 10 nm to 500 nm from the top of the highest decomposition layer.
86) In 85), the decomposition layer is decomposed thermally at a high temperature.
87) In 86), the LED or LD structure is grown on or above the decomposition stop layer.
88) In 85), the shape of the mesa is square, rectangular shape or stripe shape.
89) In 85), the decomposition layer or decomposition stop layer has a different thickness depending on the location of the wafer to change the color of LED or LD.
90) In 84-85, 89), the III-nitride decomposition layer is at least an In, Ga or

Al containing layer.
91) In 85-90), the decomposition stop layer is AlₓGa₍₁₋ₓ₎N(0≤x≤1), InₓGa₍₁₋ₓ₎N(0≤x≤1), AlₓGa₍₁₋ₓ₎N/Al_{y}Ga_{(1-y)}N superlattice (0≤x≤1, 0≤y≤1, x≠y) or InₓGa₍₁₋ₓ₎N/In_{y}Ga_{(1-y)}N superlattice (0≤x≤1, 0≤y≤1, x≠y) or at least an In, Ga or Al containing layer.
92) In 87, 89), the emission color of LED or LD is blue, green and red depending on the thickness of decomposition stop layer or decomposition layer.
93) In 84-86, 89, 92), the thickness of the decomposition layer is from 0 to 200 nm.
94) In 87, 89, 92), the in-plane lattice constant or strain of at least one InGaN layer of at least one LED or LD structure is biaxially relaxed more than 30%.
95) In 87, 89, 92), the in-plane lattice constant or strain of at least one InGaN layer of at least one LED or LD structure is biaxially relaxed more than 50%.
96) In 87, 89, 92, 94-95), an LED display is comprised of at least one of blue, green and red LEDs or LDs.
97) In 87, 89, 92, 94-96), an LED or LD display is comprised of at least blue, green or red LEDs or LDs.
98) In 94-97), the LED display is a micro- or mini-LED display.
99) In 98), the micro- or mini-LED display is used for smart phones, AR/VR display, TV/computer display, and other displays.
100) Multi-color LEDs or LDs are grown on or above AlₓGa₍₁₋ₓ₎N (0≤x≤1), InₓGa₍₁₋ₓ₎N(0≤x≤1), AlₓGa₍₁₋ₓ₎N/Al_{y}Ga_{(1-y)}N superlattice (0≤x≤1, 0≤y≤1, x≠y) or InₓGa₍₁₋ₓ₎N/In_{y}Ga_{(1-y)}N superlattice (0≤x≤1, 0≤y≤1, x≠y) or at least and In, Ga or Al containing decomposition stop layer with a different thickness from 10 nm to 500 nm depending on the emission color of the LED.
101) Multi-color LEDs or LDs are grown on or above AlₓGa₍₁₋ₓ₎N (0)≤x≤1), InₓGa₍₁₋ₓ₎N(0≤x≤1), AlₓGa₍₁₋ₓ₎N/Al_{y}Ga_{(1-y)}N superlattice (0≤x≤1, 0≤y≤1, x≠y) or InₓGa₍₁₋ₓ₎N/In_{y}Ga_{(1-y)}N superlattice (0≤x≤1, 0≤y≤1, x≠y) or at least an In, Ga or Al containing decomposition stop layer on the decomposed decomposition layer of InₓGa₍₁₋ₓ₎N(0≤x≤1) or at least an Indium containing layer with a different thickness from 0 to 100 nm depending on the emission color of the LED.
102) Multi-color LEDs or LDs with a different relaxation of InGaN layers depending on emission color of LEDs or laser diodes (LDs) is grown planarly on or above a substrate.
103) In 102), at least one InGaN layer of red LED or LD has the largest relaxation of in-plain lattice constant or strain.
104) In 102), at least one InGaN layer of green LED or LD has the second largest or no relaxation of in-plain lattice constants or strain.
105) In 102), at least one InGaN layer of blue LED or LD has the third largest or no relaxation of in-plain lattice constant or strain.
106) In 102), the blue, green and red LED or LD are grown on or above AlₓGa₍₁₋ₓ₎N(0)≤x≤1), InₓGa₍₁₋ₓ₎N(0≤x≤1), AlₓGa₍₁₋ₓ₎N/Al_{y}Ga_{(1-y)}N superlattice (0≤x≤1, 0≤y≤1, x≠y) or InₓGa₍₁₋ₓ₎N/In_{y}Ga_{(1-y)}N superlattice (0≤x≤1, 0≤y≤1, x≠y) or at least an In, Ga or Al containing decomposition stop layer with a different relaxation depending on the emission color of each LED or LD.
107) In 102), the blue and green LED or LD are grown on or above AlₓGa₍₁₋ₓ₎N(0≤x≤1), InₓGa₍₁₋ₓ₎N (0≤x≤1), AlₓGa₍₁₋ₓ₎N/Al_{y}Ga_{(1-y)}N superlattice (0≤x≤1, 0≤y≤1, x≠y), InₓGa₍₁₋ₓ₎N/In_{y}Ga_{(1-y)}N superlattice (0≤x≤1, 0≤y≤1, x≠y) or at least an In, Ga or Al containing decomposition stop layer with a different relaxation depending on the emission color of each LED or LD.
108) In 102), the green and red LED or LD are grown on or above AlₓGa₍₁₋ₓ₎N(0≤x≤1), InₓGa₍₁₋ₓ₎N(0≤x≤1), AlₓGa₍₁₋ₓ₎N/Al_{y}Ga_{(1-y)}N superlattice (0≤x≤1, 0≤y≤1, x≠y), n-type InₓGa₍₁₋ₓ₎N/In_{y}Ga_{(1-y)}N superlattice (0≤x≤1, 0≤y≤1, x≠y) or at least an In, Ga or Al containing decomposition stop layer with a different relaxation depending on the emission color of each LED or LD.
109) In 102), the substrate is Si, GaN, AlN, sapphire, glass, SiC, plastic, etc.
110) The III-nitride based decomposition layer and the decomposition stop layer is grown by the selective area growth on the blue LED epitaxial wafer, a green LED structure is grown by selective area growth directly on the blue LED epitaxial wafer and on the decomposition stop layer at the same time, and the green LED structure grown on or above the decomposition stop layer emit a red light.
111) In 110), each blue, green and red LED structure is mesa etched to separate each LED and to reach to the n-layers to make n-contact.
112) In 111), three primary color LEDs forms monolithic display for the application of smart phones, watches, AR, TV, computers and all kinds of displays.

### Process Flowchart

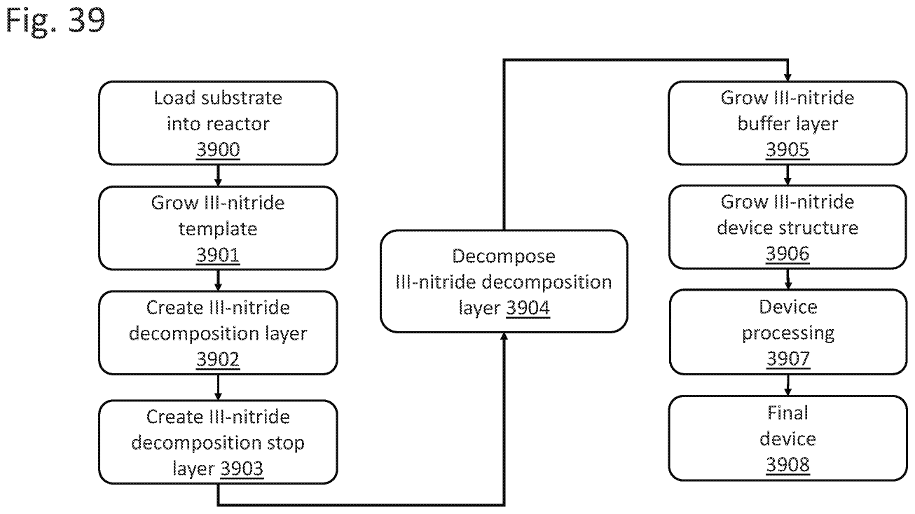

FIG. 39 is a flowchart that illustrates the steps for a process of fabricating a III-nitride based device, according to the present invention. Specifically, the flowchart illustrates the steps for a process of fabricating a III-nitride based device having an in-plane lattice constant or strain that is preferably more than 30% biaxially relaxed, more preferably 50% or more biaxially relaxed, and most preferably at least 70% biaxially relaxed.

Block 3900 represents the step of loading a substrate into a chamber of an MOCVD reactor. The substrate may comprise sapphire, GaN, AlN, SiC, Si, sapphire or other materials.

Block 3901 represents the step of growing a III-nitride based template on or above the substrate. The III-nitride based template may comprise GaN when fabricating InGaN-based devices: the III-nitride based template may comprise GaN or AlN when fabricating AlGaN-based devices.

Block 3902 represents the step of creating a III-nitride based decomposition layer on or above the III-nitride based template. In one embodiment, the III-nitride based decomposition layer consists of a single layer, rather than multiple layers, wherein the single layer may comprise InGaN when fabricating InGaN-based devices, wherein the single InGaN layer is grown by MOCVD at a temperature of about 700-800° C. on the GaN template, and the InGaN layer has a thickness of about 10 nm or less. Alternatively, the III-nitride based decomposition layer consists of a single layer, rather than multiple layers, wherein the single layer may comprise GaN, InGaN or AlGaN when fabricating AlGaN-based devices, and the single GaN, InGaN or AlGaN layer has a thickness of about 10 nm or less.

Block 3903 represents the step of creating a III-nitride based decomposition stop layer on or above the III-nitride based decomposition layer. The III-nitride based decomposition stop layer may comprise GaN, InGaN, InGaN/GaN SL or InₓGa₍₁₋ₓ₎N/In_{y}Ga_{(1-y)}N(1≥x≥0, 1≥y≥0, x≠y) SL when fabricating InGaN-based devices, wherein the decomposition stop layer is grown by MOCVD at a temperature that increases from about 750° C. to about 900˜1000° C., and the decomposition stop layer has a thickness of about 1000 nm or less. Alternatively, the III-nitride based decomposition stop layer may comprise AlN, AlGaN, AlGaN/GaN SL or AlₓGa₍₁₋ₓ₎N/Al_{y}Ga_{(1-y)}N(1≥x≥0, 1≥y≥0, x≠y) SL when fabricating AlGaN-based devices, wherein the decomposition stop layer is grown by MOCVD at a temperature that increases from about 1000° C. to about 1400° C., and the decomposition stop layer has a thickness of about 1000 nm or less.

Block 3904 represents the step of decomposing the III-nitride based decomposition layer by increasing the temperature, but not the III-nitride based decomposition stop layer. In this step, the temperature is increased to about 900˜1600° C. to decompose the GaN, InGaN, AlGaN or AlInGaN layer that comprises the III-nitride based decomposition layer. Moreover, this step may be performed as part of Block 3903 by epitaxially growing the III-nitride based decomposition stop layer, for example, where 30 nm of the growth is at a temperature of about 750° C. and a remaining 70 nm of the growth is with the temperature ramped linearly to about 1000° C. Alternatively, the III-nitride based template or substrate may be annealed at a high temperature to decompose or melt the III-nitride based decomposition layer, which has a lower sublimation temperature or melting point than the III-nitride based decomposition stop layer, but not the III-nitride based decomposition stop layer.

Block 3905 represents the optional step of epitaxially growing a III-nitride based buffer layer on or above the III-nitride based decomposition stop layer after the III-nitride based decomposition layer is decomposed. The III-nitride based buffer layer may comprise InGaN when fabricating InGaN-based devices. Alternatively, the III-nitride based buffer layer may comprise AlGaN when fabricating AlGaN-based devices.

Block 3906 represents the step of epitaxially growing a III-nitride based device structure on or above the III-nitride based decomposition stop layer and the optional III-nitride based buffer layer. The III-nitride based device structure may comprise InGaN layers such as an InGaN MQW grown by MOCVD when fabricating InGaN-based devices. Alternatively, the III-nitride based device structure may comprise AlGaN layers such as an AlGaN MQW grown by MOCVD when fabricating AlGaN-based devices.

The III-nitride based device structure includes at least one of an n-type layer, active layer, and p-type layer. The at least one of the n-type layer, active layer and p-type layer has an in-plane lattice constant or strain that is preferably more than 30% biaxially relaxed, more preferably 50% or more biaxially relaxed, and most preferably at least 70% biaxially relaxed.

Moreover, the total thickness of n-type layers in the III-nitride based device structure is preferably less than 1000 nm, and more preferably less than 500 nm.

Once complete, the III-nitride based device structure is separated from the decomposed III-nitride based decomposition layer. This separation may be performed by etching or mechanical pressure.

Block 3907 represents the step of processing the III-nitride based device structure into a III-nitride based device, such as an LED or LD, and then packaging the device. This may include, but is not limited to, depositing TCO layers, sub-mounting, etching mesas or ridge waveguides, passivating sidewalls, depositing electrodes, etc.

Block 3908 represents the end result of the method, namely, a III-nitride-based device according to the present invention, wherein the III-nitride based decomposition stop layer is created on or above the III-nitride based decomposition layer; the III-nitride based decomposition layer is decomposed, but not the III-nitride based decomposition stop layer; and the III-nitride based device structure is grown on or above the III-nitride based decomposition stop layer. The III-nitride-based device may comprise, for example, an LED or LD with a peak emission wavelength from 200 nm to 1500 nm. The III-nitride-based device may comprise, in another example, other devices as described herein.

In an alternative embodiment, Blocks 3902 and 3903 may represent the steps of creating the III-nitride based decomposition layer by ion implantation into the III-nitride based template or substrate, wherein Aluminum (Al), Indium (In), Gallium (Ga) or Boron (B) ions are implanted to a specified depth from a top surface of the III-nitride based template or substrate to form the III-nitride based decomposition layer with a lower sublimation temperature or lower melting point than the III-nitride based decomposition stop layer that is on or above the III-nitride based decomposition layer in the III-nitride based template or substrate.

Moreover, the ion implantation may be performed selectively through one or more windows of a mask, so that different III-nitride based decomposition layers, each with a different thickness, different ion dose density and/or different depth, are formed in the III-nitride based template or substrate to obtain different relaxations of the lattice constant or strain of device layers grown on or above the III-nitride based decomposition stop layer, resulting in different III-nitride based device structures grown on or above the III-nitride based decomposition stop layer, each using a different one of the different III-nitride based decomposition layers, and the different III-nitride based device structures emit at different wavelengths.

In another alternative embodiment, Block 3902 also represents the step of the III-nitride based decomposition layer being mesa etched to have surfaces with different thicknesses ranging from 0 to 200 nm; and Block 3903 also represents the step of the III-nitride based decomposition stop layer being grown to cover a whole area of the III-nitride based decomposition layer with a thickness from 10 nm to 500 nm from a top surface of the III-nitride based decomposition layer. In this embodiment, the III-nitride based device structure emits light at wavelengths that differ depending on a thickness of the III-nitride based decomposition layer and the III-nitride based decomposition stop layer, and a relaxation of layers in the III-nitride based device structure.

The above steps may be modified, eliminated, repeated, or completed in any desired order, without departing from the scope of the present invention.

### Nomenclature

The terms “Group-III nitride” or “III-nitride” or “nitride” or “III-N” as used herein refer to any composition or material related to (B, Al, Ga, In, Sc, Y)N semiconductors having the formula BᵤAlᵥGa_{w}InₓSc_{y}Y_{z}N where 0≤u≤1, 0≤v≤1, 0≤w≤1, 0≤x≤1, 0≤y≤1, 0≤z≤1, and u+v+w+x+y+z=1. These terms as used herein are intended to be broadly construed to include respective nitrides of the single species, B, Al, Ga, In, Sc and Yn, as well as binary, ternary, quaternary, etc., compositions of such Group III metal species. Accordingly, these terms include, but are not limited to, the compounds of AlN, GaN, InN, AlGaN, AlInN, InGaN, AlGaInN, etc. When two or more of the (B, Al, Ga, In, Sc, Y)N component species are present, all possible compositions, including stoichiometric proportions as well as off-stoichiometric proportions (with respect to the relative mole fractions present of each of the (B, Al, Ga, In, Sc, Y)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of III-nitride materials. When identifying crystal orientations, directions, terminations and polarities using Miller indices, the use of braces, { }, denotes a set of symmetry-equivalent planes, which are represented by the use of parentheses, ( ) The use of brackets, [ ], denotes a direction, while the use of brackets, < >, denotes a set of symmetry-equivalent directions.

Many III-nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in III-nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

### REFERENCES

The following publications and patents are incorporated by reference herein:
[1] A. Paranjpe, J. Montgomery, S. M. Lee, and C. Morath, SID Symp. Dig. Tech. Pap. 49, 597 (2018).
[2] M. S. Wong, S. Nakamura, and S. P. DenBaars, ECS J. Solid State Sci. Technol. 9, 015012 (2020).
[3] S. S. Pasayat et al., Semicond. Sci. Technol. 34 (2019) 115020.
[4] S. S. Pasayat et al., Appl. Phys. Express 14, 011004 (2021).
[5] Y. Kawaguchi et al., Mater. Res. Soc. Symp. Proc. Vol. 449, 1997.
[6] J. Hwang et al., Appl. Phys. Express, 7, 071003 (2014).
[7] Z. Chen et al., J. Phys. D: Appl. Phys. 54 (2021) 123001.
[8] H. Jiang and J. Lin, “Micro LEDs”, Semiconductors and Semimetals, Vol. 106.
[9] S. Mehari et al., Optics Express, 26, 1564, 2018.
[10] Holder, C. O., Leonard, J. T., Farrell, R. M., Cohen, D. A., Yonkee, B., Speck, J. S., DenBaars, S. P., Nakamura, S., Feezell, D. F., “Nonpolar III-nitride vertical-cavity surface emitting lasers with a polarization ratio of 100% fabricated using photoelectrochemical etching,” Appl. Phys. Lett. 105(3), 031111 (2014).
[11] U.S. Pat. No. 9,859,464, issued Jan. 2, 2018, to DeMille et al., and entitled “Lighting emitting diode with light extracted from front and back sides of a lead frame.”
[12] U.S. Pat. No. 9,240,529, issued Jan. 19, 2016, to DeMille et al., and entitled “Textured phosphor conversion layer light emitting diode.”
[13] U.S. Pat. No. 7,781,789, issued Aug. 24, 2010, to DenBaars et al., and entitled “Transparent mirrorless light emitting diode.”
[14] U.S. Pat. No. 10,217,916, issued Feb. 26, 2019, to Nakamura et al., and entitled “Transparent light emitting diodes.”
[15] Philip Chan, Steven P. DenBaars and Shuji Nakamura, “Growth of highly-relaxed InGaN pseudo-substrates over full 2-in. wafers,” Appl. Phys. Lett. 119, 131106 (28 Sep. 2021).
[16] Philip Chan, Vincent Rienzi, Norleakvisoth Lim, Hsun-Ming Chang, Michael Gordon, Steven P. DenBaars and Shuji Nakamura, “Demonstration of relaxed InGaN-based red LEDs grown on high active region temperature,” Appl. Phys. Express 14, 101002 (30 Sep. 2021).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
fabricating a III-nitride based device having an in-plane lattice constant or strain that is more than 30% biaxially relaxed, by:
creating a III-nitride based decomposition stop layer on or above a III-nitride based decomposition layer, wherein an increase in temperature decomposes the III-nitride based decomposition layer; and
growing a III-nitride based device structure on or above the III-nitride based decomposition stop layer.

2. The method of claim 1, wherein the III-nitride based device structure grown on or above the III-nitride based decomposition stop layer has a peak photoluminescence wavelength increased by at least 50 nm as compared to a III-nitride based device structure grown without the decomposed III-nitride based decomposition layer.

3. The method of claim 1, wherein:
the III-nitride based decomposition layer comprises an InₓGa₍₁₋ₓ₎N(1≥x≥0) layer grown by metalorganic chemical vapor deposition (MOCVD) at a temperature of about 700-800° C. on or above a GaN template, and the InₓGa₍₁₋ₓ₎N (1≥x≥0) layer has a thickness of about 10 nm or less;
the III-nitride based decomposition stop layer comprises a InₓGa₍₁₋ₓ₎N (1≥x≥0) or InₓGa₍₁₋ₓ₎N/In_{y}Ga_{(1-y)}N (1≥x≥0, 1≥y≥0, x≠y) layer grown by MOCVD at a temperature that increases from about 700˜800° C. to about 900˜1100° C., and the decomposition stop layer has a thickness of about 500 nm or less;
as the temperature increases to about 900˜1100° C., the InGaN decomposition layer is decomposed, but not the decomposition stop layer;
the III-nitride based device structure comprises an InGaN multiple quantum well (MQW) grown by MOCVD on or above the decomposition stop layer at a temperature greater than 800° C., and the InGaN MQW emits green, red or near infrared light.

4. The method of claim 1, wherein at least one of a temperature, a thickness of the III-nitride based decomposition layer, a thickness of the III-nitride based decomposition stop layer, or an Indium content of the III-nitride based decomposition layer, are tailored so that atoms of the III-nitride based decomposition layer are distributed and the III-nitride based decomposition stop layer forms on or above the III-nitride based decomposition layer with reduced strain.

5. The method of claim 1, wherein the III-nitride based device structure on or above the III-nitride based decomposition stop layer includes at least one of an n-type layer, active layer, and p-type layer, and the at least one of the n-type layer, active layer and p-type layer has the in-plane lattice constant or strain that is more than 50% biaxially relaxed.

6. The method of claim 5, wherein the at least one of the n-type layer, active layer and p-type layer has the in-plane lattice constant or strain that is 70% or more biaxially relaxed.

7. The method of claim 5, wherein the at least one of the n-type layer, active layer and p-type layer has the in-plane lattice constant or strain that is at least 80% biaxially relaxed.

8. The method of claim 1, wherein the III-nitride based decomposition layer is grown on or above a substrate with a III-nitride based template deposited thereon.

9. The method of claim 1, wherein the III-nitride based decomposition layer comprises InGaN, InAlGaN, InAlN AlGaN, GaN or InN, and has a thickness that is less than 10 nm.

10. The method of claim 1, wherein the III-nitride based decomposition stop layer comprises GaN, AlN, AlₓGa₍₁₋ₓ₎N/Al_{y}Ga_{(1-y)}N (1≥x≥0, 1≥y≥0, x≠y) superlattice (SL) or AlₓGa₍₁₋ₓ₎N(1≥x≥0), and the decomposition stop layer comprises an n-type decomposition stop layer which is a part of a III-nitride based n-type layer of the III-nitride based device structure.

11. The method of claim 1, wherein the III-nitride based decomposition stop layer has a thickness that is less than 1000 nm.

12. The method of claim 1, wherein:
the III-nitride based decomposition layer is created by ion implantation into a III-nitride based template or substrate, wherein at least Aluminum (Al), Indium (In), Gallium (Ga) or Boron (B) ions are implanted to a specified depth from a top surface of the III-nitride based template or substrate to form the III-nitride based decomposition layer with a lower sublimation temperature or lower melting point than the III-nitride based decomposition stop layer that is on or above the III-nitride based decomposition layer in the III-nitride based template or substrate; and
the III-nitride based template or substrate is annealed at a high temperature to decompose or melt the III-nitride based decomposition layer with the lower sublimation temperature or melting point, but not the III-nitride based decomposition stop layer.

13. The method of claim 12, wherein the ion implantation is performed selectively through one or more windows of a mask, so that different III-nitride based decomposition layers, each with a different thickness, different ion dose density and/or different depth, are formed in the III-nitride based template or substrate to obtain different relaxations of the lattice constant or strain of device layers grown on or above the III-nitride based decomposition stop layer, resulting in III-nitride based device with a different relaxation grown on or above the III-nitride based decomposition stop layer, each using a different one of the different III-nitride based decomposition layers, and the III-nitride based device with a different relaxation emit at different wavelengths.

14. The method of claim 1, wherein a total thickness of n-type layers in the III-nitride based device structure is less than 1000 nm.

15. The method of claim 1, wherein the III-nitride based device structure is separated from the decomposed III-nitride based decomposition layer.

16. The method of claim 1, wherein the III-nitride based device structure is a light-emitting diode (LED) or laser diode (LD) with a peak emission wavelength from 200 nm to 1500 nm.

17. The method of claim 1, wherein:
the III-nitride based decomposition layer is mesa etched to have surfaces with different thicknesses ranging from 0 to 200 nm;
the III-nitride based decomposition stop layer is grown to cover a whole area of the III-nitride based decomposition layer with a thickness from 10 nm to 500 nm from a top surface of the III-nitride based decomposition layer; and
the III-nitride based device structure emits light at wavelengths that differ depending on a thickness of the III-nitride based decomposition layer, the III-nitride based decomposition stop layer, or a relaxation of layers in the III-nitride based device structure.

18. The method of claim 1, wherein:
the III-nitride based decomposition layer and the decomposition stop layer are grown by selective area growth on a blue light emitting epitaxial structure;
a green light emitting epitaxial structure is grown by selective area growth on both the blue light emitting epitaxial structure and the decomposition stop layer; and
the green light emitting epitaxial structure grown on the decomposition stop layer becomes a red light emitting epitaxial structure.

19. The method of claim 18, wherein each of the blue, green and red light emitting epitaxial structures is mesa etched to separate each of the blue, green and red light emitting epitaxial structures and to expose an n-type layer for an n-contact.

20. A device, comprising:
a III-nitride based device having an in-plane lattice constant or strain that is more than 30% biaxially relaxed, comprising:
a III-nitride based decomposition stop layer created on or above a III-nitride based decomposition layer, wherein the III-nitride based decomposition layer is decomposed, but not the III-nitride based decomposition stop layer; and
a III-nitride based device structure grown on or above the III-nitride based decomposition stop layer.

21. A product-by-process, comprising:
a III-nitride based device having an in-plane lattice constant or strain that is more than 30% biaxially relaxed, comprising:
a III-nitride based decomposition stop layer created on or above a III-nitride based decomposition layer, wherein the III-nitride based decomposition layer is decomposed, but not the III-nitride based decomposition stop layer; and
a III-nitride based device structure grown on or above the III-nitride based decomposition stop layer;
wherein the III-nitride based device having the in-plane lattice constant or strain that is more than 30% biaxially relaxed is fabricated by:
creating the III-nitride based decomposition stop layer on or above the III-nitride based decomposition layer, wherein a temperature is increased to decompose the III-nitride based decomposition layer, but not the III-nitride based decomposition stop layer; and
growing the III-nitride based device structure on or above the III-nitride based decomposition stop layer.
